(19) United States
(12) Patent Application Publication
(10) Pub. No.: US 2021/0170595 A1
(43) Pub. Date: Jun. 10, 2021

(54) MAGNETIC RESONANCE IMAGING MAGNET ASSEMBLY SYSTEMS AND METHODS

(71) Applicant: Hyperfine Research, Inc., Guilford, CT (US)

(72) Inventors: Tie Hu, Guilford, CT (US); Cedric Hugon, Guilford, CT (US)

(21) Appl. No.: 17/115,132

(22) Filed: Dec. 8, 2020

Related U.S. Application Data
(60) Provisional application No. 62/984,001, filed on Mar. 2, 2020.
(60) Provisional application No. 62/945,979, filed on Dec. 10, 2019.

(51) Int. Cl. B25J 9/16; B25J 15/06

(52) U.S. Cl. CPC B25J 9/1664; H01F 7/02; B25J 15/0608

(57) ABSTRACT

Systems and methods for automated assembly of a B₀ magnet assembly for use in a point-of-care MRI system are provided herein. A gripper capable of gripping a permanent magnet with a high clamping force is provided for positioning the permanent magnet in the B₀ magnet assembly in accordance with a permanent magnet layout. A robot having multiple degrees of freedom is provided for positioning the gripper. Components of the system described herein have been developed to withstand the effects of strong magnetic forces generated by high-strength magnetic fields surrounding the B₀ magnet assembly.

### CROSS-REFERENCE TO RELATED APPLICATIONS

This application claims the benefit under 35 U.S.C. § 119(e) of U.S. provisional patent application Ser. No. 62/984,001, entitled “MAGNETIC RESONANCE IMAGING MAGNET ASSEMBLY SYSTEMS AND METHODS”, filed Mar. 2, 2020 under Attorney Docket No. 00354.70050US01, and U.S. provisional patent application Ser. No. 62/945,979, entitled “MAGNETIC RESONANCE IMAGING MAGNET ASSEMBLY SYSTEMS AND METHODS”, filed Dec. 10, 2019 under Attorney Docket No. 00354.70050US00, each of which are incorporated by reference in their entireties herein.

### FIELD

The present disclosure relates generally to magnetic resonance imaging (MRI) devices and, more specifically, systems and methods for assembling a magnet assembly configured for use with MRI devices.

### BACKGROUND

MRI provides an important imaging modality for numerous applications and is widely utilized in clinical and research settings to produce images of the inside of the human body. As a generality, MRI is based on detecting magnetic resonance (MR) signals, which are electromagnetic waves emitted by atoms in response to state changes resulting from applied electromagnetic fields. For example, nuclear magnetic resonance (NMR) techniques involve detecting MR signals emitted from the nuclei of excited atoms upon the re-alignment or relaxation of the nuclear spin of atoms in an object being imaged (e.g., atoms in the tissue of the human body). Detected MR signals may be processed to produce images, which in the context of medical applications, allows for the investigation of internal structures and/or biological processes within the body for diagnostic, therapeutic and/or research purposes.

MRI provides an attractive imaging modality for biological imaging due to the ability to produce non-invasive images having relatively high resolution and contrast without the safety concerns of other modalities (e.g., without needing to expose the subject to ionizing radiation, e.g., x-rays, or introducing radioactive material to the body). Additionally, MRI is particularly well suited to provide soft tissue contrast, which can be exploited to image subject matter that other imaging modalities are incapable of satisfactorily imaging. Moreover, MR techniques are capable of capturing information about structures and/or biological processes that other modalities are incapable of acquiring.

### SUMMARY

Some embodiments include a gripper comprising a base, a first jaw movably coupled to the base and having first padding disposed on a first surface of the first jaw, a second jaw movably coupled to the base and having second padding disposed on a second surface of the second jaw, and a linear actuator comprising a motor, and at least one lead screw coupled to the motor and to the first and second jaws, such that rotation of the at least one lead screw causes the first jaw and the second jaw to move toward or away from one another along the base, wherein, when the linear actuator rotates the at least one lead screw such that the first and second jaws move towards each other to grip an object disposed between the first and second surfaces, the first and second jaws exert a force of at least 150 lbf on the object.

Some embodiments include a robot comprising a robotic arm comprising a plurality of arm segments independently movable along respective degrees of freedom, including a first arm segment movable along a first degree of freedom, an end effector coupled to the robotic arm and comprising a gripper, the gripper comprising a base, first and second jaws movably coupled to the base, at least one motor, and at least one lead screw coupled to the at least one motor and to the first arm segment, wherein rotation of the at least one lead screw causes the first arm segment to move along the first degree of freedom, wherein the at least one motor is separated from the first and second jaws of the gripper by at least 250 millimeters.

Some embodiments include a system comprising a robot configured to place a plurality of permanent magnets on a ferromagnetic surface in accordance with a permanent magnet layout for a magnetic assembly, the robot comprising a robotic arm comprising multiple arm segments movable along respective degrees of freedom, a gripper comprising a base, and first and second jaws movably coupled to the base, and at least one controller configured to access information specifying the permanent magnet layout, grasp, using the first and second jaws of the gripper, a first permanent magnet from the plurality of permanent magnets, position, using the robotic arm, the first permanent magnet at a location on the ferromagnetic surface in accordance with the permanent magnet layout, and release the first permanent magnet from the gripper after positioning the first permanent magnet.

Some embodiments include a method for placing permanent magnets on a ferromagnetic surface in accordance with a permanent magnet layout for a magnetic assembly using a robot comprising a robotic arm comprising multiple arm segments movable along respective degrees of freedom, and a gripper having a first and second jaw movably coupled to a base of the gripper, the method comprising accessing information specifying the permanent magnet layout for the magnetic assembly, and controlling the robot to grasp, using the first and second jaws of the gripper, a first permanent magnet from a plurality of permanent magnets, position, using the robotic arm, the first permanent magnet at a location on the ferromagnetic surface in accordance with the permanent magnet layout, and release the first permanent magnet from the gripper after positioning the first permanent magnet.

Some embodiments include a computer-readable medium storing instructions that, when executed by an apparatus configured to place permanent magnets on a ferromagnetic surface in accordance with a permanent magnet layout for a magnetic assembly, the apparatus comprising a robot comprising a robotic arm having multiple arm segments movable along respective degrees of freedom, and a gripper having a first and second jaw movably coupled to a base of the gripper, cause the apparatus to perform a process comprising accessing information specifying the permanent magnet layout for the magnetic assembly, controlling the robot to grasp, using the first and second jaws of the gripper, a first permanent magnet from a plurality of permanent magnets, position, using the robotic arm, the first permanent magnet at a location on the ferromagnetic surface in accordance with the permanent magnet layout, and release the first permanent magnet from the gripper after positioning the first permanent magnet.

Some embodiments include a method for assembling a magnetic resonance imaging system, the method comprising: assembling a magnetic assembly, wherein the assembling the magnetic assembly comprises: controlling a robot comprising a robotic arm having multiple arm segments movable along respective degrees of freedom, and a gripper having a first and second jaw movably coupled to a base of the gripper to: grasp, using the first and second jaws of the gripper, a plurality of permanent magnets; and position, using the robotic arm, the plurality of permanent magnets on a ferromagnetic surface; producing a permanent magnet shim based on one or more magnetic field measurements of the magnetic assembly; and assembling the magnetic resonance imaging system using the magnetic assembly and the permanent magnet shim.

### BRIEF DESCRIPTION OF DRAWINGS

Various non-limiting embodiments of the technology will be described with reference to the following figures. It should be appreciated that the figures are not necessarily drawn to scale. Items appearing in multiple figures are indicated by the same reference number in all figures in which they appear.

FIG. 1 illustrates architecture of an example system for assembling a magnet assembly, in accordance with some embodiments of the technology described herein.

FIGS. 2A-2B illustrate hardware module diagrams of the example system of FIG. 1, in accordance with some embodiments of the technology described herein.

FIG. 3 shows an illustrative graphical user interface of the example system of FIG. 1, in accordance with some embodiments of the technology described herein.

FIG. 4A illustrates a perspective view of an illustrative example of a robot configured to assemble a magnet assembly, in accordance with some embodiments of the technology described herein.

FIG. 4B illustrates an enlarged perspective view of the example robot of FIG. 4A, in accordance with some embodiments of the technology described herein.

FIG. 4C-4D illustrate dimensions of the example robot and system of FIG. 4A, in accordance with some embodiments of the technology described herein.

FIGS. 4E1-4E3 illustrate a schematic power control diagram for one or more motors of the example robot of FIG. 4A, in accordance with some embodiments of the technology described herein.

FIG. 4F illustrates an example of a feedback control loop diagram for one or more motors of the example robot of FIG. 4A, in accordance with some embodiments of the technology described herein.

FIG. 4G illustrates a graph measuring motor torque vs. displacement of the example robot of FIG. 4A, in accordance with some embodiments of the technology described herein.

FIG. 4H illustrates a graph measuring motor torque vs. pull force on the example robot of FIG. 4A, in accordance with some embodiments of the technology described herein.

FIGS. 5-10 illustrates additional views of the example robot of FIG. 4A, in accordance with some embodiments of the technology described herein.

FIG. 11A illustrates an illustrative example of a gripper configured to grasp an object, in accordance with some embodiments of the technology described herein.

FIGS. 11B-11C illustrate dimensions of the example gripper of FIG. 11A, in accordance with some embodiments of the technology described herein.

FIGS. 12-14 illustrate additional views of the example gripper of FIG. 11A, in accordance with some embodiments of the technology described herein.

FIG. 15 illustrates a jaw and a drive nut of the example gripper of FIG. 11A, in accordance with some embodiments of the technology described herein.

FIGS. 16 and 17A-17B illustrate a padding of the example gripper of FIG. 11A, in accordance with some embodiments of the technology described herein.

FIG. 18 illustrates a perspective view of the example gripper of FIG. 11A, in accordance with some embodiments of the technology described herein.

FIGS. 19A-19B illustrate examples of alternative embodiments of an example gripper, in accordance with some embodiments of the technology described herein.

FIG. 20 shows an illustrative example of the example gripper of FIG. 11A exerting a clamping force on a load cell, in accordance with some embodiments of the technology described herein.

FIG. 21 shows an illustrative example of the reading of the clamping force exerted on the load cell by the example gripper in FIG. 20, in accordance with some embodiments of the technology described herein.

FIGS. 22A-B illustrate FEM simulations for determining maximum displacement of jaws of example grippers, in accordance with some embodiments of the technology described herein.

FIG. 22C illustrates a FEM simulation for determining stress on jaws of an example gripper, in accordance with some embodiments of the technology described herein.

FIG. 22D illustrates a FEM simulation for determining strain on jaws of an example gripper, in accordance with some embodiments of the technology described herein.

FIG. 23 illustrates an example of an experimental setup used to measure anti-slip force of the example gripper of FIG. 11A, in accordance with some embodiments of the technology described herein.

FIG. 24 illustrates a measured pull force on a magnetic block held by an example gripper without slippage, in accordance with some embodiments of the technology described herein.

FIG. 25 shows an illustrative example of a ring-type magnetic layout for a point-of-care MRI assembled by the example system of FIG. 1, in accordance with some embodiments of the technology described herein.

FIGS. 26A-26B illustrates examples of a B₀ magnet comprising a plurality of concentric permanent magnet rings, each of the rings comprising multiple permanent magnets, in accordance with some embodiments of the technology described herein.

FIG. 26C illustrates an example of a tapered permanent magnet, in accordance with some embodiments of the technology described herein.

FIG. 26D illustrates an example of an assembled magnetic ring formed using the tapered permanent magnets of FIG. 26C, in accordance with some embodiments of the technology described herein.

FIGS. 27A-27B illustrate views of the example gripper of FIG. 11A placing and assembling permanent magnets on a ferromagnetic plate, in accordance with some embodiments of the technology described herein.

FIGS. 27C-27J illustrate an example process of assembling a magnet assembly having a plurality of concentric rings according to a permanent magnet layout, in accordance with some embodiments of the technology described herein.

FIGS. 28-29 illustrate an example permanent magnet layout for a ring-type magnet assembled by the example system of FIG. 1, in accordance with some embodiments of the technology described herein.

FIG. 30 illustrates an example magnet assembly having a ring of permanent magnets in anchoring positions, in accordance with some embodiments of the technology described herein.

FIG. 31 illustrates part of an example magnet assembly having a ring of permanent magnets with a set of permanent magnets placed between permanent magnets already placed in anchoring positions, in accordance with some embodiments of the technology described herein.

FIGS. 32A-32D illustrate flowcharts of illustrative processes for placing permanent magnets on a ferromagnetic plate, in accordance with some embodiments of the technology described herein.

FIG. 33 shows an example of the system of FIG. 1 inserting a permanent magnet between a pair of permanent magnets placed at anchoring positions, in accordance with some embodiments of the technology described herein.

FIG. 34 shows an example of the system of FIG. 1 holding a permanent magnet between a pair of permanent magnets placed in anchoring positions for epoxy hardening, in accordance with some embodiments of the technology described herein.

FIG. 35 shows an example of the system of FIG. 1 releasing a permanent magnet inserted between a pair of permanent magnets placed at anchoring positions, in accordance with some embodiments of the technology described herein.

FIG. 36 illustrates an example of three permanent magnets positioned on a ferromagnetic plate assembled by the example system of FIG. 1, in accordance with some embodiments of the technology described herein.

FIG. 37 illustrates an example of the system of FIG. 1 inserting a permanent magnet between permanent magnets already positioned on a ferromagnetic plate, in accordance with some embodiments of the technology described herein.

FIGS. 38A-38D illustrate aspects of an example monitoring system for monitoring placement of permanent magnets on a ferromagnetic plate, in accordance with some embodiments of the technology described herein.

FIG. 39A illustrates an example model of forces exerted on a permanent magnet during positioning of the permanent magnet in a magnet assembly, in accordance with some embodiments of the technology described herein.

FIG. 39B illustrates an example method of preparing a permanent magnet prior to assembling a magnet assembly, in accordance with some embodiments of the technology described herein.

FIG. 39C illustrates an example method of preparing the example gripper of FIG. 11A prior to assembling a magnet assembly, in accordance with some embodiments of the technology described herein.

FIGS. 40A-40B illustrate example embodiments of a gripper having tapered jaws, in accordance with some embodiments of the technology described herein.

FIGS. 40C-40D illustrate example embodiments of removable holding fixtures for use with systems configured to assemble a magnet assembly, in accordance with some embodiments of the technology described herein.

FIG. 41 illustrates an example gripper having interchangeable jaws, in accordance with some embodiments of the technology described herein.

FIGS. 42A-42B illustrates perspective views of an example rotary mechanism for rotating a yoke of a magnet assembly, in accordance with some embodiments of the technology described herein.

FIG. 42C illustrates a perspective view of a frame of the example rotary mechanism of FIGS. 42A-42B, in accordance with some embodiments of the technology described herein.

FIG. 43A illustrates a perspective view of the example rotary mechanism of FIGS. 42A-42B in combination with the example robot of FIG. 4A, in accordance with some embodiments of the technology described herein.

FIG. 43B illustrates the example rotary mechanism of FIGS. 42A-42B in the process of mounting a yoke of a magnet assembly, in accordance with some embodiments of the technology described herein.

FIGS. 43C-43E illustrate the example rotary mechanism of FIGS. 42A-42B in combination with the example robot of FIG. 4A during a process of assembling a magnet assembly, in accordance with some embodiments of the technology described herein.

FIGS. 44A-44D illustrate an example method for placing permanent magnets onto a yoke of a magnet assembly, in accordance with some embodiments of the technology described herein.

FIGS. 45A-45F illustrate an example method for inserting a permanent magnet onto a yoke of a magnet assembly, in accordance with some embodiments of the technology described herein.

FIG. 46 illustrates an example method for assembling a magnetic resonance imaging system, in accordance with some embodiments of the technology described herein.

FIG. 47 illustrates exemplary components of a magnetic resonance imaging system, in accordance with some embodiments of the technology described herein.

FIGS. 48A-48B illustrate views of an example portable MRI system, in accordance with some embodiments of the technology described herein.

FIG. 48C illustrates another example of a portable MRI system, in accordance with some embodiments of the technology described herein.

### DETAILED DESCRIPTION

Some MRI systems use permanent magnets to generate the main magnetic field (the B₀ field) in which the subject is imaged. Such MRI systems include a magnet assembly in which the permanent magnets are arranged in a particular layout to create a main magnetic (B₀) field having desired characteristics including size, geometry, homogeneity, and strength. A magnet assembly is an assembly that includes one or more magnets (e.g., one or more permanent magnets). Such a magnet assembly may be referred to as a “B₀ magnet assembly” or “B₀ assembly” herein. In addition to permanent magnets, the B₀ magnet assembly may include one or more other components made from ferromagnetic material (e.g., steel, silicone steel, etc.) and/or one or more non-ferromagnetic components (e.g., plastic, fiberglass, etc.).

The inventors have recognized that there are challenges to manufacturing a B₀ magnet assembly in which multiple permanent magnets are positioned according to a specified layout. Each permanent magnet must be positioned precisely without deviating from its specified position in the layout; even a small deviation can dramatically alter the characteristics of the main magnetic field. This precision is especially difficult to achieve due the strong magnetic forces present during assembly including: (1) magnetic forces between a permanent magnet being positioned in the B₀ magnet assembly and neighboring or nearby permanent magnets already positioned in the B₀ magnet assembly; and (2) magnetic forces between a permanent magnet being positioned and one or more other ferromagnetic components of the B₀ magnet assembly (e.g., a ferromagnetic plate on which the permanent magnets may be placed).

Although it is possible to manually assemble permanent magnets into a B₀ magnet assembly, the inventors have recognized that manual assembly has several drawbacks. First, manual positioning and placement of permanent magnets lacks precision and may create inaccuracies in the alignment of the magnets in the B₀ magnet assembly. Second, manual techniques often require the use of specially designed tools and fixtures making manual techniques expensive. The high cost of assembling the B₀ magnet assembly contributes to the overall high cost of the MRI system which limits the accessibility of MRI as an available imaging modality even when the use of MRI would be advantageous. Third, manual assembly techniques are time consuming.

Accordingly, the inventors have developed systems and methods for constructing a B₀ magnet assembly with the requisite precision, more quickly than using manual methods, and at a lower cost than using manual methods. The techniques of constructing B₀ magnet assemblies described herein will allow for increased availability of MRI systems and MRI as an imaging modality. Aspects of the technology described herein may reduce the cost of manufacturing a point-of-care MRI system by up to 50% compared to manual techniques.

Among the multiple innovations described herein, the inventors have developed a robotic system for automating construction of B₀ magnet assemblies.

Novel aspects of the robotic system developed by the inventors include, but are not limited to, the gripper used by the robotic system to grasp permanent magnets, the robotic arm coupled to the gripper, materials used for robotic system components, the design of individual robotic system components, the placement of individual robotic system components within the robotic system, graphical user interfaces for interacting with the robotic system (e.g., for controlling the system, monitoring performance of the system, specifying permanent magnet layout, etc.), and methods for using the robotic system to assemble permanent magnets into specified layouts. These and many other novel aspects of the robotic system are described herein.

In some embodiments, the robotic system for assembling a B₀ magnet includes a robot having a robotic arm and a gripper coupled to the robotic arm. The gripper may be configured to grasp permanent magnets and precisely place them onto a ferromagnetic plate. The robotic arm and the gripper may be configured to move along one or multiple degrees of freedom to position the permanent magnets in accordance with a specified permanent magnet layout.

As part of designing a robotic system for automatically constructing a B₀ magnet assembly from permanent magnets, the inventors have developed a gripper capable of grasping and placing permanent magnets without permitting their slippage during assembly. Such slippage may result from magnetic forces—as described above, a permanent magnet held by the gripper will experience downward force as a result of being pulled toward the ferromagnetic plate onto which the permanent magnet is to be placed and/or lateral forces due to near permanent magnets. Permanent magnets are often prepared to have smooth surfaces with very low coefficients of friction (e.g., to improve the homogeneity of the B₀ magnetic field), which can lead to slippage. The gripper developed by the inventors is designed to avoid slippage by generating a clamping force on the permanent magnet sufficiently high for the gripper to retain the permanent magnet without slippage. In some embodiments, the gripper comprises opposing jaws that are configured to exert a clamping force of at least 150 lbf on the permanent magnet.

Furthermore, the inventors have recognized that the robotic arm of the robot used to position the permanent magnet must be designed such that the robotic arm is capable of withstanding forces from the environment of the magnet assembly. For example, the strong pulling forces generated by components of the magnet assembly as described herein could alter the position of and/or damage the robotic arm. The inventors have recognized that the robotic arm must be robust enough to withstand the high torques experienced by the robotic arm during assembly of the B₀ magnet. In some embodiments, the dimensions of the robotic arm are made sufficiently small such that the torque experienced by the robotic arm due to magnetic pulling forces and the weight of the permanent magnet is minimized.

The inventors have also recognized that components of the robot and gripper could be damaged by the strong magnetic fields generated by components of the magnet assembly present in the vicinity of the robot and gripper. Thus, the inventors have developed various methods to reduce the potential damage caused by the strong magnetic fields, including, for example, constructing at least some (e.g., all) components of the robot and gripper out of non-ferrous materials (e.g., aluminum), separating motors of the robot and gripper from the permanent magnets and magnet assembly by at least a threshold distance, and separating a feed-in area for loading the permanent magnets from the ferromagnetic plate and assembled permanent magnets.

The inventors have also recognized that the precision with which permanent magnets are placed can be improved by using an automated system for positioning and placing the permanent magnets. In some embodiments, the system has at least one controller for positioning the permanent magnets in accordance with a specified magnet layout. In some embodiments, the system includes a graphical user interface (GUI) allowing for user control of the positioning and placement of the permanent magnets, including selection of the specified layout, as described herein. In some embodiments, the system includes a monitoring system having one or more cameras for monitoring the placement of the permanent magnets on the ferromagnetic plate to ensure that the B₀ magnet assembly is being correctly constructed.

Thus, aspects of the present disclosure relate to a gripper, comprising a base; a first jaw movably coupled to the base and having first padding disposed on a first surface of the first jaw; a second jaw movably coupled to the base and having second passing disposed on a second surface of the second jaw; and a linear actuator, comprising a motor, and at least one lead screw coupled to the motor and to the first and second jaws, such that rotation of the at least one lead screw causes the first jaw and the second jaw to move toward or away from one another along the base; wherein, when the linear actuator rotates the at least one lead screw (having a pitch of at least 10 threads per inch, for example) such that the first and second jaws move towards each other to grip an object (e.g., a permanent magnet) disposed between the first and second surfaces, the first and second jaws exert a force (e.g., of at least 150 lbf, at least 200 lbf, between 150 lbf and 250 lbf, etc.) on the object. In some embodiments, the gripper may additionally or alternatively be actuated mechanically (e.g., hydraulically, pneumatically, etc.).

In some embodiments, the first and second jaws are configured to exert the force of at least 150 lbf on the object without deforming the first surface of the first jaw by more than 0.05 millimeters. In some embodiments, the motor is separated from the first and second jaws by at least 250 millimeters.

In some embodiments, the first and second jaws are configured to retain the permanent magnet between the first and second surfaces when a pulling force (e.g., of at least 200 lbf, at least 150 lbf, between 100 lbf and 120 lbf, etc.) is exerted on the permanent magnet in a direction substantially perpendicular to a direction along which the first and second jaws move.

In some embodiments, the first and second jaws comprise non-ferrous material (e.g., aluminum). In some embodiments, the second surface is substantially parallel to and faces the first surface. In some embodiments, the padding comprises silicon rubber. In some embodiments, the padding comprises an etched surface. In some embodiments, the base comprises non-ferrous material.

In some embodiments, the object is a permanent magnet of a plurality of permanent magnets and the gripper further comprises a camera for monitoring placement of the plurality of permanent magnets on a ferromagnetic surface. The camera may be configured to provide a top view of the ferromagnetic surface during placement of the plurality of permanent magnets on the ferromagnetic surface.

In some embodiments, the first and second jaws are self-locking. In some embodiments, the first and second jaws are self-centering. For example, the at least one lead screw may comprise a right-threaded portion and a left-threaded portion and the motor may comprise a single motor configured to drive both of the left- and right-threaded portions such that when the linear actuator rotates the at least one lead screw, the right-threaded portion is rotated a same amount as the left-threaded portion. In some embodiments, the first jaw is coupled to a first drive nut and the second jaw is coupled to a second drive nut, and the first and second drive nuts are coupled to the at least one lead screw.

According to some aspects of the technology, there is provided a robot, comprising a robotic arm comprising a plurality of arm segments independently movable along respective degrees of freedom, including a first arm segment movable along a first degree of freedom; an end effector coupled to the robotic arm and comprising a gripper, the gripper comprising: a base and first and second jaws movably coupled to the base; at least one motor; and at least one screw coupled to the at least one motor and to the first arm segment, wherein rotation of the at least one screw causes the first arm segment to move along the first degree of freedom, wherein the at least one motor is separated from the first and second jaws of the gripper by at least 250 millimeters.

In some embodiments, the at least one motor comprises a plurality of motors, each of the plurality of motors being coupled to a respective arm segment in the plurality of arm segments, and each of the plurality of motors being separated from the first and second jaws of the gripper by at least 250 millimeters.

In some embodiments, the robot further comprises second and third arm segments movable along second and third degrees of freedom, respectively, the second and third arm segments each being coupled to a respective one of the plurality of motors; and second and third screws coupled to the second and third arm segments and their respective motors, wherein rotation of the second screw causes the second arm segment to move along the second degree of freedom, and rotation of the third screw causes the third arm segment to move along the third degree of freedom. In some embodiments, the first, second, and third arm segments are configured to move along substantially perpendicular directions.

In some embodiments, the end effector is configured to move the gripper along at least two additional degrees of freedom distinct from respective degrees of freedom of the plurality of arm segments.

In some embodiments, the at least one screw comprises a pair of screws and the motor is configured to rotate the pair of screws concurrently. In some embodiments, the first arm segment comprises a gantry having a first side and second side, the first side is coupled to a first screw of the pair of screws, and the second side is coupled to a second screw of the pair of screws. The gantry may be configured to slide along a pair of rails.

In some embodiments, the robot further comprises a first gear coupled to the third arm segment, the first gear being configured to rotate the gripper in a first plane defined by the first and second degrees of freedom when the first gear is driven by a first gear motor. In some embodiments, the robot further comprises a second gear coupled to the third arm segment, the second gear being configured to rotate at least part of the third arm segment in a second plane defined by the second and third degrees of freedom when the second gear is driven by a second gear motor. The first and second gear motors may be separated from the first and second jaws of the gripper by at least 250 millimeters.

In some embodiments, the robotic arm comprises non-ferrous material (e.g., aluminum).

In some embodiments, the gripper is configured to grip a first permanent magnet between the first and second jaws and the robot is configured to position the first permanent magnet in accordance with a permanent magnet layout. For example, the robot may be configured to position a plurality of permanent magnets of a ferromagnetic surface at a rate of no more than 3.5 minutes per permanent magnet. In some embodiments, the robot is configured to position a plurality of permanent magnets in accordance with the permanent magnet layout, the permanent magnet layout comprising at least one ring of permanent magnets. The at least one ring may comprise at least 20 permanent magnets. In some embodiments, the permanent magnet layout comprises at least two concentric rings of permanent magnets.

The robot may be configured to position a second permanent magnet in accordance with the permanent magnet layout on a ferromagnetic surface no more than 2 millimeters apart from the first permanent magnet. In some embodiments, the first permanent magnet has a maximum dimension of 80 millimeters or less.

The first permanent magnet may be tapered comprising a first end and a second end opposite the first end, the first end may have a length greater than or equal to 20 millimeters and less than or equal to 50 millimeters, and the second end may have a length greater than or equal to 30 millimeters and less than or equal to 70 millimeters.

In some embodiments, the robot may be configured to position a plurality of permanent magnets in accordance with the permanent magnet layout, the plurality of permanent magnets comprising at least 20 permanent magnets.

In some embodiments, the gripper further comprises at least one linear actuator comprising a gripper motor and at least one screw, wherein when the first and second jaws of the gripper move towards each other to grip an object (e.g., a permanent magnet) disposed between the first and second jaws, the first and second jaws exert a force of at least 150 lbf on the object. In some embodiments, the first and second jaws are configured to exert the force of at least 150 lbf on the object without deforming the first surface of the first jaw by more then 0.05 millimeters. In some embodiments, the gripper comprises first and second paddings disposed on first and second jaws of the gripper, respectively, and the padding comprises silicon. In some embodiments, the first padding comprises an etched surface.

In some embodiments, the robotic arm is configured to withstand a static moment of at least 1000 Nm.

In some embodiments, the robot is coupled to a system base, and the system base is configured to support a ferromagnetic surface and rotate the ferromagnetic surface.

According to some aspects of the technology, there is provided a system, comprising a robot configured to place a plurality of permanent magnets on a ferromagnetic surface in accordance with a permanent magnet layout for a magnetic assembly, the robot comprising: a robotic arm comprising multiple arm segments movable along respective degrees of freedom; a gripper comprising a base, and first and second jaws movably coupled to the base; and at least one controller configured to: (1) access information specifying the permanent magnet layout; (2) grasp, using the first and second jaws of the gripper, a first permanent magnet from the plurality of permanent magnets; (3) position, using the robotic arm, the first permanent magnet at a location on the ferromagnetic surface in accordance with the permanent magnet layout; and (4) release the first permanent magnet from the gripper after positioning the first permanent magnet.

The at least one controller may be further configured to position each of the plurality of permanent magnets, including the first permanent magnet, on the ferromagnetic surface in accordance with the permanent magnet layout. The at least one controller may be configured to position the plurality of permanent magnets on the ferromagnetic surface at a rate of no more than 3.5 minutes per permanent magnet.

In some embodiments, the at least one controller may be configured to position each of the plurality of permanent magnets to form at least one ring of permanent magnets on the ferromagnetic surface. The at least one ring may comprise a plurality of concentric rings of permanent magnets. In some embodiments, the at least one ring may comprise at least 20 permanent magnets.

In some embodiments, the at least one controller is further configured to position, using the robotic arm, a second permanent magnet at a location on the ferromagnetic surface no more than 2 millimeters apart from the first permanent magnet. In some embodiments, the plurality of permanent magnets comprises at least 20 permanent magnets.

In some embodiments, the first permanent magnet has a maximum dimension of 80 millimeters or less. In some embodiments, the first permanent magnet is tapered and comprises a first end and a second end opposite the first end, the first end has a length greater than or equal to 20 millimeters and less than or equal to 50 millimeters, and the second end has a length greater than or equal to 30 millimeters and less than or equal to 70 millimeters.

In some embodiments, the at least one controller is further configured to (1) place the first permanent magnet on the ferromagnetic surface; (2) rotate the ferromagnetic surface; and (3) place a second permanent magnet of the plurality of permanent magnets on the ferromagnetic surface after rotation the ferromagnetic surface.

In some embodiments, the at least one controller is further configured to (1) position a first set of permanent magnets at anchoring positions in a ring layout; and (2) after positioning the first set of permanent magnets, position a second set of permanent magnets at positions between the anchoring positions in the ring layout. The anchoring positions in the ring layout may be equidistance from one another.

In some embodiments, the system further comprises at least one camera for monitoring the placement of the plurality of permanent magnets on the ferromagnetic surface. In some embodiments, the at least one camera comprises a first camera coupled to the gripper and configured to provide a top view of the ferromagnetic surface during placement of the plurality of permanent magnets on the ferromagnetic surface. The at least one camera may further comprise a second camera external to the robot and configured to provide a side view of the ferromagnetic surface during placement of the plurality of permanent magnets on the ferromagnetic surface.

In some embodiments, the robot is configured to determine a series of movements to be performed to place the plurality of permanent magnets on the ferromagnetic surface based on the information specifying permanent magnet layout. In some embodiments, the information specifying permanent magnet layout indicates a series of movements to be performed by the robot to place the plurality of permanent magnets on the ferromagnetic surface.

In some embodiments, the system further comprises a display, and the at least one controller is configured to cause the display to display a graphical user interface (GUI) containing a visualization of the permanent magnet layout.

In some embodiments, the gripper further comprises at least one linear actuator comprising a motor and at least one screw, wherein when the first and second jaws of the gripper move towards each other to grip one of the plurality of permanent magnets disposed between the first and second jaws, the first and second jaws exert a force of at least 150 lbf on the one of the plurality of permanent magnets. In some embodiments, the first and second jaws are configured to exert the force of at least 150 lbf on the one of the plurality of permanent magnets without deforming the first surface of the first jaw by more than 0.05 millimeters.

In some embodiments, the gripper comprises first padding disposed on the first jaw of the gripper, the first padding comprising silicon. In some embodiments, the first padding comprises an etched surface.

In some embodiments, the ferromagnetic surface comprises a first ferromagnetic surface and a second ferromagnetic surface disposed above the first ferromagnetic surface; and the system further comprises a frame coupled to the first and second ferromagnetic surfaces and configured to rotate the first and second ferromagnetic surfaces such that, subsequent to rotating the first and second ferromagnetic surfaces, the second ferromagnetic surface is disposed below the first ferromagnetic surface.

According to some aspects of the technology, there is provided a method for placing permanent magnets on a ferromagnetic surface in accordance with a permanent magnet layout for a magnetic assembly using a robot comprising a robotic arm comprising multiple arm segments movable along respective degrees of freedom, and a gripper having a first and second jaw movably coupled to a base of the gripper, the method comprising: accessing information specifying the permanent magnet layout for the magnetic assembly; and controlling the robot to: (1) grasp, using the first and second jaws of the gripper, a first permanent magnet from a plurality of permanent magnets; (2) position, using the robotic arm, the first permanent magnet at a location on the ferromagnetic surface in accordance with the permanent magnet layout; and (3) release the first permanent magnet from the gripper after positioning the first permanent magnet.

In some embodiments, controlling the robot to position the first permanent magnet comprises moving the first permanent magnet in at least one of four degrees of freedom.

In some embodiments, the method further comprises loading the first permanent magnet into a feeding area isolated from the ferromagnetic surface before controlling the robot to grasp the first permanent magnet.

In some embodiments, the method further comprises causing the ferromagnetic surface to rotate using a motor coupled to the ferromagnetic surface after releasing the first permanent magnet from the gripper.

In some embodiments, the method further comprises controlling the robot to place a first plurality of permanent magnets on the ferromagnetic surface and then controlling the robot to place one or more permanent magnets in a second plurality of permanent magnets between each of the permanent magnets in the first plurality of permanent magnets.

In some embodiments, the method further comprises adding one or more plastic shims to the first permanent magnet before controlling the robot to grasp the first permanent magnet.

In some embodiments, the ferromagnetic surface comprises a first ferromagnetic surface and a second ferromagnetic surface disposed above the first ferromagnetic surface and the method further comprises rotating the first and second ferromagnetic surfaces such that, subsequent to the rotating, the second ferromagnetic surface is disposed below the first ferromagnetic surface.

According to some aspects of the technology, there is provided a computer-readable medium storing instructions that, when executed by an apparatus configured to place permanent magnets on a ferromagnetic surface in accordance with a permanent magnet layout for a magnetic assembly, the apparatus comprising a robot comprising a robotic arm having multiple arm segments movable along respective degrees of freedom, and a gripper having a first and second jaw coupled to a base of the gripper, cause the apparatus to perform a process comprising: accessing information specifying the permanent magnet layout for the magnetic assembly; and controlling the robot to: (1) grasp, using the first and second jaws of the gripper, a first permanent magnet from a plurality of permanent magnets; (2) position, using the robotic arm, the first permanent magnet at a location on the ferromagnetic surface in accordance with the permanent magnet layout; and (3) release the first permanent magnet from the gripper after positioning the first permanent magnet.

According to some aspects of the technology, there is provided a method for assembling a magnetic resonance imaging system, the method comprising: (1) assembling magnetic assembly, wherein the assembling the magnetic assembly comprises controlling a robot comprising a robotic arm having multiple arm segments movable along respective degrees of freedom, and a gripper having a first and second jaw movably coupled to a base of the gripper to: (a) grasp, using the first and second jaws of the gripper, a plurality of permanent magnets; and (b) position, using the robotic arm, the plurality of permanent magnets on a ferromagnetic surface; (2) producing a permanent magnet shim based on one or more magnetic field measurements of the magnetic assembly; and (3) assembling the magnetic resonance imaging system using the magnetic assembly and the permanent magnet shim.

In some embodiments, the method further comprises coupling one or more additional magnetics components to the magnetic resonance imaging system, the one or more additional magnetics components comprising at least one radio-frequency coil configured to, when operated, transmit radio frequency signals to a field of view of the magnetic resonance imaging system and/or to respond to magnetic resonance signals emitted from the field of view.

In some embodiments, the one or more additional magnetics components further comprise a plurality of gradient coils configured to, when operated, generate magnetic fields to provide spatial encoding of emitted magnetic resonance signals.

In some embodiments, producing the permanent magnet shim to the B₀ magnet comprises: (1) determining deviation of a B₀ field generated by the magnetic assembly from a desired B₀ field; (2) determining a magnetic pattern that, when applied to magnetic material of the magnetic assembly, produces a corrective magnetic field that corrects for at least some of the determined deviation; and (3) applying the magnetic pattern to the magnetic material of the magnetic assembly to produce the shim.

In some embodiments, coupling the one or more additional magnetics components to the magnetic resonance imaging system comprises mechanically coupling the one or more additional components to the magnetic resonance imaging system. In some embodiments, coupling the one or more additional magnetics components to the magnetic resonance imaging system comprises electrically coupling the one or more additional components to the magnetic resonance imaging system.

In some embodiments, assembling the magnetic assembly further comprises accessing information specifying a permanent magnet layout for the plurality of permanent magnets, and positioning the plurality of permanent magnets on the ferromagnetic surface comprises positioning the plurality of permanent magnets on the ferromagnetic surface in accordance with the permanent magnet layout.

In some embodiments, positioning the plurality of permanent magnets on the ferromagnetic surface comprises: (1) placing a first permanent magnet of the plurality of permanent magnets on the ferromagnetic surface; (2) rotating the ferromagnetic surface; and (3) placing a second permanent magnet of the plurality of magnets on the ferromagnetic surface subsequent to rotating the ferromagnetic surface.

In some embodiments, the ferromagnetic surface comprises a first ferromagnetic surface and a second ferromagnetic surface disposed above the first ferromagnetic surface, and positioning the plurality of permanent magnets on the ferromagnetic surface comprises: (1) placing a first permanent magnet of the plurality of permanent magnets on the first ferromagnetic surface; (2) rotating the first and second ferromagnetic surfaces such that the second ferromagnetic surface is disposed below the first ferromagnetic surface; and (3) subsequent to the rotating, placing a second permanent magnet of the plurality of permanent magnets on the second ferromagnetic surface.

The aspects and embodiments described above, as well as additional aspects and embodiments, are described further below. These aspects and/or embodiments may be used individually, all together, or in any combination, as the technology is not limited in this respect.

A “permanent magnet” may be any object or material that maintains its own persistent magnetic field once magnetized. Materials that can be magnetized to produce a permanent magnet are referred to herein as “ferromagnetic” and include, as non-limiting examples, iron, nickel, cobalt, neodymium (NdFeB) alloys, samarium cobalt (SmCo) alloys, alnico (AlNiCo) alloys, strontium ferrite, barium ferrite, etc. While NdFeB produces higher field strengths (and in general is less expensive than SmCo), SmCo exhibits less thermal drift and thus provides a more stable magnetic field in the face of temperature fluctuations. Other types of permanent magnet material(s) may be used as well, as the aspects are not limited in this respect. In general, the type or types of permanent magnet material utilized will depend, at least in part, on the field strength, temperature stability, weight, cost and/or ease of use requirements of a given B0 magnet implementation.

Permanent magnet material (e.g., magnetizable material that has been driven to saturation by a magnetizing field) retains its magnetic field when the driving field is removed. The amount of magnetization retained by a particular material is referred to as the material's remanence. Thus, once magnetized, a permanent magnet generates a magnetic field corresponding to its remanence, eliminating the need for a power source to produce the magnetic field. In the embodiments described herein, the permanent magnets are magnetized prior to assembling the magnet assembly.

In some embodiments, a permanent magnet may be a solid object or have a hollow portion. A permanent magnet may be manufactured from any suitable material or materials, including any of the materials described herein. In some embodiments, a coating may be applied to a permanent magnet, as described herein. For example, a phosphate passivation coating may be applied to a permanent magnet which is used to assemble a B₀ magnet assembly for a MRI system.

A permanent magnet may be of any suitable shape, non-limiting examples of which include rectangular, trapezoidal, triangular or wedge-shaped, cylindrical, tapered, etc. The inventors have recognized that certain shapes of a permanent magnet may be advantageous for various reasons, including the requirements of the specified magnet layout, the configuration of the robot and the gripper, and desired characteristics of the magnet assembly and the resulting B₀ field. Examples of such shapes are described herein.

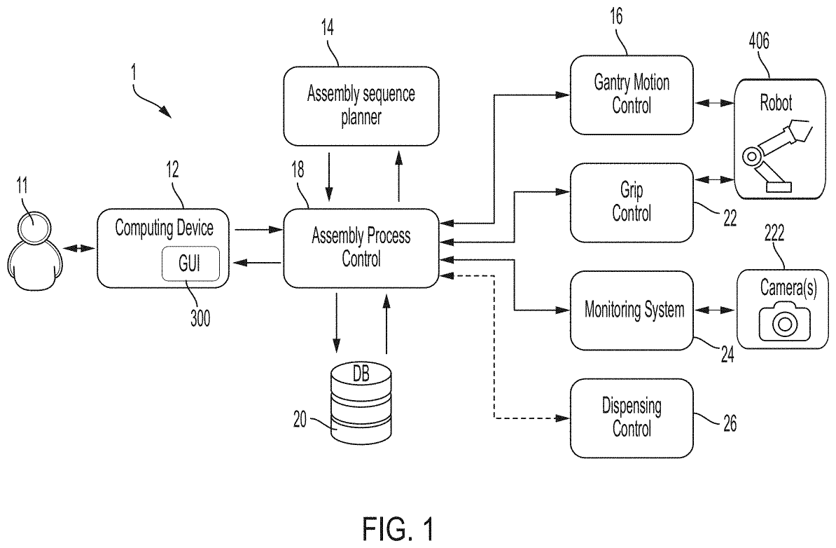

FIG. 1 illustrates architecture of an example system 1 for assembling a magnet assembly, in accordance with some embodiments of the technology described herein. As shown in FIG. 1, system 1 includes a graphical user interface (GUI) 12, assembly sequence planner 14, gantry motion control 16, assembly process control 18, data store 20, gripper control 22, robot 406, monitoring system 24, one or more cameras 222, and dispensing control 26. Each of the components of system 1 described herein may communicate with one or more other components of the system 1. It should be recognized that system 1 is illustrative and that the system may have one or more other components of any suitable type in addition to or instead of the components illustrated in FIG. 1. A system for assembling a magnet assembly may generally comprise the components illustrated in FIG. 1, though the implementation of these components for a particular system may differ vastly, as discussed in further detail herein.

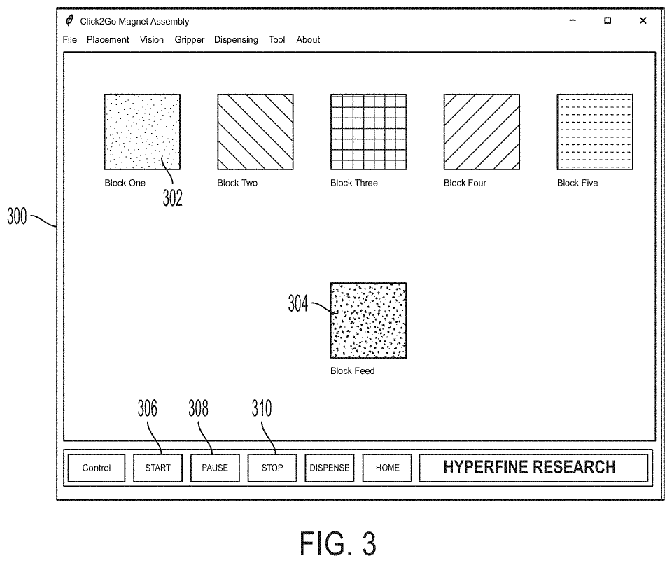

As shown in FIG. 1, system 1 may comprise a computing device 12 (e.g., a laptop, a computer coupled to a monitor, a tablet, etc.). In some embodiments, computing device 12 includes a display and at least one controller (e.g., controller 228) is configured to cause the display to display a graphical user interface (e.g., GUI 300) containing a visualization of aspects of the magnet assembly and/or the process of assembling the permanent magnets. For example, a user may control system 1 and/or monitor performance of system 1 via the GUI 300. The GUI 300 is described herein including with reference to FIG. 3.

In some embodiments, data store 20 may be configured to store information specifying a permanent magnet layout for a B₀ magnet assembly. Examples of specified layouts which can be stored in the data store 20 are described herein. In some embodiments, the information specifying a permanent magnet layout indicates a series of movements to be performed by the robot to place the magnetic blocks on a ferromagnetic plate part of the assembly. In some embodiments, the robot can be configured to determine the series of movements to be performed to place the magnetic blocks on the ferromagnetic plate based on the information specifying magnetic block layout, for example, using at least one controller of the system 1. For example, the assembly sequence planner 14 and assembly process control 18 can be configured to determine, communicate, and/or execute the series of movements to be performed by the robot to place the permanent magnets on the ferromagnetic plate.

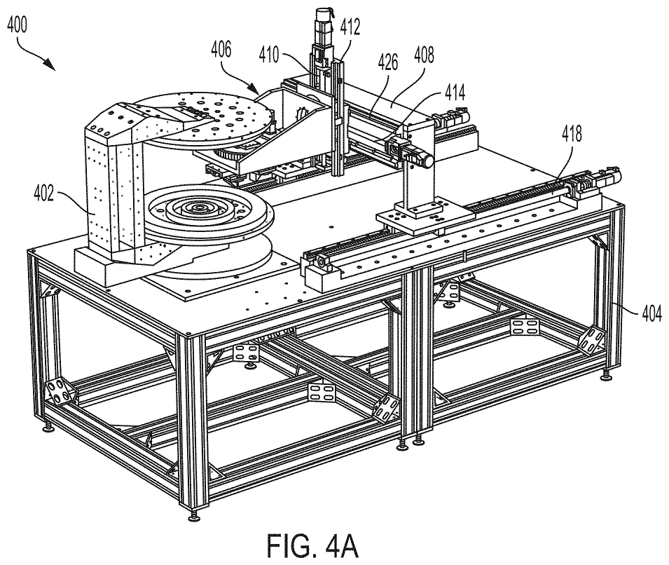

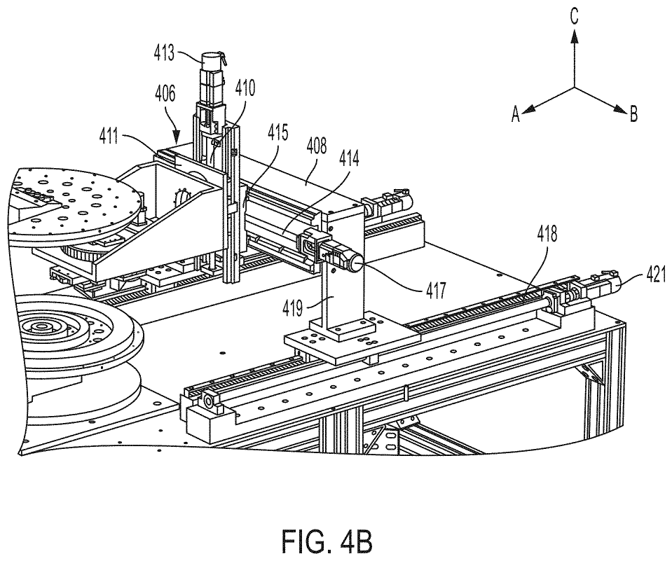

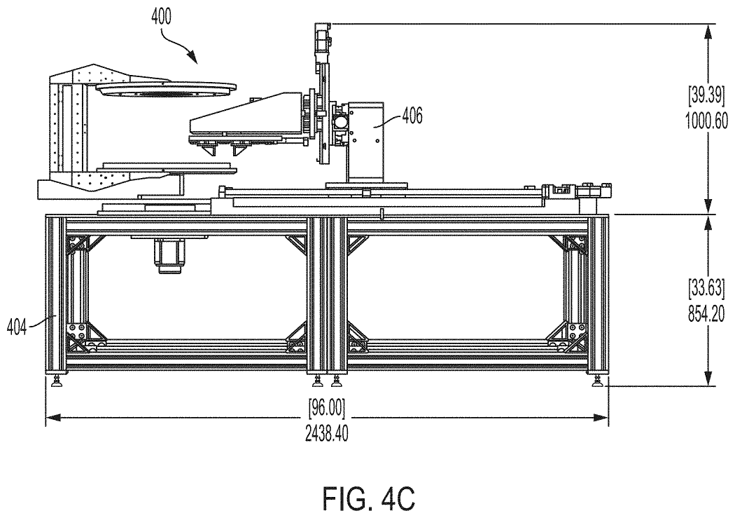

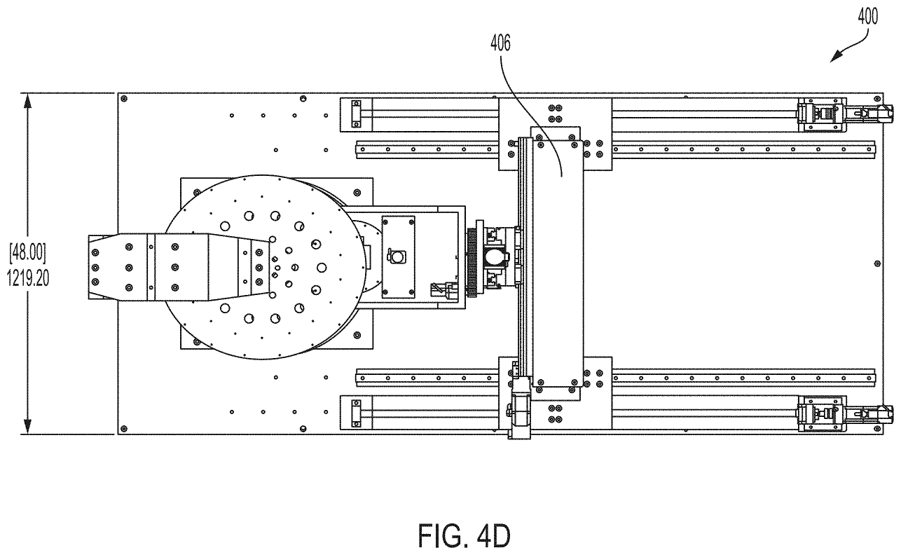

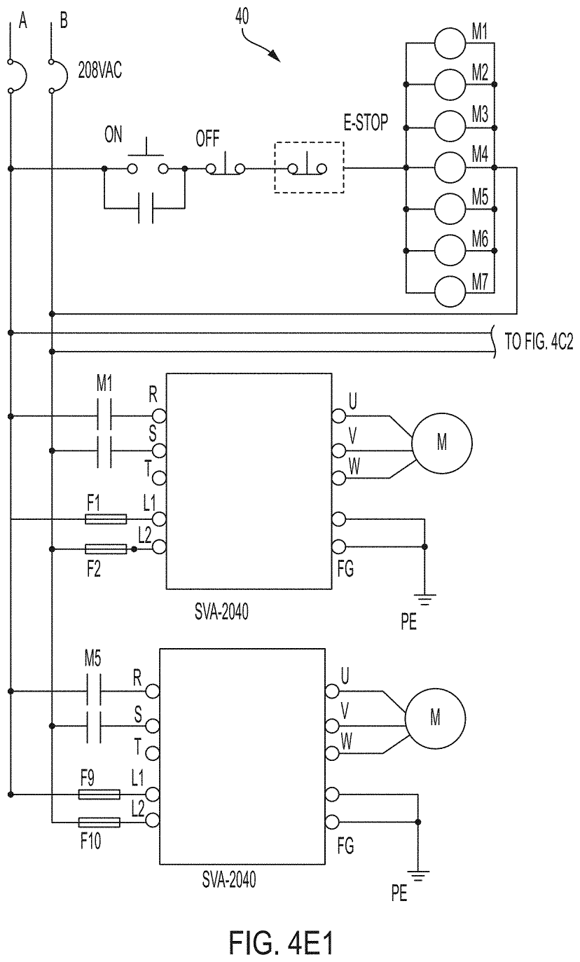

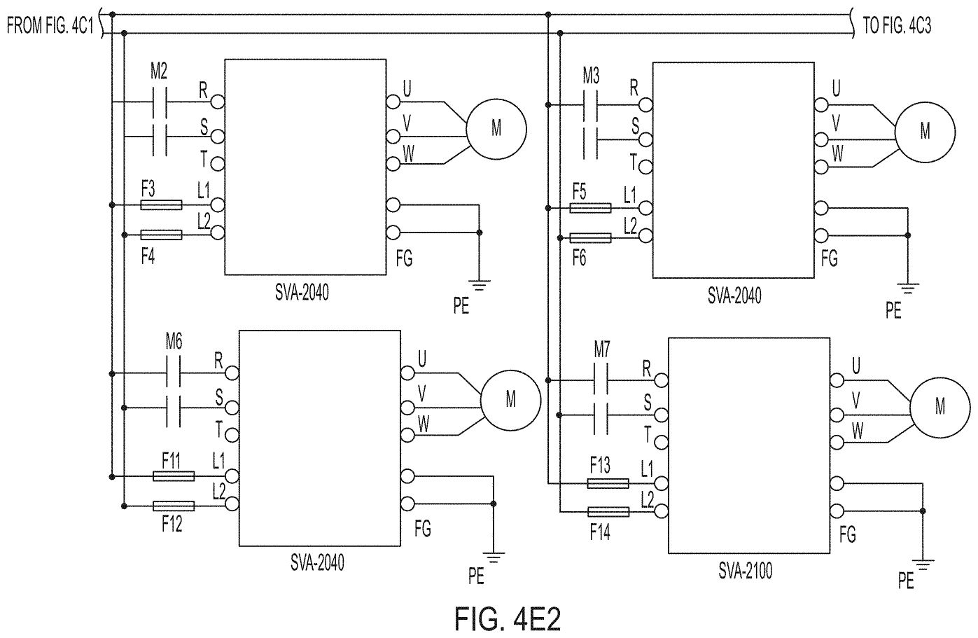

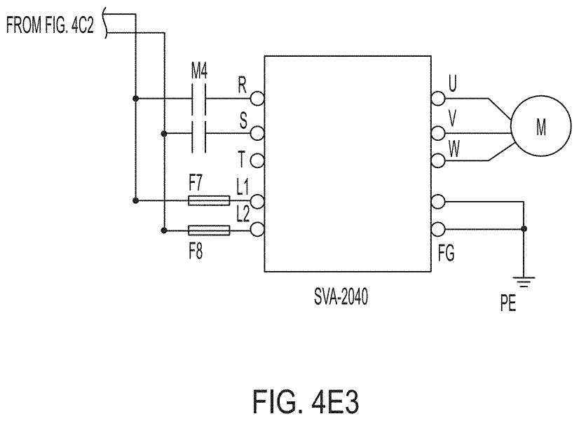

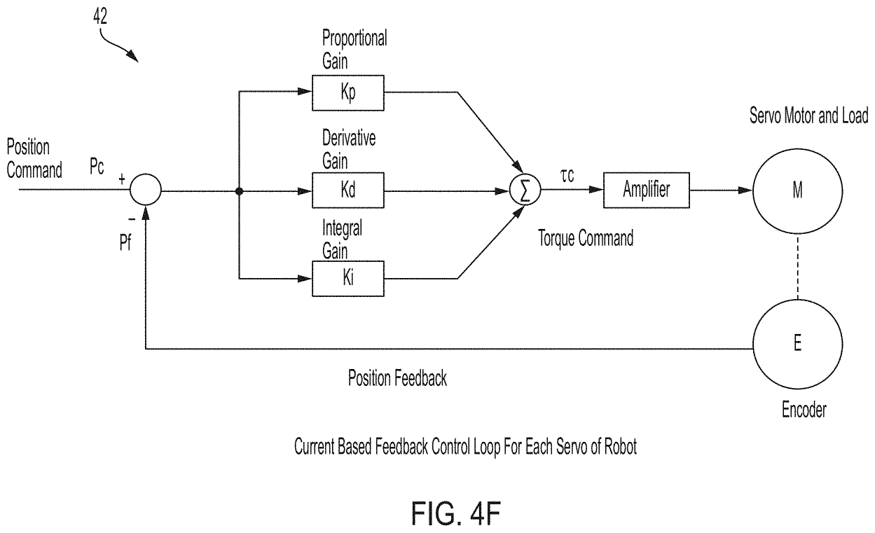

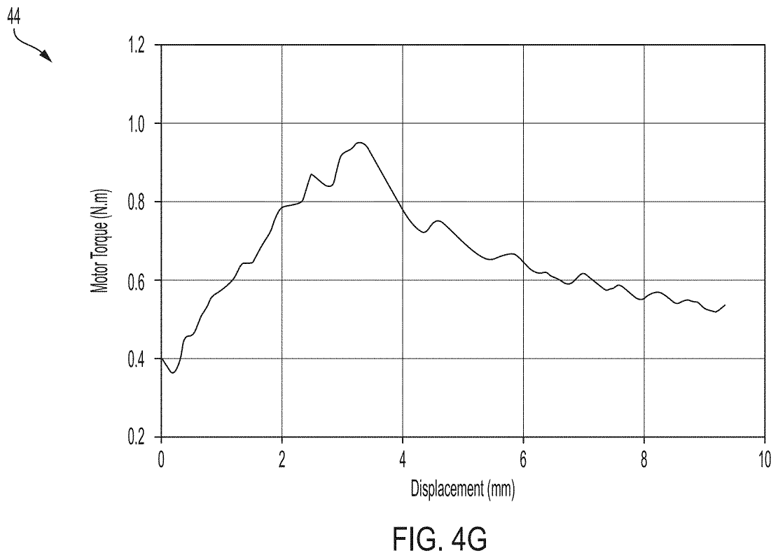

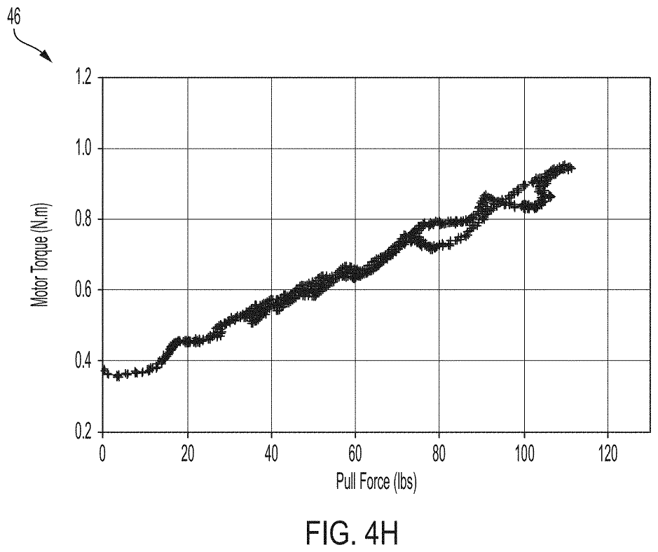

Robot 406, shown further, for example, in FIG. 4A, may include a robotic arm and a gripper coupled to the robotic arm. The gripper may be configured to grasp permanent magnets for assembling a magnetic assembly. The robotic arm may include multiple segments, one of which may be a gantry configured to slide along rails. Gantry motion control 16, grip control 22, and dispensing control 26 may be configured to control aspects of the robot 406 and the gripper. For example, in some embodiments, gantry motion control 16 may be configured to control a robotic arm of the robot and gripper control 22 may be configured to control jaws of the gripper. In some embodiments, dispensing control 26 may be configured to control the loading of a permanent magnet into a feed-in area, as described herein. In some embodiments, the gantry motion control 16, grip control 22, and dispensing control 26 may each comprise an individual controller. In other embodiments, two or more of the gantry motion control 16, grip control 22, and dispensing control 26 may be implemented using a single shared controller.

In some embodiments, system 1 includes a monitoring system 24 for monitoring the assembly of a B₀ magnet. As will be described herein, monitoring system 24 may comprise one or more cameras 222 for monitoring the positioning and placement of the permanent magnets on the ferromagnetic plate.

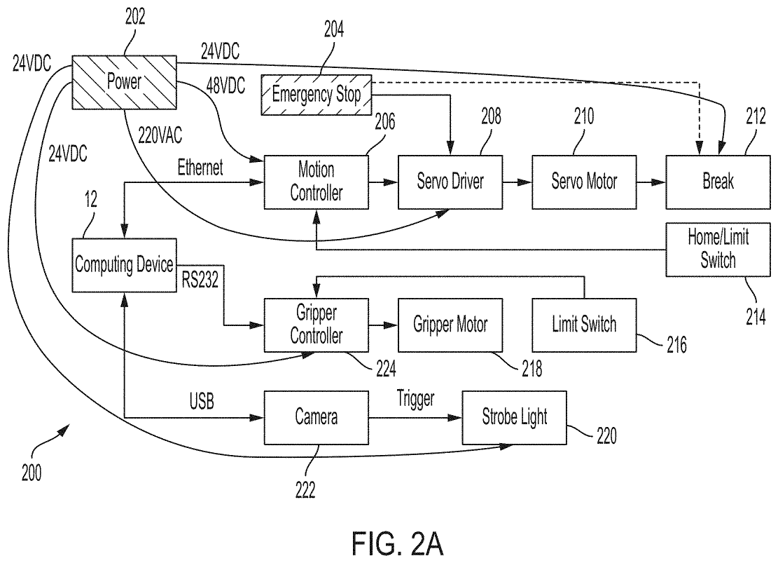

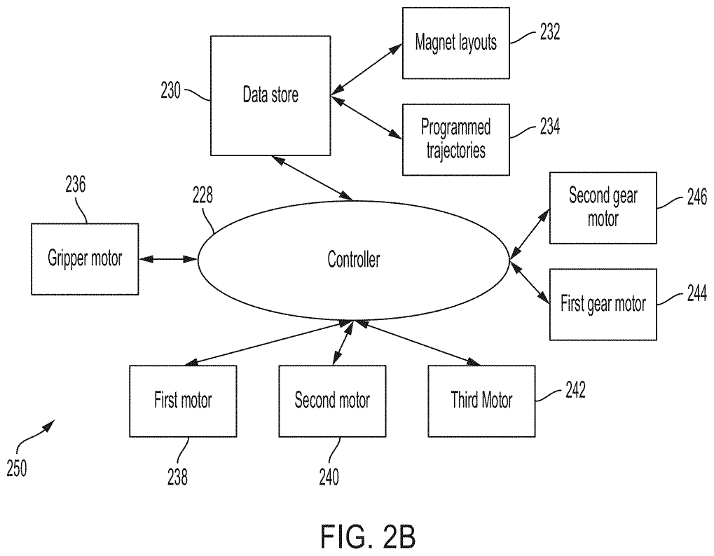

FIGS. 2A-2B illustrate hardware module diagrams of the example system of FIG. 1, in accordance with some embodiments of the technology described herein. For example, in FIG. 2A, the hardware module 200 comprises power 202, emergency stop 204, motion controller 206, servo driver 208, servo motor 210, break 212, limit switches 214 and 216, gripper motor 218, strobe light 220, camera 222, gripper controller 224, and computing device 12. Each of the components illustrated in FIG. 2A may be configured to communicate with one or more other components of the system 1.

Power 202 is configured to provide power to electronic components of the system 1. Power 202 may comprise one or more sources of power for the components of system 1. As shown in FIG. 2A and described herein, including with respect to FIG. 4E1-4E3, the voltage provided to a component of system 1 by power 202 may vary depending on the type of component and the function of the component.

Emergency stop 204, in some embodiments, may provide a means of immediately stopping drive motion by robot 406 of the system 1 by communicating with the servo driver 208. In some embodiments, the emergency stop 204 may be triggered automatically upon the occurrence of certain conditions of the system 1. In some embodiments, emergency stop may be configured to be triggered by a user 11.

Motion controller 206 may be configured to facilitate motion of robot 406 of the system 1 by decoding instructions from a computing device 12 and communicating instructions to the servo driver 208.

Servo driver 208 may be configured to drive servo motor 210 based on instructions from motion controller 206.

Servo motor 210 may be configured to drive components of robot 406 of system 1 based on signals from servo driver 208.

Break 212 and limit switches 214 and 216 may be configured to provide feedback to system 1 regarding position of robot 406 and/or a gripper of system 1.

Gripper controller 224 may be configured to facilitate motion of a gripper of system 1 by decoding instructions from a computing device 12 and communicating instructions to a gripper motor 218.

Gripper motor 218 may be configured to drive components of a gripper of system 1.

Computing device 12 may be configured to give instructions to components of the system 1. In some embodiments, the instructions provided by computing device 12 may be provided by a user.

Camera 222 and strobe light 220 may be implemented as components of monitoring system 24 as described further herein.

In FIG. 2B, the hardware module 250 comprises controller 228, data store 230, magnetic block layouts 232, programmed trajectories 234, gripper motor 236, first motor 238, second motor 240, third motor 242, first gear motor 244, and second gear motor 246. As shown in FIG. 2B, the system 1 may comprise several motors configured to facilitate movement of robot 406 and a gripper. In some embodiments, one or more motors of the technology described herein may be a servo motor. Servo motors allow for more precise control of the motion of the system for assembling a magnet assembly described herein.

Controller 228 may be a hardware module (e.g. one or more processors, circuitry implemented via one or more Field Programmable Gate Arrays (FPGAs), an application-specific integrated circuit (ASICs)) and/or any other suitable circuitry configured to perform the functions of controller 228 described herein.

As shown in FIG. 2B, various components of the hardware module may be configured to communicate with each other. For example, the controller 228 may be configured to communicate with each of the motors of the system to control the movement of the gripper and robot 406. Furthermore, controller 228 may be configured to communicate with data store 230. As described herein, data store 230 may comprise information specifying a permanent magnet layout 232. In some embodiments, data store 230 stores information regarding characteristics of the magnet assembly (e.g. dimensions of the magnet assembly). In some embodiments, the data store 230 further stores a series of movements to be performed by the robot to place the permanent magnets on the ferromagnetic plate, also referred to herein as programmed trajectories 234. The controller 228 may use the information specifying permanent magnet layout 232 and/or the programmed trajectories 234 to control one or more of the motors described herein.

In some embodiments, controller 228 may be configured to control monitoring system 24, including one or more of the cameras 222 of monitoring system 24.

FIG. 3 shows an illustrative graphical user interface 300 of the example system of FIG. 1, in accordance with some embodiments of the technology described herein. In some embodiments, a user 11 may control, monitor, and/or otherwise interact with the system 1 via the GUI 300.

In some embodiments, the GUI 300 can receive various types of input from a user 11. For example, user 11 can interact with the GUI 300 using any suitable input device (e.g., a keyboard, mouse, and/or touch screen) of the computing device 12. In some embodiments, the GUI 300 comprises several options for user input to control the assembly of the B₀ magnet. For example, the GUI 300 may comprise a start button 306 which allows a user to initiate assembly of the B₀ magnet. In some embodiments, the GUI 300 may include a pause button 308 which allows a user to temporarily pause assembly of the B₀ magnet. Further still, in some embodiments, the GUI may include a stop button 310 which allows a user to stop the assembling of the B₀ magnet.

The GUI 300 may include one or more buttons for initiating assembly of individual permanent magnets. For example, the user may initiate assembly of a first permanent magnet using button 302. In the embodiment of FIG. 3, five individual block buttons for controlling the assembly of individual permanent magnets are shown. However, GUI 300 may have any number of individual block buttons for controlling the placement of individual permanent magnets, as aspects of the technology described herein are not limited in this respect.

In some embodiments, the system 1 may be configured to determine how many individual block buttons to display on the GUI 300 based at least in part on the information specifying a permanent magnet layout 232. For example, the permanent magnet layout 232 may be representative of a magnet assembly having a certain number of permanent magnets, and the GUI 300 may be configured to display individual block buttons for each of the permanent magnets in the permanent magnet layout 232.

In some embodiments, the GUI 300 may further include a block feed button 304 for controlling the feeding of a next permanent magnet. In some embodiments, the block feed button 304 may control the system to return to a position to grasp another permanent magnet. In some embodiments, the block feed button 304 may control the loading of the next permanent magnet into a feeding area. In some embodiments the loading of the next permanent magnet into a feeding area may be performed manually. In other embodiments, the loading of the next permanent magnet into a feeding area may be performed by an external robotic device, including, for example, a multi-axis standard robot. In other embodiments, the loading of a next permanent magnet into a feeding area may be performed by the system 1 itself.

In some embodiments, the GUI 300 may allow a user 11 to view and/or control several additional aspects of the magnet assembly process. For example, the GUI 300 may allow the user 11 to select from among multiple permanent magnet layouts 232 to be assembled. In some embodiments, the user 11 can specify and/or define a custom layout using the GUI 300. In some embodiments, the GUI 300 may allow a user to view images and/or video of the magnet assembly process generated by one or more cameras 222 of the system 1. In some embodiments, the GUI 300 may display images and/or video allowing a user 11 to monitor the placement of the permanent magnets on the ferromagnetic plate so that the user 11 can determine how well the placement of the permanent magnets conform to a specified permanent magnet layout. For example, in some embodiments, the system 1 may compute deviations from the permanent magnet layout using data gathered by the one or more cameras 222 of the system 1, as described herein. In some embodiments, the GUI can provide the computed information regarding deviations from the permanent magnet layout to a user 11 to specify whether placement of the permanent magnets conform to the permanent magnet layout. In some embodiments, the computed information regarding deviations from the permanent magnet layout may allow for a deviation tolerance indicating an acceptable amount of deviation between the actual positioning of the permanent magnets and the positioning of the permanent magnets in the specified permanent magnet layout. In some embodiments, a user 11 may set a custom deviation tolerance indicating an acceptable amount of deviation between the actual positioning of the permanent magnets and the positioning of the permanent magnets in the specified permanent magnet layout.

FIGS. 4A-4D and 5-10 show an example of a robot of system 1 configured to assemble a magnet assembly, in accordance with some embodiments of the technology described herein. As shown in FIGS. 4A-4B, system 400 comprises robot 406 comprising a robotic arm 408 configured to position an object. In some embodiments, the robotic arm is configured to position or more permanent magnets in a magnet assembly according to a permanent magnet layout.

In some embodiments, robotic arm 408 may be configured to move along one or more distinct degrees of freedom so as to position permanent magnet in a magnet assembly according to a specified magnet layout. In the embodiments illustrated in FIGS. 4A-D and 5-10, the robot 406 is configured to move along at least three degrees of freedom. For example, a first degree of freedom can include movement along a longitudinal axis labeled “A” in FIG. 4B. A second degree of freedom can include movement along a lateral axis labeled “B” in FIG. 4B. A third degree of freedom can include movement along a transverse axis labeled “C” in FIG. 4B. In some embodiments, the A, B, and C axes are substantially perpendicular to each other.

In some embodiments, the one or more distinct degrees of freedom include rotation in one or more planes of rotation. In some embodiments, a first plane of rotation can be defined by the longitudinal and lateral axes (the “AB” plane, otherwise referred to herein as rotation about the C axis). In some embodiments, a second plane of rotation can be defined by the lateral and transverse axes (the “BC” plane, otherwise referred to herein as rotation about the A axis).

Robot 406 can be configured move along and/or rotate in any number and any combination of degrees of freedom, and aspects of the technology described herein are not limited in this respect. For example, in some embodiments, the robot 406 may be configured to move along and/or rotate in only some of the degrees of freedom described herein. In other embodiments, the robot 406 may be configured to move along and/or rotate in at least the degrees of freedom described herein. In some embodiments, the robot 406 may be configured to move in alternative and/or additional directions. For example, additional and/or alternative directions may or may not be substantially perpendicular to the A, B, and C axes defined herein. Furthermore, the robot 406 can be configured to rotate in planes defined by any of the axes described herein or other axes, whether or not the robot 406 is capable of linear motion in those axes. The inventors have recognized that a robot capable of moving in the various directions described herein may enable quicker and more precise placement of permanent magnets in a magnet assembly.

As shown in FIG. 4B, for example, the robot 406 may comprise a robotic arm 408 comprising a plurality of arm segments. For example, the robotic arm 408 may comprise a first arm segment 419, a second arm segment 415, and a third arm segment 411. In some embodiments, each of the first arm segment 419, second arm segment 415, and the third arm segment 411 may be configured to move independently along a respective degree of freedom. For example, in some embodiments, the first arm segment 419 may be configured to move along the “A” axis, the second arm segment 415 may be configured to move along the “B” axis, and the third arm segment 411 may be configured to move along the “C” axis.

In some embodiments, the first, second, and third arm segments 419, 415, 411 may be mechanically coupled to each other and may be configured to move along respective degrees of freedom when another of the arm segments moves along the respective degrees of freedom. For example, in the illustrated embodiment, the second arm segment 415 is coupled to the first arm segment 419 such that the second arm segment 415 is configured to move along the A axis when the first arm segment 419 moves along the A axis. The second arm segment 415 is configured to move along the B axis independently of the first arm segment 419. The third arm segment 411 is coupled to the second arm segment 415, such that the third arm segment 411 is configured to move along the B axis when the second arm segment 415 moves along the B axis. In addition, the third arm segment 411 is configured to move along the A axis when the first and second arm segments 419, 415 move along the A axis. In addition, the third arm segment 411 may be configured to move along the C axis independently of both the first and second arm segments 419, 415. In this respect, the first, second, and third arm segments 419, 415, 411 of the robotic arm 408 may be configured to move along the respective A, B, and C axes together as well as independently of each other.

In some embodiments, robot 406 may include one or more linear actuators configured to move the robotic arm 408. For example, in some embodiments, the linear actuator may include at least one motor and at least one lead screw coupled to the motor. In some embodiments, the linear actuator may be configured to rotate the at least one lead screw using the at least one motor. In other embodiments, the actuator may be a hydraulic actuator, a pneumatic actuator, or any other suitable type of linear actuator, as aspects of the technology described herein are not limited in this respect.

In the illustrative embodiment shown in FIG. 4B, the robot 406 comprises a first motor 421 and first lead screw 418 coupled to the first motor 421. The first arm segment 419 is coupled to the first lead screw 418 such that rotation of the first lead screw 418 by the first motor 421 causes the first arm segment 419 to move along a first degree of freedom. For example, movement along the first degree of freedom in the illustrated embodiment comprises movement along the longitudinal axis labeled as the A axis in FIG. 4B.

In some embodiments, the robot 406 further comprises a second motor 416 and a third motor 413. In the illustrated embodiment, the second motor 416 is coupled to a second lead screw 414 and the third motor 413 is coupled to a third lead screw 410. Although, in the illustrated embodiment the first lead screw 418, the second lead screw 414, and the third lead screw 410 each have an individual motor coupled to and configured to rotate the lead screw, in other embodiments, one or more motors may be configured to be coupled to and rotate multiple of the first lead screw 418, the second lead screw 414, and/or the third lead screw 410. Further still, the robot 406 may be implemented having additional motors other than those described herein.

The second lead screw 414 may be coupled to the second arm segment 415 and the second motor 416 may be configured to rotate the second lead screw 414 such that the second arm segment 415 is configured to move along a respective degree of freedom when the second lead screw 414 is rotated. For example, in the illustrated embodiment, the second arm segment 415 is configured to move along a lateral axis labeled the “B” axis in FIG. 4B, when the second motor 416 rotates the second lead screw 414.

The third lead screw 410 may be coupled to the third arm segment 411 and the third motor 413 may be configured to rotate the third lead screw 410 such that the third arm segment 411 is configured to move along a respective degree of freedom when the third lead screw 410 is rotated. For example, in the illustrated embodiment, the third arm segment 411 is configured to move along a transverse axis, labeled the “C” axis in FIG. 4B, when the third motor 413 rotates the third lead screw 410.

Each of the first lead screw 418, the second lead screw 414, and the third lead screw 410 may have a tightly spaced thread. The pitch of a screw refers to the distance between the screw's threads. In some embodiments, the pitch of the first lead screw 418, the second lead screw 414, and the third lead screw 410 is 5 mm or less. In some embodiments, the pitch of one or more of the first lead screw 418, the second lead screw 414, and the third lead screw 410 may vary from other lead screws of the robot 406.

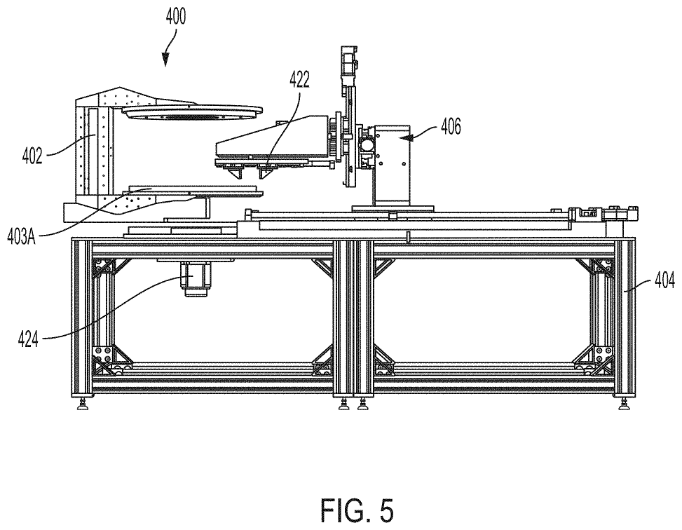

FIG. 5 illustrates a side view of the robot 406, in accordance with some embodiments of the technology described herein.

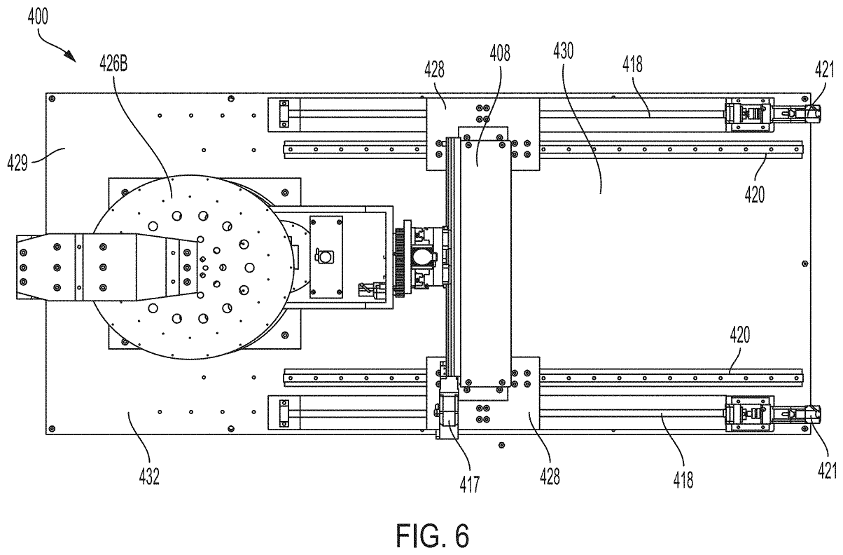

FIG. 6 illustrates a top view of the robot 406, in accordance with some embodiments of the technology described herein. In some embodiments, for example, as shown in FIG. 6, the first arm segment 419 may comprise one or more plates 428 coupled to the first lead screw 418 and configured to slide along the first lead screw. The one or more plates 428 may facilitate coupling of the first arm segment 419 to the first lead screw 418 as described herein.

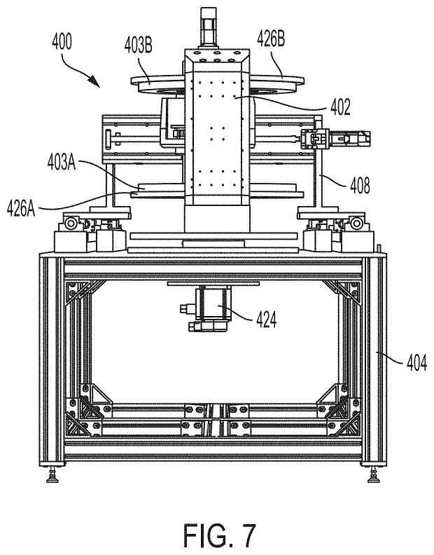

FIG. 7 illustrates a front view of the robot 406, in accordance with some embodiments of the technology described herein.

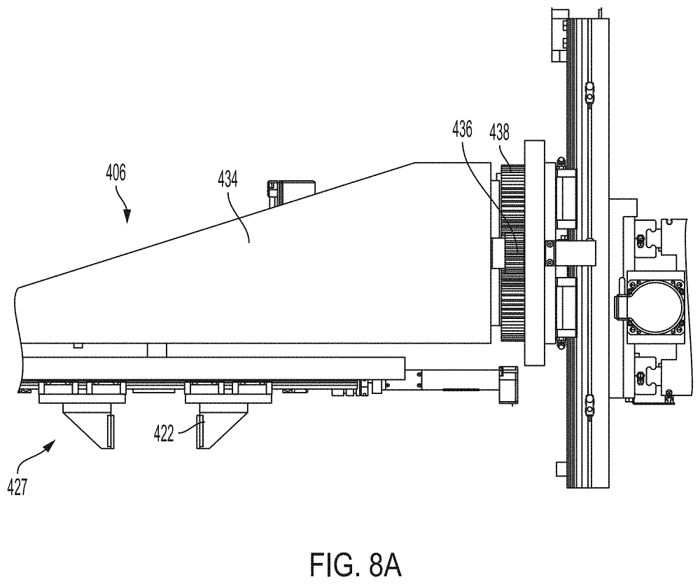

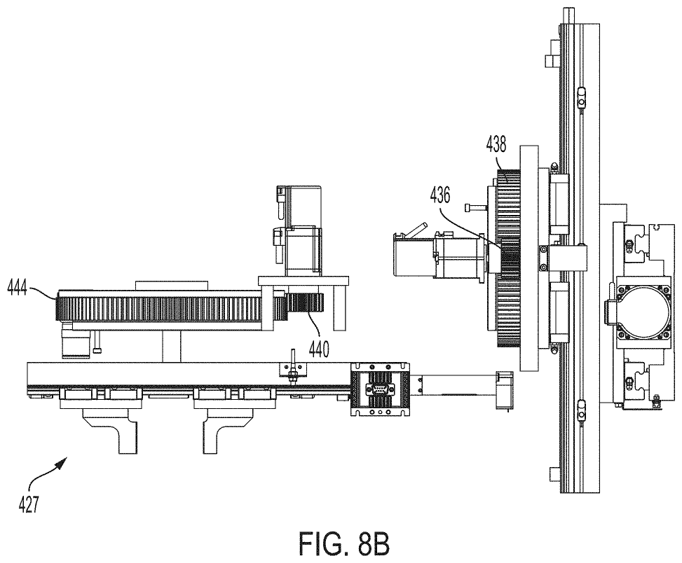

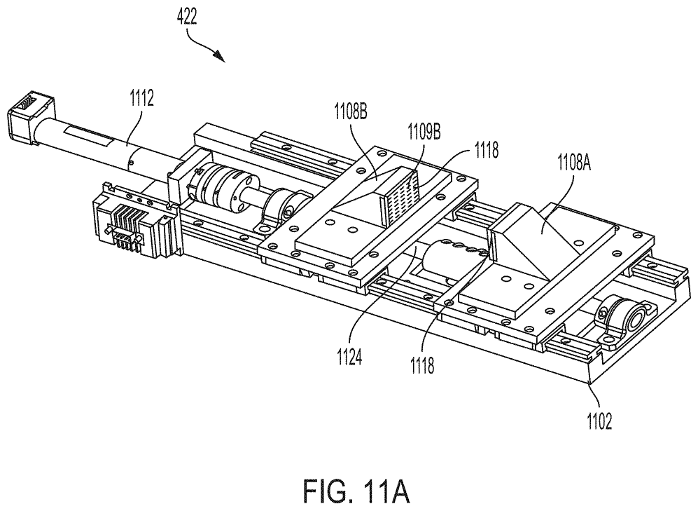

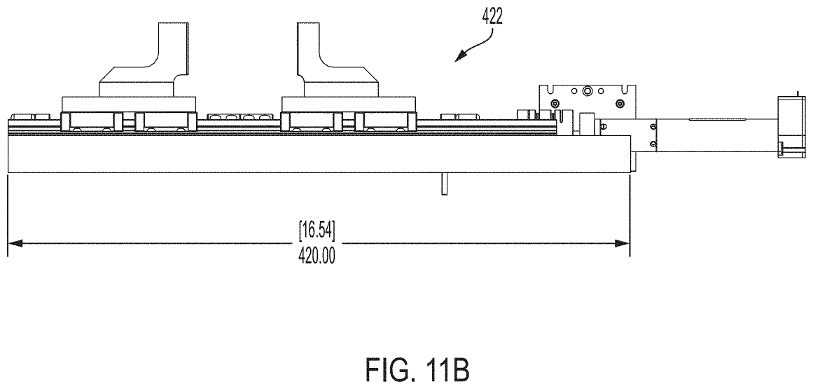

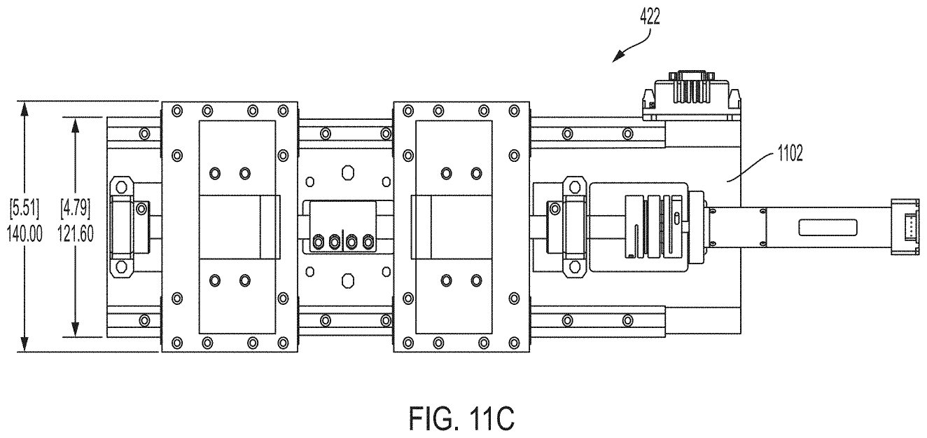

As shown in FIGS. 8A-8B, for example, the robot 406 may further comprise an end effector 427 coupled to the robotic arm 408. In some embodiments, the end effector 427 comprises a gripper 422 configured to grasp a permanent magnet. As described herein, including with respect to FIGS. 11A-15 and FIG. 18, the gripper 422 may include first and second jaws configured to grasp a permanent magnet.

As illustrated in FIG. 8A, for example, the robot 406 may further comprise a housing 434 coupled to the end effector 427. The housing 434 may be composed of any suitable material including, for example, non-ferrous material (e.g., aluminum). The inventors have recognized that using a non-ferrous material for one or more elements of the robot is advantageous as non-ferrous materials are unaffected to the strong magnetic forces generated by the magnet assembly. In other embodiments, the housing 434 may include both ferrous and non-ferrous materials, as aspects of the technology described herein are not limited in this respect.

The inventors have recognized that it is advantageous to separate the motor(s) of the robot 406, such as the first motor 421, the second motor 417, the third motor 413, the first gear motor 446, and the second gear motor 442, from the jaws of the end effector 427 as well as the magnet assembly 402 by a minimum distance while still providing a robot 406 having relatively compact dimensions so as to minimize the torque experienced by the robot 406 as described herein. The inventors have recognized that maintaining a minimum distance between the one or more motors of the robot 406 and the jaws of the end effector 427 and/or the magnet assembly 402 reduces the possibility that electrical components of the one or more motors are impacted (e.g., become damaged, do not properly operate, etc.) by virtue of the strong magnetic forces generated by the magnet assembly and its components. For example, a permanent magnet grasped between the jaws of the end effector 427 may generate a magnetic field that may impact operation of the motor(s). By separating one, some or all of motors of the robot 406 from the jaws of the end effector 427, and thus from the permanent magnet which is grasped by the jaws, the impact of the magnetic force exerted on the motor(s) is reduced or eliminated.

Accordingly, in some embodiments, one, some, or all of the motors are each separated from the jaws of the end effector 427 by at least a threshold distance (e.g., at least 200 mm, at least 250 mm, at least 300 mm, at least 400 mm, at least 500 mm, etc.). The threshold distance may depend on the strength of the magnetic field generated by the magnets being moved by the robot—the stronger the magnetic field, the farther away the motors are to be placed from the jaws to avoid being impacted by the magnetic field.

In some embodiments, the end effector 427 is configured move in additional degrees of freedom distinct from the movement of the robot 406, such as by rotating in one or more planes of rotation. For example, in some embodiments the end effector 427 may be configured to rotate about the A and/or B axes shown in FIG. 4B. In this way, the end effector 427 can allow the gripper 422 to place permanent magnets on both bottom and top ferromagnetic plates (e.g., plates 403A and 403B as shown in FIG. 7) disposed opposite each other by rotating the gripper 180° in the BC plane, otherwise referred to herein as rotation about the A axis.

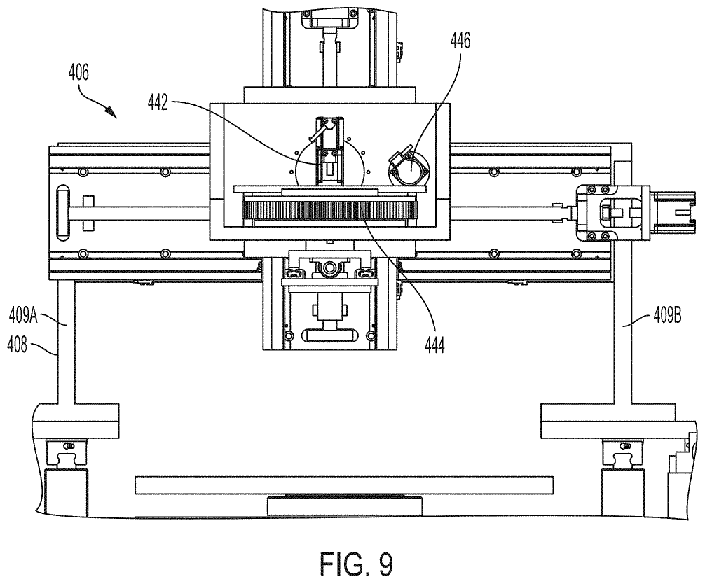

In the illustrated embodiments, for example, in FIGS. 8A-9, the robot 406 comprises first and second gear motors 446, 442 coupled to the robotic arm 406. In the illustrated embodiment, the first gear motor 446 is coupled to a first gear 436 and the second gear motor 442 is coupled to a second gear 440. Although, in the illustrated embodiment the first gear 436 and the second gear 440 each have an individual gear motor coupled to and configured to rotate the gear, in other embodiments, one or more gear motors may be configured to be coupled to and rotate multiple of the first gear 436 and the second gear 440.

In the illustrated embodiment, the first gear 436 is coupled to the end effector 427 and the first gear motor 446 is configured to rotate the first gear 436 such that the end effector 427 moves along a respective degree of freedom when the first gear 436 is rotated. In some embodiments, the end effector 427 may be configured to rotate in a plane of rotation when the first gear 436 is rotated by the first gear motor 446. For example, in the illustrated embodiment, the end effector 427 is configured to rotate in the “AB” plane defined by the A and B axes, otherwise referred to herein at rotation about the C axis, when the first gear motor 446 rotates the first gear 436.

In the illustrated embodiment, the second gear 440 is coupled to the end effector 427 and the second gear motor 442 is configured to rotate the second gear 440 such that the end effector 427 moves along a respective degree of freedom when the second gear 440 is rotated. In some embodiments, the end effector 427 may be configured to rotate in a plane of rotation when the second gear 440 is rotated by the second gear motor 442. For example, in the illustrated embodiment, the end effector 427 is configured to rotate in the “BC” plane defined by the B and C axes, otherwise referred to herein as rotation about the “A” axis, when the second gear motor 442 rotates the second gear 440.

As shown in FIG. 9, the first arm segment 419 may comprise a gantry having first and second side segments 409A, 409B. In the illustrated embodiment, first lead screw 418 is a pair of lead screws and the first motor 421 comprises a pair of motors configured to rotate the pair of lead screws. In some embodiments, the first lead screw 418 is a single lead screw. In some embodiments, the first motor 421 may comprise a single motor configured to rotate both of the pair of lead screws. In the illustrated embodiment, for example, the pair of lead screws can be rotated by the first motors 421 concurrently. While the embodiment illustrated in FIGS. 4A-10 show the first lead screw 418 as a pair of lead screws, in other embodiments, the first lead screw 418 may be implemented as a single continuous screw with both a left-threaded portion and a right-threaded portion. The first side segment 409A of the first arm segment 419 may be coupled to one of the left- or right-threaded portions of the first lead screw 418 while the second side segment 409B of the first arm segment 419 may be coupled to the other of the left- or right-threaded portion of the first lead screw 418.

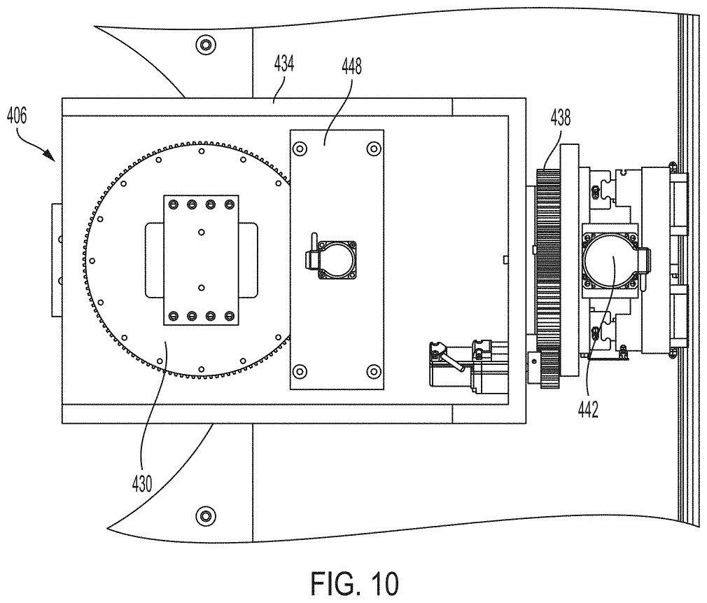

FIG. 10 illustrates a top view of the robot 406 configured to assemble a magnet assembly, according to embodiments of the technology described herein. In the embodiment illustrated in FIG. 10, the robot 406 further comprises a mounting 448 and adapter 430 for coupling the end effector 427 to the robot 406.

In some embodiments, the system 400 further comprises one or more linear rails and bearings coupled to a system base 404. The one or more linear rails and bearings may be configured to assist in the translational motion of the robotic arm 408. For example, in the illustrated embodiment, first linear rails 420 are configured to facilitate motion of the first arm segment 419 along a first degree of freedom. A second linear rail 416 is configured to facilitate motion of the second arm segment 415 along a second degree of freedom. A third linear rail 420 is configured to facilitate motion of the third arm segment 411 along a third degree of freedom.

In some embodiments, the robot 406 further comprises one or more sleeve bearings coupled to the first and second gears 436, 440. The sleeve bearings may be configured to assist in the rotational motion of the robotic arm 408. For example, in the illustrated embodiment, a first sleeve bearing 438 is coupled to the first gear 436 and configured to facilitate the rotation of the end effector 427 in a first plane of rotation. A second sleeve bearing 444 is coupled to the second gear 440 and configured to facilitate the rotation of the end effector in a second plane of rotation. Furthermore, the one or more sleeve bearings may be sufficiently robust, having a load capacity of up to 500 kgf, for example.

In some embodiments, one or more of the first and second sleeve bearings 438, 444 may be omitted and one or more of the first and second gears 436, 440 may instead be directly coupled to the robot 406. In some embodiments, the first gear 436 configured to facilitate rotation of the end effector 427 in the first plane of rotation may be omitted. In such embodiments, a rotary fixture may be used to switch positions of the top and bottom ferromagnetic plates 403A, 403B so that magnet assembly can be performed on the top ferromagnetic plate without further need to rotate the robot 406.

Although not shown in the figures, the one or more segments of the robotic arm 408 may be coupled to the one or more lead screws by one or more drive nuts. For example, the first arm segment 419 may be coupled to the first lead screw 418 by one or more drive nuts configured to slide along the first lead screw 418. In some embodiments, such as where the first arm segment 419 comprises a first side segment 409A and a second side segment 409B, for example, the first side segment 409A may be coupled to one first lead screw 418 by a first drive nut and the second side segment 409B may be coupled to a second first lead screw 418 by a second drive nut.

Robot 406 may be comprised of any suitable material. The inventors have recognized that, in some embodiments, all or portions of the robot 406 can be comprised a non-ferrous material such as aluminum, zinc, bronze, and/or a combination thereof. The inventors have recognized that using a non-ferrous material for one or more components of the robot is advantageous as non-ferrous materials are unaffected by the strong magnetic forces generated by the magnet assembly. However, in some embodiments, the robot 406 may be comprised of one or more materials other than those described herein, including ferrous and non-ferrous materials, and aspects of the technology described herein are not limited in this respect.

The inventors have recognized that the robot described herein may be manufactured such that the robot is sufficiently robust to withstand strong magnetic forces generated by components of the magnet assembly. For example, the robot 406 can be manufactured having sufficiently small dimensions so as to minimize the torque experienced by the robotic arm 408. In some embodiments, the robot 406 can be manufactured such that the robotic arm 408 can withstand a static moment of at least 1000 Nm. In some embodiments, the robot 406 can be manufactured such that the robotic arm 408 can withstand a 200 kgf peak force when the gap between the permanent magnet and the ferromagnetic plate is 1 mm or less, for example at 0.5 mm from the ferromagnetic plate.

FIGS. 4C-4D illustrate example dimensions for the robot 406 and system 400. As shown in FIGS. 4C-4D, in some embodiments, the robot 406 has a length (i.e. in the direction along the A axis shown in FIG. 4B) of approximately 96 inches or less. In some embodiments, the robot 406 has a width (i.e. in the direction along the B axis shown in FIG. 4B) of approximately 48 inches or less. In some embodiments, the robot 406 has a height (i.e. in the direction along the C axis shown in FIG. 4B) of approximately 39.4 inches or less.

FIGS. 4E1-4E3 illustrate a schematic power control diagram 40 for one or more motors of the example robot of FIG. 4A, in accordance with some embodiments of the technology described herein. In some embodiments, the robot 406 has a 200V AC power source for powering the one or more motors of the robot 406. The one or more motors of the robot 406 may each have two power inputs: a first input for motor power and a second input for servo drive control electronics. The motor power line may be isolated from a magnet assembly area 432 and may be controlled by a technician overseeing operation of the system 400. The technician may control power of the system 400 using a start, stop, and/or an emergency button. For example, in cases of emergency, an emergency button can be provided wherein pushing the emergency button immediately cuts off power to the system to protect the technician and nearby equipment. The power source for each of the one or more motors may by protected by individual fuse and circuit breakers.

A current-based control method may be applied for one or more, e.g. all, of the motors of the robot, for example, the first motor 421, the second motor 417, the third motor 413, the first gear motor 446, and/or the second gear motor 442. Furthermore, current-based control methods may be applied to one or more additional motors of the system 400, such as the system motor 424 and/or the gripper motor 1112, as further described herein. FIG. 4F illustrates an example of a feedback control loop diagram 42 for one or more motors of the example robot of FIG. 4A, in accordance with some embodiments of the technology described herein. The inventors have recognized that a current-based control method may allow the robot 406 to move in accordance with a series of movements pertaining to a permanent magnet layout 232 even while the robot 406 is experiencing large external forces and torque.

For example, proportional, integral, and differential (PID) feedback control may be implemented for each degree of freedom, e.g. each axis of motion in some embodiments, for which the one or more motors are configured to move the robot 406 along. Each axis of motion may have a rotational encoder mounter to a motor shaft. The position feedback may be used to generate a torque command for a motor amplifier with a tuned PID value. The torque experienced by each of the motors of the robot 406 is given by the following equation:

$$τ = K p * ( {P}_{c} - {P}_{f} ) + K d * \frac{d ( {P}_{c} - {P}_{f} )}{d t} + K i * {\int }_{0}^{t} ( {P}_{c} - {P}_{f} ) d η$$

Wherein τ is the torque experienced by each of the motors of the robot 406, Kp is the proportional gain, Kd is the derivative gain, Ki is the integral gain, P_{c} is the position command signal, and P_{f} is the position feedback signal, as shown in FIG. 4F. Due to the high magnetic force generated by the magnet assembly 402 and its components, the motor amplifier must generate a large current to enable the one or more motors to withstand the resulting high torques.

FIG. 4G illustrates a graph measuring motor torque vs. displacement of the example robot of FIG. 4A, in accordance with some embodiments of the technology described herein. The graph 44 in FIG. 4G illustrates a measured motor torque value during the process of lifting a permanent magnet from the ferromagnetic plate 403. The torque experienced by a motor of robot 406 is correlated with the magnetic force, otherwise referred to herein generally as a “pull force”, exerted on the motor, as shown in FIG. 4H. FIG. 4H illustrates a graph 46 measuring motor torque vs. pull force on the example robot of FIG. 4A, in accordance with some embodiments of the technology described herein. The magnetic pull force and torque experienced components of the robot 406 may be measured and/or monitored during assembly of the B₀ magnet assembly.

FIG. 4A further illustrates an example embodiment of a magnet assembly 402. The magnet assembly 402 may comprise one or more plates 403, for positioning and placing a permanent magnet according to a specified layout. In some embodiments, the one or more plates 403 may be manufactured from a ferromagnetic material, such as steel, for example. Therefore, plates 403, are also referred to herein as a ferromagnetic plate 403. However, the plates 403 may be comprised of any suitable material or materials.

In some embodiments, the ferromagnetic plate 403 comprises a lower plate 403A and an upper plate 403B. In such embodiments, the robot 406 may be configured to place permanent magnets on the lower plate 403A and the upper plate 403B by rotating the end effector 427 about the A axis as described herein, to produce a B₀ magnet assembly having an upper B₀ magnet and a lower B₀ magnet, and an imaging region therebetween. The imaging region defines the volume in which the B0 magnetic field produced by a given B0 magnet is suitable for imaging. More particularly, the imaging region corresponds to the region for which the B₀ magnetic field is sufficiently homogeneous at a desired field strength that detectable MR signals are emitted by an object positioned therein in response to application of radio frequency excitation (e.g., a suitable radio frequency pulse sequence). Although the one or more plates 403 are referred to herein as a lower plate 403A and an upper plate 403B, the one or more plates 403 may be configured having any orientation with respect to one another, such as side by side, for example. Furthermore, although, in the illustrated embodiment, the one or more plates 403 comprises two plates, the magnet assembly 402 may comprise only a single plate, in some embodiments.

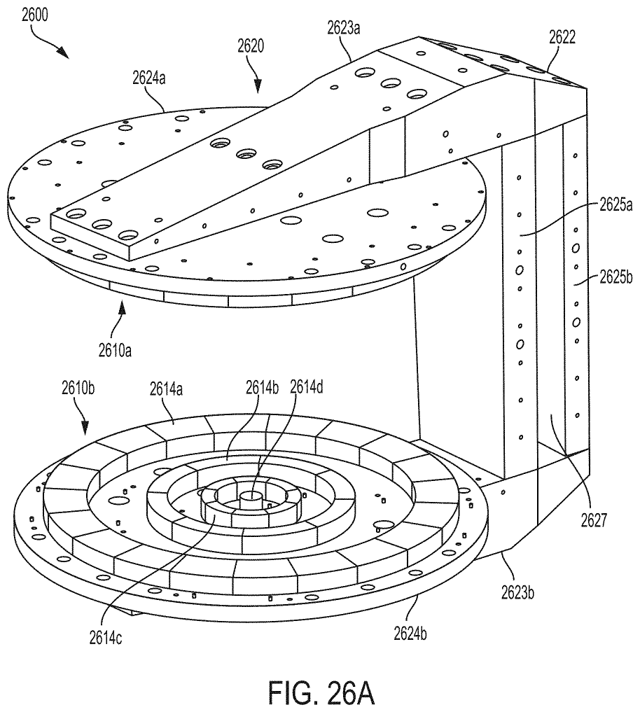

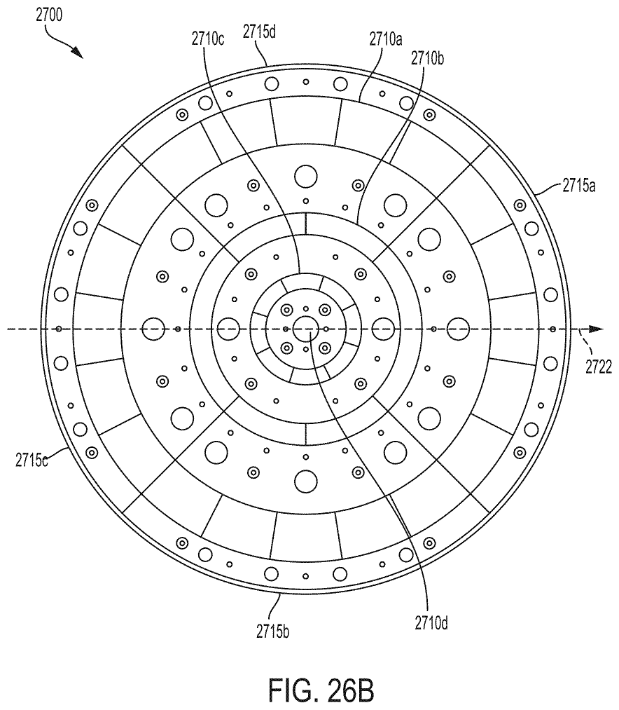

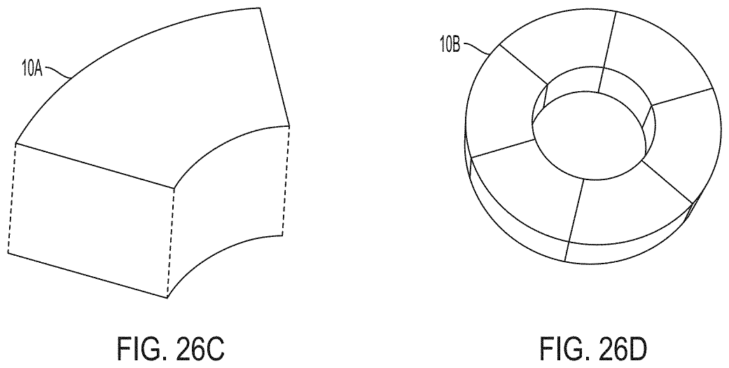

In some embodiments, the magnetic assembly 402 further comprises a yoke 426 magnetically coupled to one or more plates 403A, 403B to capture magnetic flux that, in the absence of the yoke 426, would be lost and not contribute to the flux density in the imaging region between the lower plate 403A and the lower plate 403B. In particular, yoke 426 forms a “magnetic circuit” connecting the lower and upper plates 403A, 403B so as to increase the flux density in the imaging region between the lower and upper plates 403A, 403B, thus increasing the field strength within the imaging region. In some embodiments, the yoke 426 comprises a lower yoke portion 426A coupled to the lower plate 403A, and an upper yoke portion 426B, coupled to the upper plate 403B. In some embodiments, the lower and upper yoke portions 426A, 426B of the magnetic assembly 402 may be connected by an assembly frame described herein, including with reference to FIGS. 26A-26B.

In the embodiment illustrated in FIGS. 4A-4B and 5-10, for example, the robot 406 and the magnet assembly 402 are supported by a system base 404. The system base 404 may be comprised of a non-ferrous material, such as aluminum. The system base 404 may be configured to provide a precise ground for the assembly of the B0 magnet assembly 402. Furthermore, the system base 404 may reduce the hazard that strong magnetic fields generated by the magnet assembly 402 and its components, including one or more permanent magnets, cause damage to surrounding equipment and personnel. In some embodiments, the base may have a width of approximately 48 inches, a length of approximately 96 inches and a height of approximately 33.6 inches.

The system may further have a jig plate 429 disposed between the magnet assembly 402 and the system base 404. The jig plate 429 may increase the stability of the magnet assembly 402 to ensure minimal movement of the magnet assembly 402 during the positioning and placing of permanent magnets on the magnet assembly 402 by the robot 406. In some embodiments, the jig plate 429 may comprise a non-ferrous material, such as aluminum. In some embodiments, the jig plate 429 comprises a solid material, such as cast aluminum. The jig plate 429 manufactured to be relatively thin, for example having dimensions of 4 ft.×8 ft.×½ in. In some embodiments, the jig plate 429 supports both the robot 406 and the magnet assembly 402, while in other embodiments, the jig plate 429 is configured to support only one of the robot 406 or the magnet assembly 402.

In some embodiments, a system motor 424 may be coupled to the system base 404 and the lower plate 403A. In the illustrated embodiments, the lower plate 403A is configured as a turn table capable of being rotated by the system motor 424. The inventors have recognized that rotating the lower plate 403A is advantageous as it enables more precise positioning and placement of a permanent magnet on the lower plate 403A while reducing the movement required by the robotic arm 408. For example, in the illustrated embodiment, by rotating the lower plate 403A, the robotic arm 408 requires less movement in the longitudinal direction, also referred to herein as along the A axis. Thus, the robot 406 can be manufactured having smaller dimensions, minimizing the torque experienced by the robotic arm 408.

Prior to positioning and placing a permanent magnet, the permanent magnet may be loaded into a feed-in area 430. A “feed-in” area, as referred to herein, is an area for loading permanent magnets to be assembled by the robot 406. After placing one or more permanent magnets into the feed-in area 430, the robot 406 may be configured to grasp a permanent magnet from the feed-in area 430, and assemble the permanent magnet in the magnet assembly 402 by positioning and placing the permanent magnet onto the ferromagnetic plate 403A, 403B in an assembly area 432. An “assembly area”, as referred to herein, is an area for assembling permanent magnets onto the ferromagnetic plate 403A, 403B of the magnet assembly 402. There are a variety of methods of loading a permanent magnet into the feed-in area 430, as described herein, such as manually loading the permanent magnet into the feed-in area 430, and/or automatically loading the permanent magnet into the feed-in area 430 using an external device, such as a multi-axis robot, for example, and/or using the system 400 to assist in loading the permanent magnet into the feed-in area 430. In some embodiments, a permanent magnet is loaded onto a moving belt which moves the permanent magnet into a position where the permanent magnet can be grasped by the robot 406.

The inventors have recognized that it is advantageous to isolate the assembly area 432 from a feed-in area 430. Both the permanent magnets in the feed-in area 430 and components of the magnet assembly 402 in the assembly area 432 may exert magnetic forces on each other which are strongest when the objects are closest together. For example, if the magnetic force exerted by components of the magnet assembly 402 on an unassembled permanent magnet is strong enough, the force may cause the unassembled permanent magnet to move towards the magnet assembly 402, in some cases at high speeds, which can be dangerous. The inventors have recognized that isolating the feed-in area 430 from the assembly area 432 may reduce potential damage that might otherwise be caused by the magnetic forces generated between the unassembled permanent magnets and components of the magnet assembly 402. In the illustrated embodiment, in FIG. 6, for example, the feed-in area 430 is distanced from the assembly area 432, and the robot 406 is disposed between the feed-in area 430 and the assembly area 432.

As described herein, the inventors have developed a gripper coupled to the robot 406 and configured to grasp an object, e.g. a permanent magnet, without permitting slippage of the object even under the exertion of large pulling forces on the object. According to some aspects of the technology described herein, the gripper can be configured to grasp and place permanent magnets on the ferromagnetic plate(s) 403A, 403B. In some embodiments, the gripper may grasp a permanent magnet which has been loaded into the feed-in area 430 between opposing jaws of the gripper and the robot 406 may position the gripper by moving the one or more arm segments 419, 415, 411 of the robotic arm 408. The gripper may place the permanent magnet onto the ferromagnetic plate(s) 403A, 403B of the magnet assembly 402 by releasing the permanent magnet from the opposing jaws of the gripper, as described herein.

FIGS. 11-15 and 18 illustrate an illustrative example of a gripper configured to grasp an object, in accordance with some embodiments of the technology described herein. As shown in FIG. 11A, for example, gripper 422 comprises a base 1102 and first and second jaws 1108A-B movably coupled to the base. A linear actuator comprising a gripper motor 1112 and at least one lead screw 1124 may facilitate movement of the first and second jaws 1108A-B along the base 1102 as described herein.

First and second jaws 1108A-B of the gripper 422 may be configured to grasp an object, such as permanent magnet 10, between the first and second jaws 1108A-B so that the gripper 422 can lift and, in some embodiments, move the object to a second position. In some embodiments, lifting and moving the object comprises lifting, moving and placing the object in a second position in accordance with a specified layout. For example, the object may be permanent magnet 10, and the layout may be a specified permanent magnet layout 232 for a magnet assembly 402, which is, in some embodiments, configured to be integrated into an MRI device as described herein.

Base 1102 may be configured to support first and second jaws 1108A-B of the gripper 422. Base 1102 may be manufactured having any suitable dimensions. For example, in some embodiments, base 1102 has a width of approximately 4.8 inches and a length of approximately 16.5 inches, as shown in FIGS. 11B-C.

Components of the gripper 422, such as base 1102 and jaws 1108A-B, for example, may be manufactured from any suitable material or materials, including, for example, a non-ferrous material (e.g., aluminum). In some embodiments, the components of the gripper 422 may be comprised only of the one or more non-ferrous materials. In other embodiments, components of the gripper 422 may be coated with a non-ferrous material and an inner portion of the component may comprise a different material. The inventors have recognized that manufacturing components of the gripper 422 from non-ferrous materials allows components of the gripper 422 to withstand magnetic forces generated by one or more magnets of the magnet assembly as non-ferrous materials are resistant to magnetic forces. Thus, embodiments of the gripper 422 having components manufactured from one or more non-ferrous materials may be operational even in high strength magnetic fields, for example, greater than 1.4 T. However, in some embodiments, one or more components of the gripper 422 may comprise a ferrous material, including, for example, stainless steel.

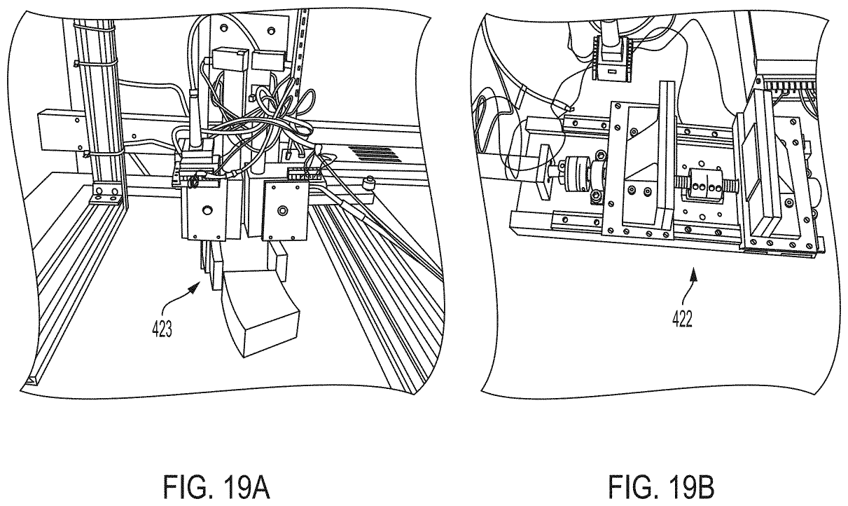

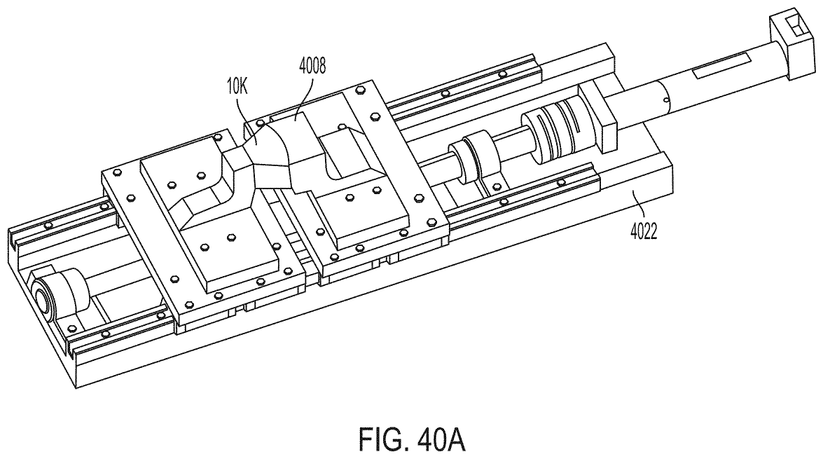

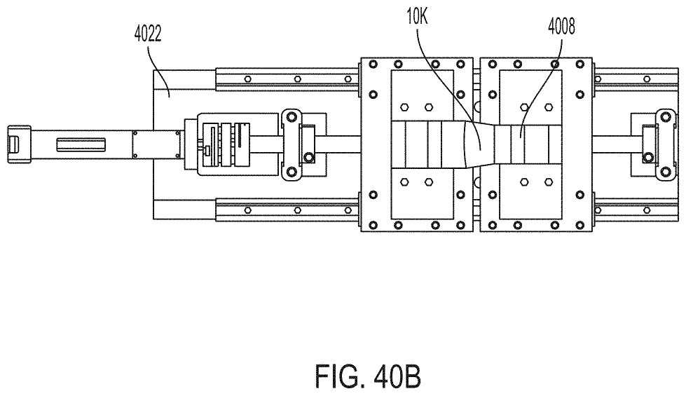

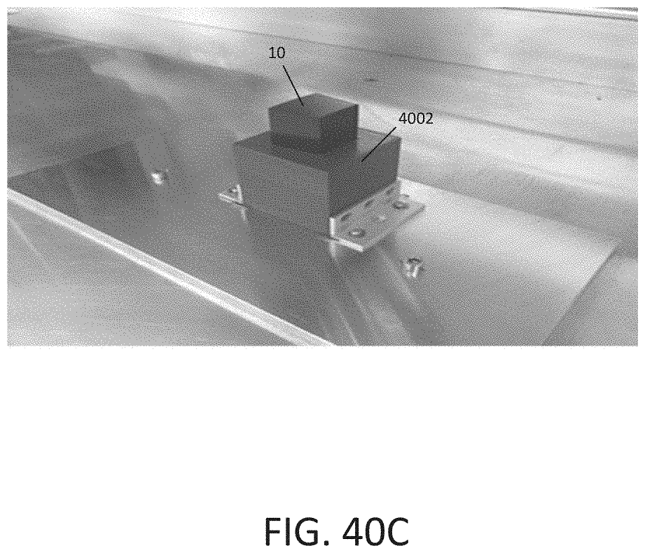

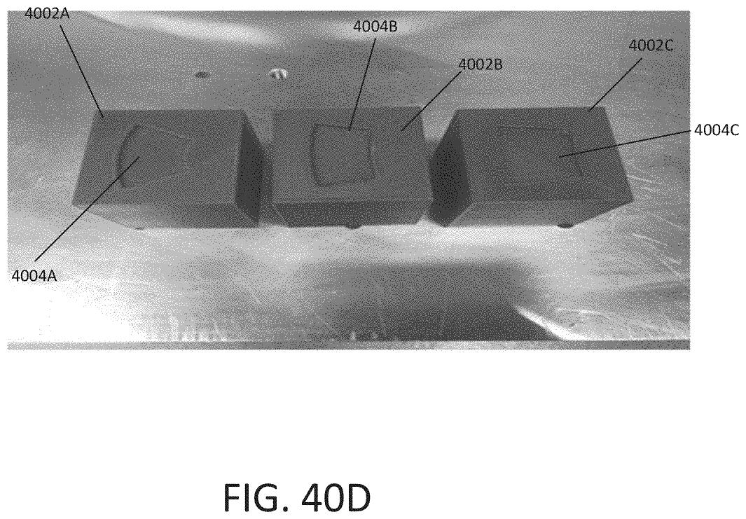

Furthermore, first and second jaws 1108A-B may be manufactured having any suitable shape, non-limiting examples of which include rectangular, trapezoidal, triangular or wedge-shaped, tapered, etc. For example, FIGS. 19A-B illustrate alternative embodiments of gripper 422, 423 having different shaped jaws. In FIG. 19A, jaws of the gripper 423 are rectangular-shaped, while, in FIG. 19B, jaws of the gripper 422 have a wedge-shape. In some embodiments, first and second jaws 1108A-B may be manufactured having substantially the same shape. In other embodiments, first and second jaws 1108A-B may be manufactured having different shapes. The inventors have recognized that it is advantageous to manufacture the first and second jaws 1108A-B having a particular shape for various reasons, including based on a particular shape of permanent magnet to be assembled, and/or based on a particular magnet layout 232. For example, FIGS. 40A-B illustrate an alternative embodiment of gripper 4022 having tapered jaws 4008. The tapered jaws 4008 may be better suited for grasping a tapered permanent magnet, such as magnet 10K. However, aspects of the technology described herein are not limited in this respect and the first and second jaws 1108A-B may be manufactured having any suitable shape for magnets having a variety of shapes.

In addition, To address the resulting non-uniformity in the magnetic field, the height or depth of the blocks in affected regions may be varied (e.g., increased) to generate additional magnetic flux to compensate for the reduction in magnetic flux density caused by the yoke, thereby improving the homogeneity of the B₀ magnetic field within the field of view of the B₀ magnet.

Even though the permanent magnets may have different sizes and shapes, in some embodiments, the automated robotic techniques described herein can be used to manipulate such permanent magnets and assemble a magnet assembly. For example, the design of the gripper allows for the gripper to be used for grasping permanent magnets having different shapes and sizes.

According to some aspects of the technology, holding fixtures are provided in a feed-in area, as described herein, to facilitate object pick-up by the gripper 422. For example, FIGS. 40C-40D illustrate example embodiments of removable holding fixtures for use with systems configured to assemble a magnet assembly, in accordance with some embodiments of the technology described herein. FIG. 40C illustrates one example of a removable holding fixture 4002 configured for holding an object, such as permanent magnet 10, to be picked up by the gripper 422. The removable holding fixture 4002 may be fixed at a location in the vicinity of the robot 406 (e.g., in the feed-in area as described herein), such that robot 406 can position the gripper 422 above the removable holding fixture 4002, and the gripper 422 can grip and pick up the permanent magnet 10 (or other object) disposed in the removable holding fixture 4002.

FIG. 40D illustrates various examples of removable holding fixtures 4004A-C configured to facilitate object pick-up by the gripper 422. As shown in FIG. 40D, each of the removable holding fixtures 4002 comprises a respective depressed portion 4004 shaped to receive an object having particular dimensions. For example, removable holding fixture 4002A comprises a depressed portion 4004A with tapered sides such that an object, such as the permanent magnet 10 shown in FIG. 40C, also having tapered sides can be received in the depressed portion 4004A. Removable holding fixtures 4002B, 4002C likewise comprise depressed portions 4004B, 4004C shaped to receive objects of particular dimensions, but which differ in shape from depressed portion 4004A. The removable holding fixtures described herein may be configured having depressed portions of any suitable shape for facilitating object holding and object pick-up, and aspects of the technology described herein are not limited in this respect.

In some embodiments, only removable holding fixtures having depressed portions of a same shape are fixed to a feed-in area at a time. For example, one or more removable holding fixtures having a tapered depressed portion like that of depressed portion 4004A shown in FIG. 40D are fixed to a feed-in area. When it is desired to position objects of a shape different than depressed portion 4004A using the robot 406 and gripper 422, a new removable holding fixture with a different shaped depressed portion may be fixed to the feed-in area in addition to or in place of the initial removable holding fixture. In other embodiments, one or more removable holding fixtures having depressed portions which differ in shape are fixed to the feed-in area at one time. Although the holding fixtures have been described herein as being “removable”, for example, such that the shape of the depressed portion can be interchanged, in some embodiments, the holding fixtures are permanently fixed to the feed-in area.

The inventors have recognized that use of one or more removable holding fixtures as described herein is advantageous as the holding fixtures improve the repeatability of gripping an object with gripper 422 and the precision with which the object can be placed on the ferromagnetic plate. In particular, use of the removable holding fixture ensures that the object being picked up by the gripper is disposed at a consistent angle and location relative to the jaws of the gripper when the object is picked up. For example, in some embodiments, it may be desired to grip an object such that the surface contact between the object being picked up and the jaws of the gripper is maximized, as described herein. As the removable holding fixture is fixed to the feed-in area and the depressed portion of the removable holding fixture is designed to receive the object, successive objects being picked by the gripper 422 will be fixed in location and angle relative to the gripper 422 when the object is picked up. Variations in the location and/or angle of the objects being picked up can result in the object being twisted relative to the gripper when the object is picked up, requiring additional positioning by the robot 406 to precisely place the object according to a specified layout, or, in some cases, resulting in positioning errors of the object when the object is placed on the ferromagnetic plate. By eliminating possible positioning errors in object placement, the objects can be placed closer together on the ferromagnetic plate. For example, in some embodiments, the methods and system described herein can achieve object placement with the gap between objects being no more than 2 mm, no more than 1.5 mm, no more than 1 mm, etc.

The gripper 422 may further comprise first and second surfaces 1109A-B, respectively. In some embodiments, first surface 1109A of first jaw 1108A is substantially parallel to and faces second surface 1109B of second jaw 1108B. The inventors have recognized that configuring first and second surfaces 1109A-B such that the first and second surfaces 1109A-B are substantially parallel to each other is advantageous as this configuration allows for maximum contact between the first and second surfaces 1109A-B of the first and second jaws 1108A-B and the object being gripped by the jaws 1108 which may prevent slippage of the object, as described herein. In some embodiments, first and second jaws 1108A-B are movably coupled to the base 1102 such that first and second jaws 1108A-B can move towards or away from each other when driven by the linear actuator, such as gripper motor 1112 and at least one lead screw 1124 described herein.

The inventors have appreciated that permanent magnets of the type used in an MRI device often are prepared having smooth surfaces in order to create homogenous magnetic fields. Due to the smooth surfaces of such permanent magnets, surfaces of these permanent magnets have a relatively low coefficient of friction which makes gripping a permanent magnet without permitting slippage difficult. In addition, this problem is exacerbated by the fact that the permanent magnets may be subject to strong magnetic forces created by neighboring permanent magnets and ferrous materials of the magnet assembly 402. Such strong magnetic forces make it more likely that the permanent magnets may slip out of the grip of the first and second jaws 1108A-B of the gripper 422.

In some embodiments as described herein, first and second jaws 1108A-B are configured to exert a high clamping force on the surface of an object, such as a permanent magnet, disposed between first and second surfaces 1109A-B of first and second jaws 1108A-B. In some embodiments, the clamping force exerted on the surface of the object is at least 150 lbf, 200 lbf, 225 lbf, or 250 lbf. In other embodiments, the clamping force is between 100 and 200 lbf. The inventors have recognized that the clamping force on an object may vary depending on the object to be gripped, and that in some instances, the clamping force may be configured to be lower on an object which is more delicate and/or at less risk of slippage. In other embodiments, the clamping force on an object may be configured to be higher where the object has a low coefficient of friction and/or is subject to a strong pulling force.

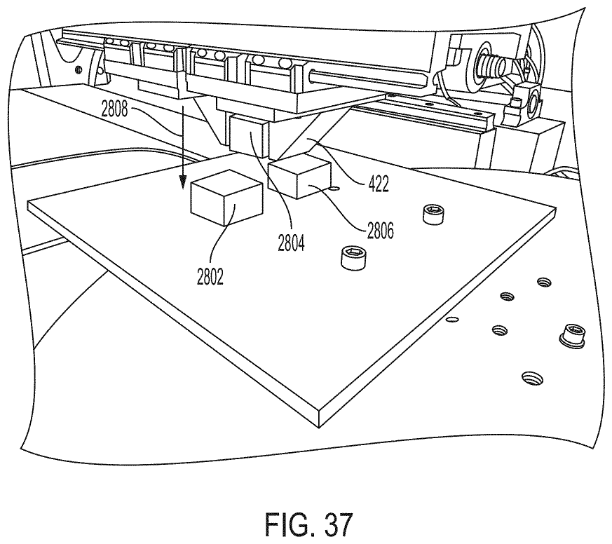

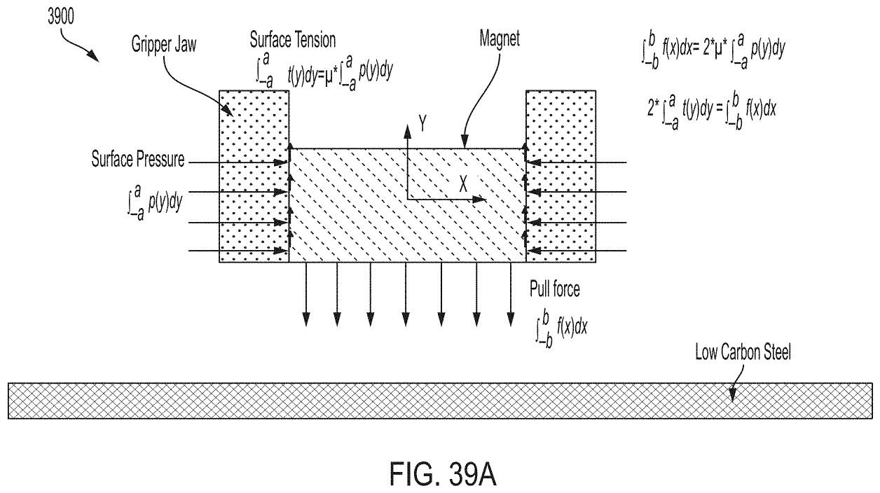

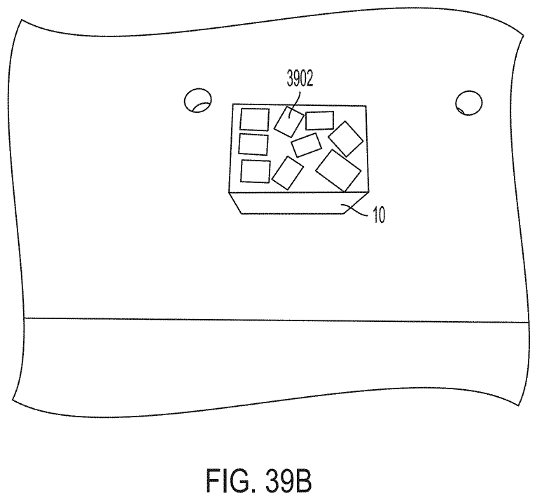

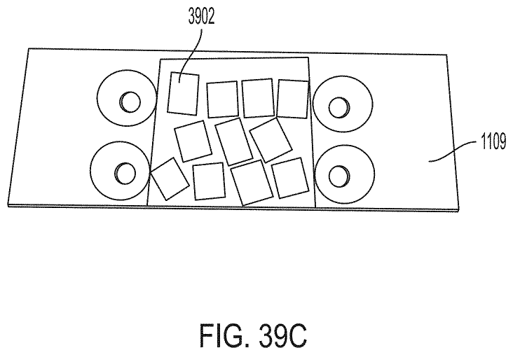

As described herein, a permanent magnet gripped by the first and second jaws 1108A-B of the gripper 422 may experience a strong pulling force downward from the first and second jaws 1108A-B due to the magnetic field generated by components of the magnet assembly 402. For example, the direction of the pulling force on the permanent magnet may be substantially perpendicular to a direction along which the first and second jaws move. The direction of the pulling force on a permanent magnet gripped by first and second jaws 1108A-B of the gripper 422 according to some embodiments, is shown by arrow 2808 in FIG. 37. The pulling force on the permanent magnet may vary (e.g. at least 100 lbf, between 100 and 120 lbf, between 100 and 200 lbf, at least 150 lbf, at least 200 lbf, between 150 and 250 lbf). In other embodiments, the pulling force experienced by the permanent magnet may be greater than or less than the forces described herein. For example, the strength of the pulling force on the permanent magnet may be based at least in part on the magnet assembly 402, the specified layout 232, the position of the permanent magnet being positioned and the number of permanent magnets currently assembled on the ferromagnetic plate 403. As will be described herein, FIG. 39A illustrates an example model of forces exerted on a permanent magnet during positioning of the permanent magnet in a magnet assembly, in accordance with some embodiments of the technology described herein.

Gripper 422 may be manufactured having any suitable dimensions. For example, as shown in FIGS. 11B-11C, the gripper 422 has a width of approximately 5.5 inches and a length of approximately 21.2 inches.

As described herein, the gripper 422 may further comprise a linear actuator comprising a gripper motor 1112 and at least one lead screw 1124. In some embodiments, the linear actuator may be configured to rotate the at least one lead screw 1124 using the at least one gripper motor 1112. In other embodiments, the actuator may be a hydraulic actuator, a pneumatic actuator, or any other suitable type of linear actuator, and aspects of the technology described herein are not limited in this respect.

The first and second jaws 1108A-B may be coupled to the at least one lead screw 1124 such that rotation of the at least one lead screw 1124 by the gripper motor 1112 causes the first and second jaws 1108A-B to move towards each other to grip an object, such as a permanent magnet, disposed between the first and second surfaces 1109A-B. The inventors have recognized that, in some embodiments, it is advantageous to rotate the at least one lead screw 1124 using a single motor 1112 such that the first and second jaws 1108A-B are configured to move along the base 1102 concurrently, as described herein.

In some embodiments, the at least one lead screw 1124 comprises a first lead screw 1124A and a second lead screw 1124B. The first and second lead screws 1124A-B may be configured such that one of the first and second lead screws 1124A, 1124B is a right-threaded lead screw and the other of the first and second lead screws 1124A, 1124B is a left-threaded lead screw. The inventors have recognized that configuring the first and second lead screws 1124A-B according to this embodiment and rotating the first and second lead screws 1124A-B concurrently with a single motor 1112 allows for self-centering of the first and second jaws 1108A-B. However, in other embodiments, the at least one lead screw 1124 may comprise a single lead screw 1124 having a left-threaded portion and a right threaded portion, and the motor 1112 may be configured to rotate the left- and right-threaded portions concurrently such that the first and second jaws 1108A-B move along the base 1102 at the same time and the gripper 422 is able to self-center the first and second jaws 1108A-B.

In some embodiments, the at least one lead screw 1124 may have a tightly spaced thread. As described herein, the pitch of a screw refers to the distance between the screw's threads. In some embodiments, the pitch of the at least one lead screw 1124 is 0.1 inches. In some embodiments, the pitch of the at least one lead screw 1124 is less than 0.1 inches. The inventors have appreciated that a smaller pitch gives a greater output for a given input. Therefore, the at least one lead screw 1124 may be more precisely controlled while minimizing power consumption of the motor 1112.

The inventors have recognized that it is advantageous to separate the gripper motor 1112 from the first and second jaws 1108A-B of the gripper 422 and/or the magnet assembly 402 by a minimum distance in order to reduce potential damage to electrical components of the gripper motor 1112 by virtue of strong magnetic forces generated by the magnet assembly 402 and its components. The inventors have recognized that maintaining a minimum distance between the gripper motor 1112 and the jaws 1108 reduces the possibility that electrical components of the gripper motor 1112 are impacted (e.g., become damaged, do not properly operate, etc.) by virtue of the strong magnetic forces generated by the permanent magnet. By separating the gripper motor 1112 from the jaws 1108 and thus a permanent magnet gripped by the jaws 1108, the impact of the magnetic force exerted on the gripper motor 1112 is reduced or eliminated.

In some embodiments, the gripper motor 1112 is separated from the first and second jaws 1108A-B by a distance of at least 250 millimeters. In other embodiments, the gripper motor 1112 is separated from the first and second jaws 1108A-B by a distance of at least 300 millimeters. Other suitable distances not mentioned herein may be used as a minimum distance to separate the gripper motor 1112 from the first and second jaws 1108A-B, as aspects of the technology described herein are not limited in this respect.

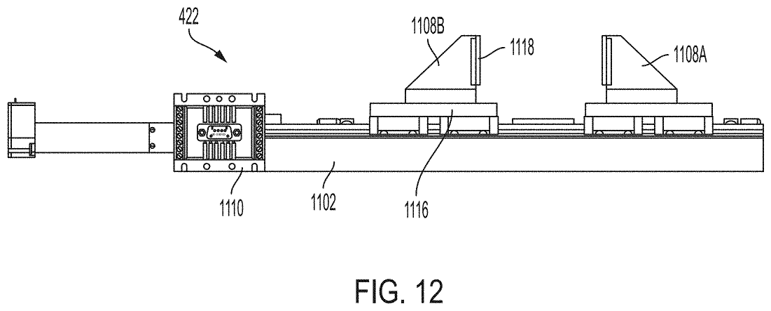

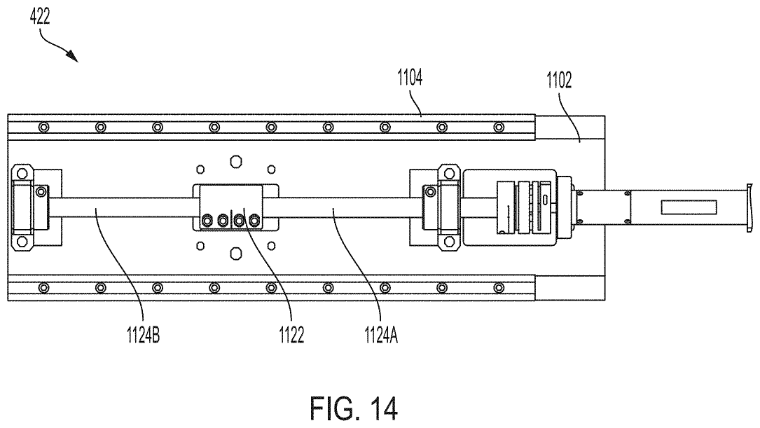

In the illustrated embodiment in FIG. 11A, the first and second jaws 1108A-B are coupled to the at least one lead screw 1124 such that the first and second jaws 1108A-B move along the base 1102 when the gripper motor 1112 rotates the at least one lead screw 1124. For example, as shown in FIG. 12 and FIG. 14, a jaw 1108 may be coupled to a surface 1116 which is configured to slide along the base 1102.

The inventors have developed a gripper 422 having first and second jaws 1108A-B which are self-locking. For example, the at least one lead screw 1124 of the gripper 422 may be configured to withstand rotation when no power is received by the gripper. Thus, when there is no driving force applied on the at least one lead screw 1124 by the gripper motor 1112, the at least one lead screw 1124 will not rotate and the first and second jaws 1108A-B will therefore remain a fixed distance from one another and exhibit no movement. The inventors have recognized that self-locking of the jaws 1108 is advantageous as an object gripped by the first and second jaws 1108A-B will not fly away and/or be dropped when power of the gripper 422 is shut off, in some cases, inadvertently.

FIG. 12 illustrates a side view of the gripper of FIG. 11A, in accordance with some embodiments of the technology described herein. As shown in FIG. 12, for example, the gripper 422 may further comprise a motor controller 1110 for controlling operation of the motor 1112. In some embodiments, the motor controller may be configured to communicate with a controller 228 of the system 400 in order to facilitate assembly of the magnet assembly 402 by the robot 406 and the gripper 422.

In some embodiments, the motor 1112 is coupled to the at least one lead screw by a motor coupler 1114. Furthermore, in some embodiments, the gripper 422 may further comprise one or more screw couplers 1120 configured to couple the at least one lead screw 1124 to the base 1102.

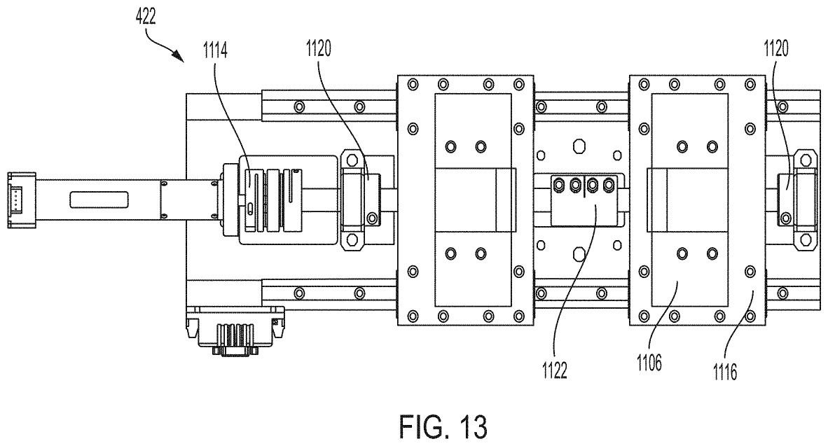

FIG. 13 illustrates a top view of the gripper of FIG. 11A, in accordance with some embodiments of the technology described herein.

FIG. 14 illustrates a top view of the gripper of FIG. 11A, in accordance with some embodiments of the technology described herein, having jaws 1108A-B removed for illustration. As shown, for example, in FIG. 14, the gripper 422 may further comprise a connector 1122. In embodiments where the at least one lead screw 1124 comprises a first lead screw 1124A and a second lead screw 1124B, the connector 1122 may be configured to couple the first and second lead screws 1124A, 1124B together such that first and second lead screws 1124A-B rotate concurrently when driven by the gripper motor 1112.

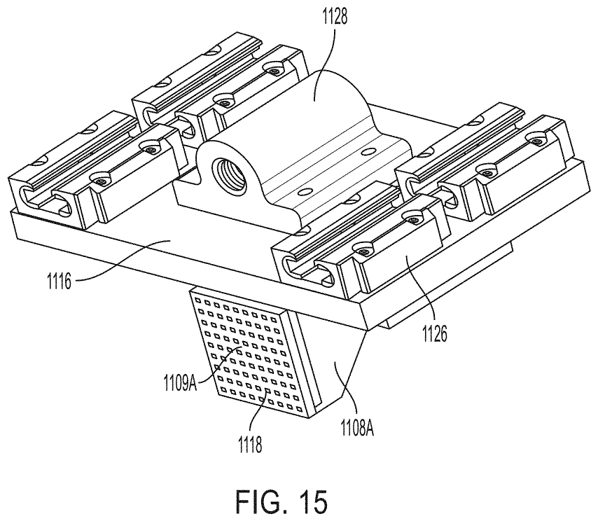

FIG. 15 illustrates a perspective view of jaws of the gripper of FIG. 11A, in accordance with some embodiments of the technology described herein. As shown in FIG. 15, each of the first and second jaws 1108A-B may be coupled to a respective surface 1116. The surface 116 may be coupled to a drive nut 1128 configured to receive the at least one lead screw 1124. Thus, the coupling of the drive nut 1128 to the at least one lead screw 1124 may facilitate movement of the jaw 1108 when the at least one lead screw is rotated. In some embodiments, the drive nut 1128 may be coupled directly to the jaw 1108 and the surface 1116 may be excluded. In the illustrated embodiment in FIG. 15, the gripper 402 comprises one drive nut 1128 per jaw 1108, however, the gripper 402 may be implemented having any suitable number of drive nuts 1228. In some embodiments, the one or more drive nuts 1128 may be made of a non-ferrous material, such as bronze, for example.

The gripper 402 may further comprise one or more bearings 1126 coupled to the first and second jaws 1108A-B. In some embodiments, the one or more bearings 1126 are coupled to the surface 1116. In other embodiments, the one or more bearings 1126 are coupled directly to the jaws 1108. In the embodiment illustrated in FIG. 15, each jaw 1108 has two bearings 1126 coupled to the jaw 1108, however, any suitable number of bearings may be used. In some embodiments, the one or more bearings 1126 may be made of a non-ferrous material (e.g. plastic, aluminum).

In some embodiments, for example, in FIG. 11A, one or more linear rails 1104 are coupled to the base 1102. The one or more bearings 1126 may be configured to receive the one or more linear rails 1104 to facilitate motion of the jaws 1108 along the base 1102. The one or more linear rails 1104 and the one or more bearings 1126 may facilitate motion of the jaws 1108 along the base 1102 by reducing friction between the jaws 1108 and the base 1102. Furthermore, the one or more linear rails 1104 and the one or more bearings 1126 may provide increased stability for the jaws 1108 of the gripper 422. In the illustrated embodiment, two linear rails 1104 are coupled to the base with one linear rail 1104 per side of the base 1102, however, any suitable number of linear rails 1104 may be implemented.

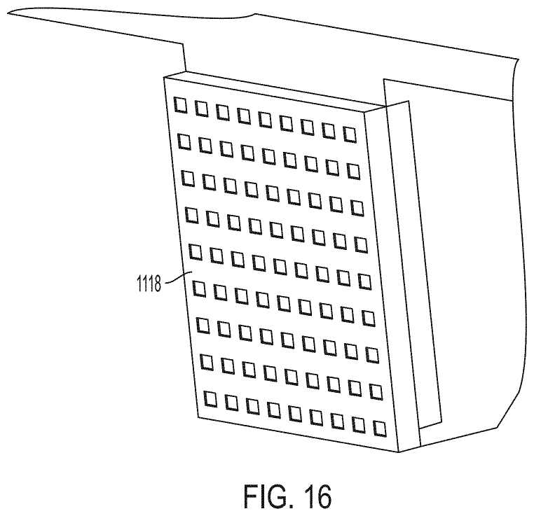

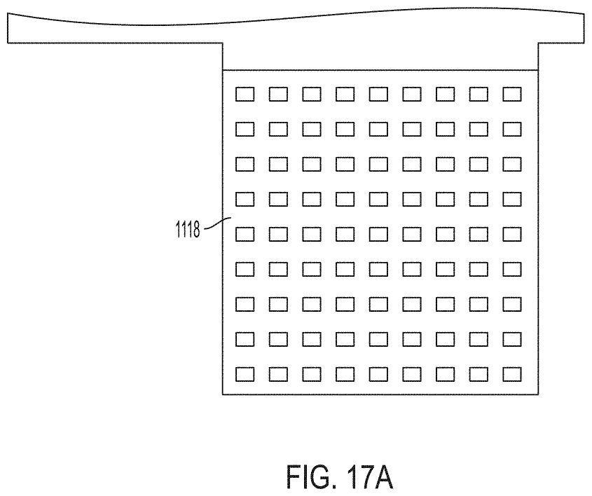

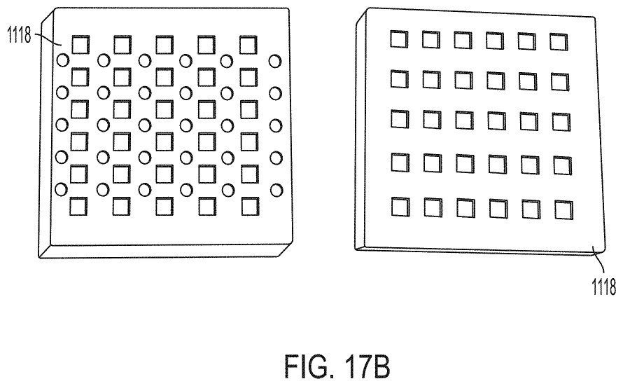

In some embodiments, gripper 422 further comprises padding 1118 disposed on each of the first and second surfaces 1109A-B to further prevent slippage of the object while the first and second jaw 1108A-B of the gripper 422 are grasping the object. FIGS. 16 and 17A-17B illustrate an example padding of the example gripper of FIG. 11A, in accordance with some embodiments of the technology described herein. The inventors have recognized that the padding 1118 can effectively increase the coefficient of friction between an object, such as a permanent magnet, and first and second jaws 1108A-B of the gripper 422 so as to further prevent slippage, even in the presence of strong magnetic forces on the object. In addition, the inventors have recognized that padding 1118 can compensate for a slight deviation in alignment between the permanent magnet and the first and second surfaces 1109A-B so as to increase surface tension between the permanent magnet and the first and second jaws 1108A-B.

Padding 1118 can be made of any suitable material, including a silicon material and/or a nitrile compound. The inventors have recognized using padding 1118 made of silicon rubber and/or nitrile rubber is advantageous as these materials provide strong surface tension between the jaws 1108 and the permanent magnet. For example, as shown in FIG. 16, padding 1118 can be a sandwiched pad comprising silicon and rubber. In some embodiments, padding 1118 measures ¼ inch thick. In some embodiments, the padding 1118 is a sandwiched pad comprising ⅛ inch silicon rubber and ⅛ inch rubber. In some embodiments, the padding 1118 measures 3.175 mm×3.175 mm. In some embodiments, the silicon rubber has a 60 A hardness on the Shore A hardness scale and the rubber is 90 A hardness on the Shore A scale. The inventors have appreciated that the hardness and depth of the padding 1118 can affect the surface tension created between the jaws 1108 and the permanent magnet by the padding 1118.

In some embodiments, padding 1118 has a laser etching on its surface to further increase friction between the padding 1118 and an object held by the gripper 422. For example, FIGS. 16 and 17A-17B, show an example of padding 1118 having laser etching on its surface. In some embodiments, the laser etching comprises 8×14 0.045″ squares etched by a laser. Etching and/or other processing of the padding 1118 may be performed in any suitable manner, and aspects of the technology described herein are not limited in this respect. Furthermore, padding 1118 may be etched and/or otherwise processed having any suitable pattern. For example, FIG. 17B shows padding 1118 having alternative embodiments of laser etching on the padding 1118.

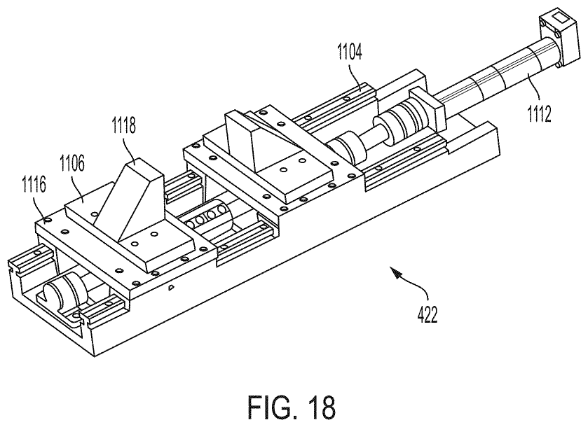

FIG. 18 illustrates a perspective view of the gripper of FIG. 11A, in accordance with some embodiments of the technology described herein.

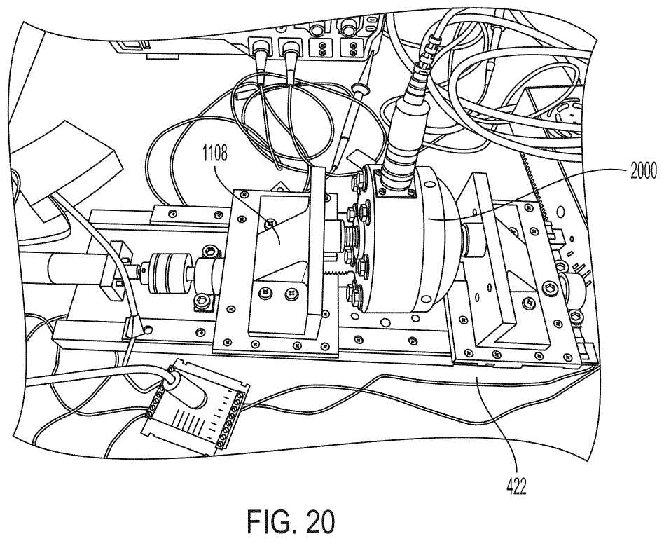

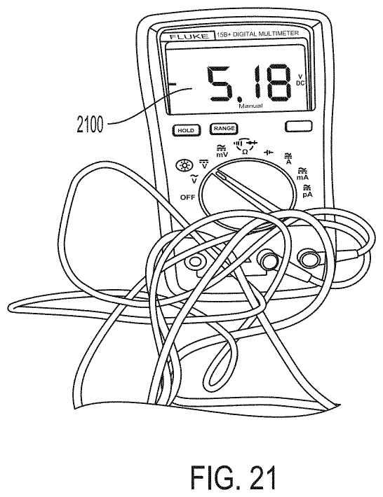

As described herein, the inventors have developed a gripper capable of exerting a high clamping force on an object disposed between first and second jaws to ensure the object is gripped without permitting slippage. The clamping force of the jaws 1108 can be verified with a load cell coupled to a digital multimeter. For example, the load cell can be a 500 lb range Futek load cell (LCF450) with a 10V range. FIG. 20 illustrates an illustrative example of the example gripper 422 of FIG. 11A exerting a clamping force on a load cell, in accordance with some embodiments of the technology described herein. The load cell 2000 can be coupled to a multimeter 2100, shown in FIG. 21, for measuring the clamping force of the jaws 1108. The reading from the multimeter 2100 in the embodiment illustrated in FIG. 21 is 5.18 V which corresponds to a clamping force of approximately 273 lbf.

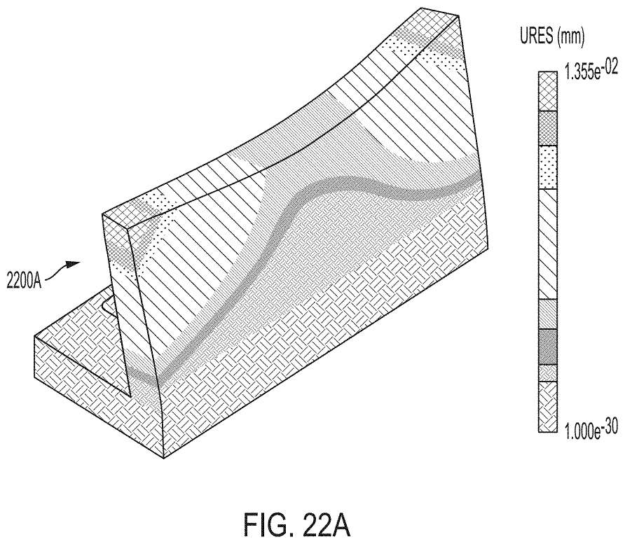

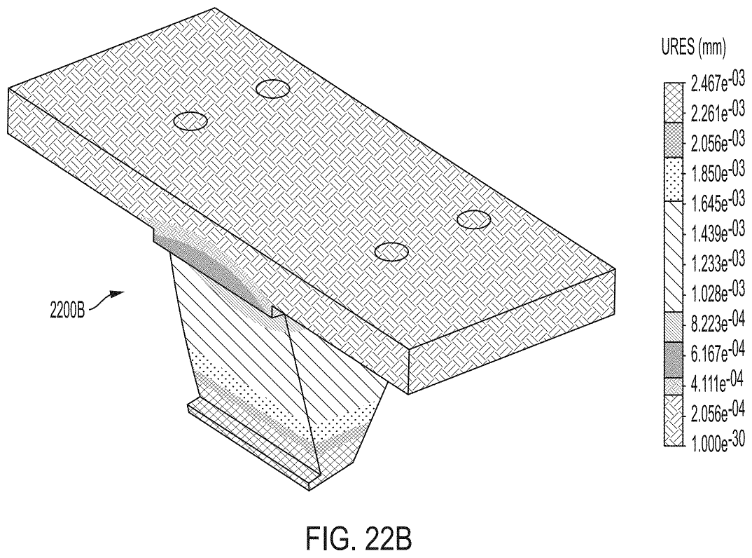

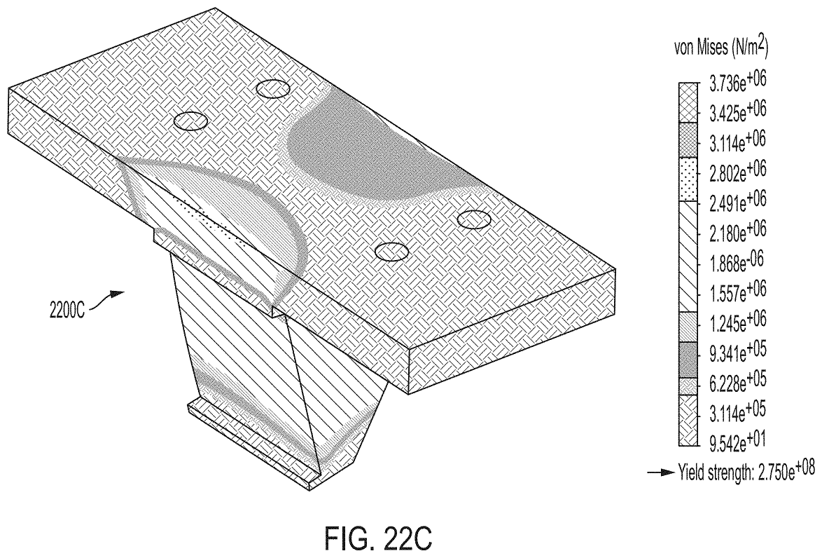

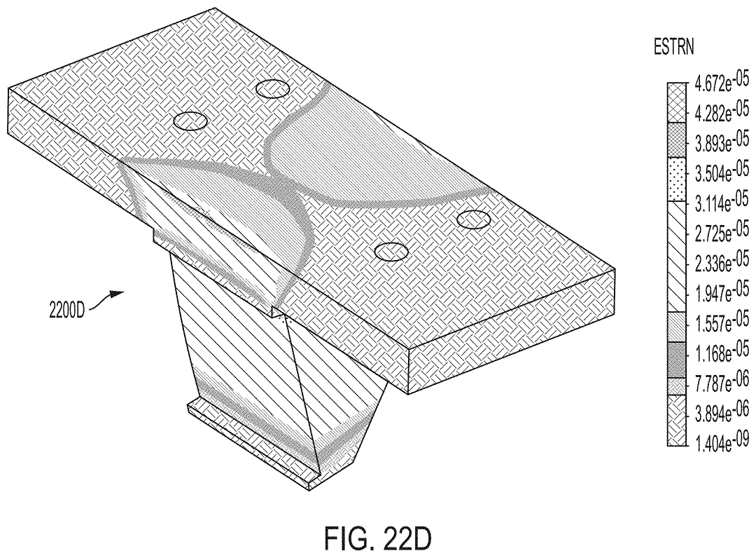

FIGS. 22A-B illustrate finite element method (FEM) simulations for determining maximum displacement of jaws of example grippers, in accordance with some embodiments of the technology described herein. The clamping force exerted by the jaws 1108 on an object disposed between the jaws 1108 may cause the first and second surfaces 1109A-B of the jaws to be displaced outwardly due to a reaction force generated by the object on the jaws 1108. FIG. 22A illustrates a FEM simulation 2200A measuring displacement of a jaw 1108 of the gripper 422 according to a first embodiment in response to a 200 kgf force exerted on the first and second surfaces 1109A-B of the jaws 1108. As shown in FIG. 22A, the maximum displacement of the jaws 1108 in the illustrated embodiment occurs at the upper ends of the first and second surfaces 1109A-B of the jaws 1108 and is approximately 0.013 mm. FIG. 22B illustrates a FEM simulation 2200B measuring displacement of a jaw 1108 of the gripper 422 according to a second embodiment in response to a 200 kgf force exerted uniformly on the first and second surfaces 1109A-B of the jaw 1108. As shown in FIG. 22B, the maximum displacement of the jaws in the illustrated embodiment occurs at the upper ends of the first and second surfaces 1109A-B of the jaws and is approximately 0.002 mm. The inventors have recognized that providing a gripper having jaws that exhibit minimal displacement even when subject to high forces promotes the gripping of an object without slippage. As described herein, maximizing the surface tension between the jaws of the gripper and an object disposed between the jaws prevents slippage of the object from between the jaws. By manufacturing the jaws such that displacement of the jaws is minimized, the jaws can remain substantially parallel the object disposed between the jaws and thereby fully contact the object with surfaces of the jaws. Therefore, maximal surface tension between the jaws and the object can be achieved when the jaws have the most surface contact with the object. The inventors have recognized that the jaws of the gripper may have sufficient surface tension to prevent slippage when the jaws are displaced no more than 0.05 mm. Therefore, it is desirable to manufacture jaws which deform no more than 0.05 mm when a force, e.g. a 200 kgf peak force, is exerted on the jaws.

FIG. 22C illustrates a FEM simulation 2200C measuring stress on a jaw 1108 of the gripper 422 according to a second embodiment in response to a 200 kgf force exerted on the first and second surfaces 1109A-B of the jaw 1108. Jaws 1108 of the gripper 422 may be able to withstand a high amount of stress. For example, as shown in FIG. 22C, the maximum stress experienced by the jaw 1108 due to a 200 kgf force is approximately 3.736×10⁶ Nm. FIG. 22D illustrates a FEM simulation 2200D measuring strain on the jaw 1108 shown in FIG. 22C. For example, as shown in FIG. 22D, the maximum strain experienced by the jaw 1108 due to a 200 kgf force is approximately 3.736×10⁶.

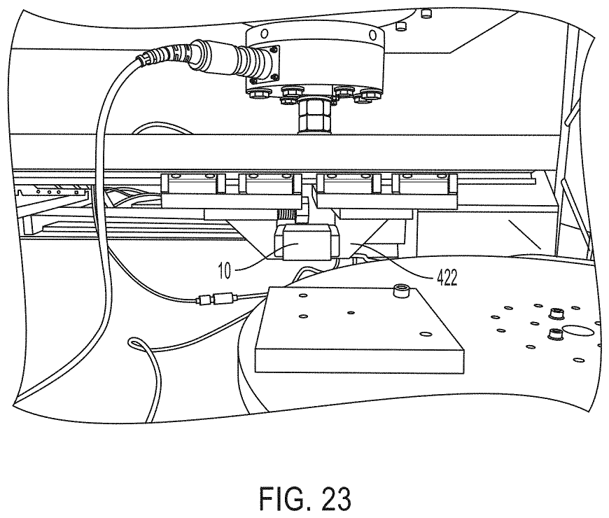

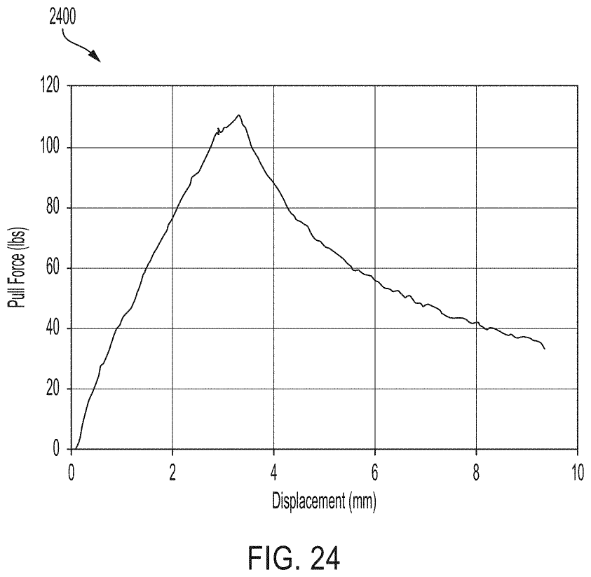

As described herein, the inventors have developed a gripper capable of gripping and object disposed between first and second jaws of the gripper without permitting slippage of the object. The anti-slip grip of the gripper 422 can be verified by the experimental set up shown in FIG. 23. For example, the gripper 422 can grasp a permanent magnet 10 between first and second jaws 1108A-B of the gripper while the permanent magnet 10 is in the presence of a high magnetic field exerting a strong magnetic pull force on the permanent magnet 10. A 500 lb load cell, such as the load cell 2000 in FIG. 20, can be mounted on top of the gripper to measure the pull force, as shown in FIG. 23, and a third motor 413 encoder can measure displacement between the permanent magnet 10 and the jaws 1108 of the gripper 422. FIG. 24 illustrates a measured pull force on a magnetic block held by an example gripper without slippage, in accordance with some embodiments of the technology described herein. As shown by the graph 2400 in FIG. 24, the gripper 422 is capable of holding the permanent magnet 10 between first and second jaws 1108A-B without slippage for pulling forces over 100 lbf.

As described herein, the robot 406 can be configured to assemble a magnet assembly 402 according to a specified layout 232. Various embodiments of the magnet assembly 402 will now be discussed further.

FIG. 26A illustrates an example configuration of a B₀ magnet 2600, in accordance with some embodiments. In particular, B₀ magnet 2600 is formed by permanent magnets 2610a and 2610b arranged in a bi-planar geometry with a ferromagnetic yoke 2620 coupled thereto to capture electromagnetic flux produced by the permanent magnets and transfer the flux to the opposing permanent magnet to increase the flux density between permanent magnets 2610a and 2610b. Each of permanent magnets 2610a and 2610b is formed from a plurality of concentric permanent magnet rings, as shown by permanent magnet 2610b comprising an outer ring of permanent magnets 2614a, a middle ring of permanent magnets 2614b, an inner ring of permanent magnets 2614c, and a permanent magnet disk 2614d at the center. Permanent magnet 2610a may comprise the same set of permanent magnet elements as permanent magnet 2610b. The permanent magnet material used may be selected depending on the design requirements of the system (e.g., NdFeB, SmCo, etc. depending on the properties desired).

The permanent magnet rings may be sized and arranged to produce a homogenous field of a desired strength in the imaging region between permanent magnets 2610a and 2610b. In the embodiment of FIG. 26A, each permanent magnet ring comprises a plurality of ferromagnetic blocks, such as permanent magnet 10, to form the respective ring. The blocks may be dimensioned and arranged to produce a magnetic field having desired characteristics such as strength and homogeneity. Furthermore, although B₀ magnets 2600 and 2700 are referred to herein as having “blocks”, it should be appreciated that magnets of the B₀ magnets 2600, 2700 may be manufactured having any suitable shape and aspects of the technology described herein are not limited to block-shaped permanent magnets.

B₀ magnet 2600 further comprises yoke 2620 configured and arranged to capture magnetic flux generated by permanent magnets 2610a and 2610b and direct it to the opposing side of the B₀ magnet to increase the flux density in between permanent magnets 2610a and 2610b, increasing the field strength within the field of view of the B₀ magnet. By capturing magnetic flux and directing it to the region between permanent magnets 2610a and 2610b, less permanent magnet material can be used to achieve a desired field strength, thus reducing the size, weight and cost of the B₀ magnet. Alternatively, for given permanent magnets, the field strength can be increased, thus improving the SNR of the system without having to use increased amounts of permanent magnet material. For example B₀ magnet 2600, yoke 2620 comprises a frame 2622 and plates 2624a and 2624b. In a manner similar to that described above in connection with yoke 2620, plates 2624a and 2624b capture magnetic flux generated by permanent magnets 2610a and 2610b and direct it to frame 2622 to be circulated via the magnetic return path of the yoke to increase the flux density in the field of view of the B₀ magnet. Yoke 2620 may be constructed of any desired ferromagnetic material, for example, low carbon steel, CoFe and/or silicon steel, etc. to provide the desired magnetic properties for the yoke. According to some embodiments, plates 2624a and 2624b (and/or frame 2622 or portions thereof) may be constructed of silicon steel or the like in areas where the gradient coils could most prevalently induce eddy currents.

Exemplary frame 2622 comprises arms 2623a and 2623b that attach to plates 2624a and 2624b, respectively, and supports 2625a and 2625b providing the magnetic return path for the flux generated by the permanent magnets. The arms are generally designed to reduce the amount of material needed to support the permanent magnets while providing sufficient cross-section for the return path for the magnetic flux generated by the permanent magnets. Arms 2623a and 2623b have two supports within a magnetic return path for the B₀ field produced by the B₀ magnet. Supports 2625a and 2625b are produced with a gap 2627 formed between, providing a measure of stability to the frame and/or lightness to the structure while providing sufficient cross-section for the magnetic flux generated by the permanent magnets.

FIG. 26B illustrates a top-down view of a permanent magnet 2710, which may, for example, be used as the design for permanent magnets 2610a and 2610b of B₀ magnet 2600 illustrated in FIG. 26A. Permanent magnet 2710 comprises concentric rings 2710a, 2710b, and 2710c, each constructed of a plurality of stacks of ferromagnetic blocks, and a ferromagnetic disk 2710d at the center. The direction of the frame of the yoke to which permanent magnet is attached is indicated by arrow 2722. In embodiments in which the yoke is not symmetric (e.g., yoke 2620), the yoke will cause the magnetic field produced by the permanent magnets for which it captures and focuses magnetic flux to be asymmetric as well, negatively impacting the uniformity of the B₀ magnetic field.

According to some embodiments, the block dimensions are varied to compensate for the effects of the yoke on the magnetic field produced by the permanent magnet. For example, dimensions of blocks in the four regions 2715a, 2715b, 2715c and 2715d labeled in FIG. 26B may be varied depending on which region the respective block is located. In particular, the height of the blocks (e.g., the dimension of the block normal to the plane of the circular magnet 2710) may be greater in region 2715c farthest away from the frame than corresponding blocks in region 2715a closest to the frame.

According to some embodiments, the material used for portions of yoke 2620 (i.e., frame 2622 and/or plates 2624a, 2624b) is steel, for example, a low-carbon steel, silicon steel, cobalt steel, etc. According to some embodiments, gradient coils (not shown in FIGS. 26A-26B) of the MRI system are arranged in relatively close proximity to plates 2624a, 2624b inducing eddy currents in the plates. To mitigate, plates 2624a, 2624b and/or frame 2622 may be constructed of silicon steel, which is generally more resistant to eddy current production than, for example, low-carbon steel.

It should be recognized that the permanent magnet illustrated in FIGS. 26A-26B can be manufactured using any number and arrangement of permanent magnet blocks and are not limited to the number, arrangement, dimensions or materials illustrated herein. The configuration of the permanent magnets will depend, at least in part, on the design characteristics of the B₀ magnet, including, but not limited to, the field strength, field of view, portability and/or cost desired for the MRI system in which the B₀ magnet is intended to operate. For example, the permanent magnet blocks may be dimensioned to produce a magnetic field ranging from 20 mT to 0.1 T, depending on the field strength desired. However, it should be recognized that other low-field strengths (e.g., up to approximately 0.2 T) may be produced by increasing the dimensions of the permanent magnet, though such increases will also increase the size, weight and cost of the B₀ magnet.

As discussed above, the height or depth of the blocks used in the different quadrants may be varied to compensate for effects on the B₀ magnetic field resulting from an asymmetric yoke. For example, in the configuration illustrated in FIG. 26A, the position of frame 2622 (in particular, legs 2625a and 2625b) to the permanent magnets 2610a and 2610b results in magnetic flux being drawn away from regions proximate the frame (e.g., quadrant 2615a), reducing the flux density in these regions.

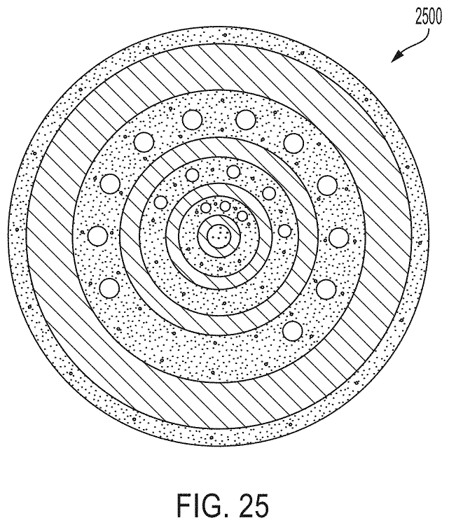

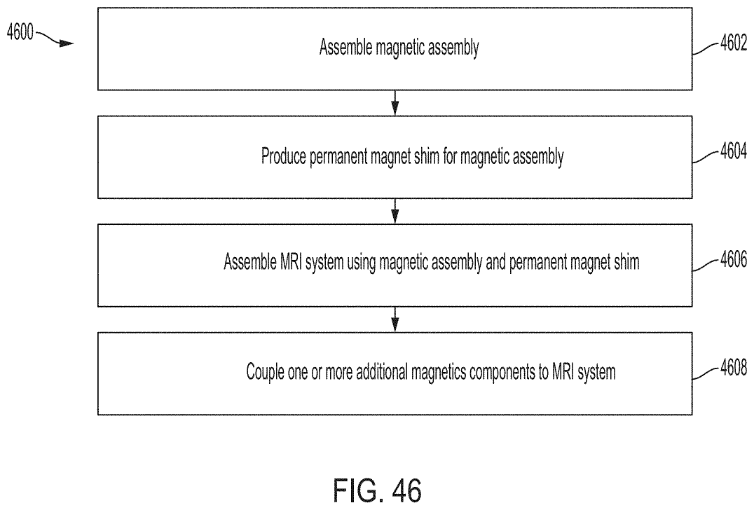

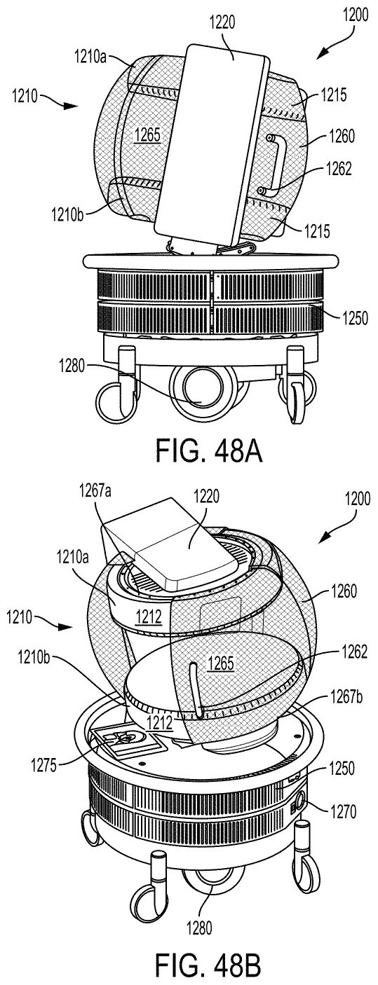

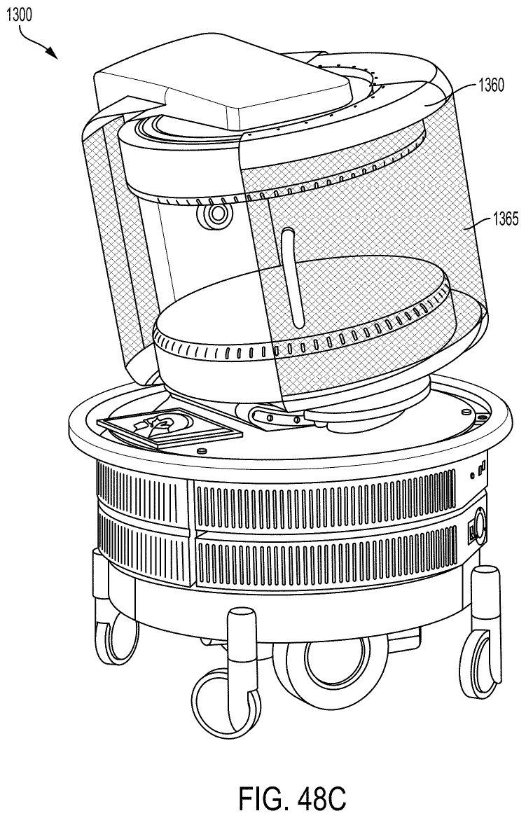

As described herein, the robot 406 may be configured to assemble a B₀ magnet in accordance with a specified permanent magnet layout. For example, FIG. 25 illustrates an embodiment of a B₀ magnet layout 2500 having a ring type structure comprising a plurality of concentric rings. In some embodiments, the B₀ magnet layout 2500 and other permanent magnet layouts described herein may be implemented in a point-of-care MRI system, such as the system described in FIGS. 46 and 48A-48C.

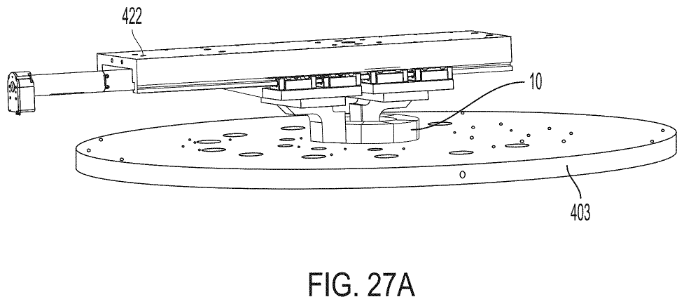

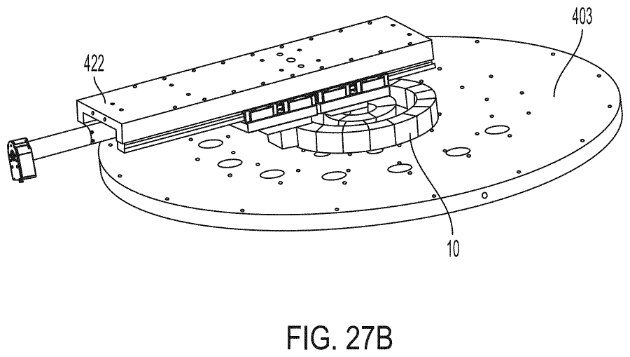

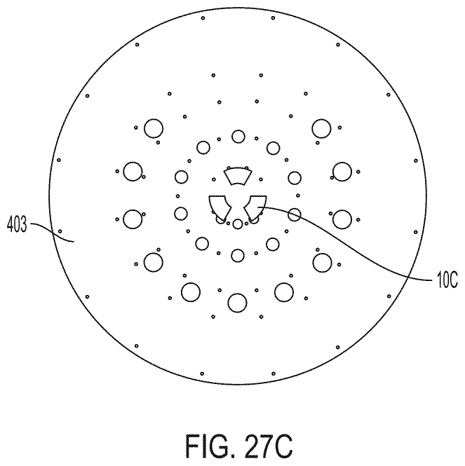

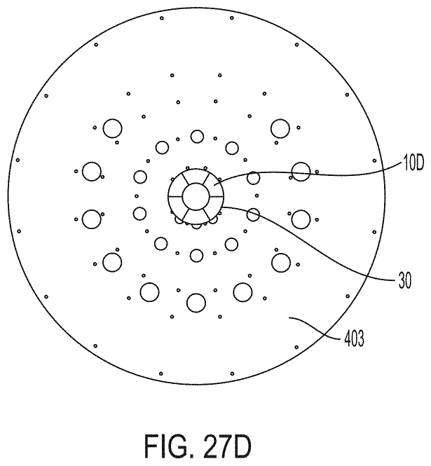

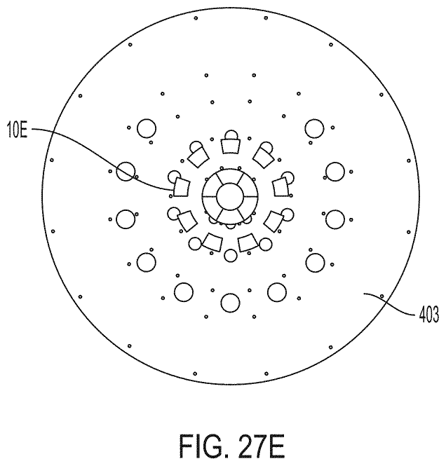

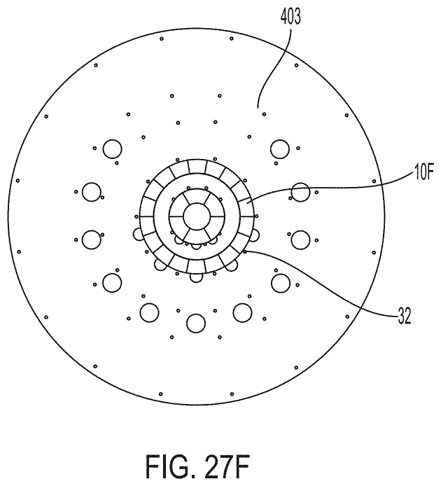

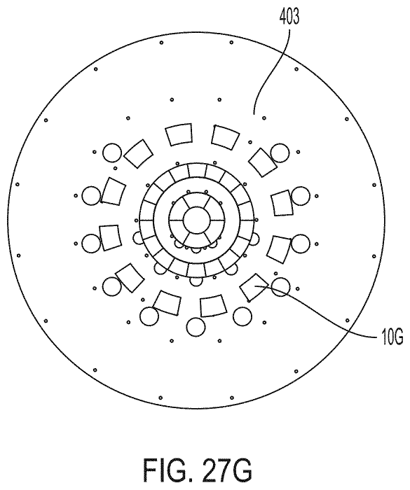

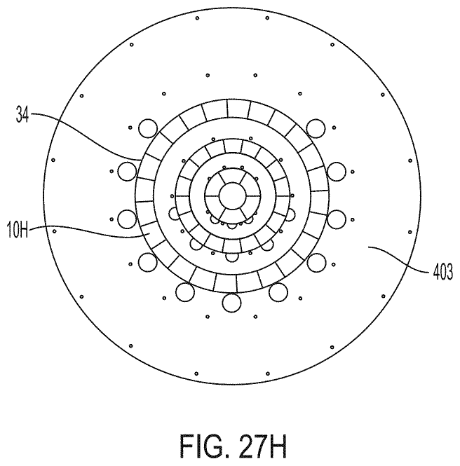

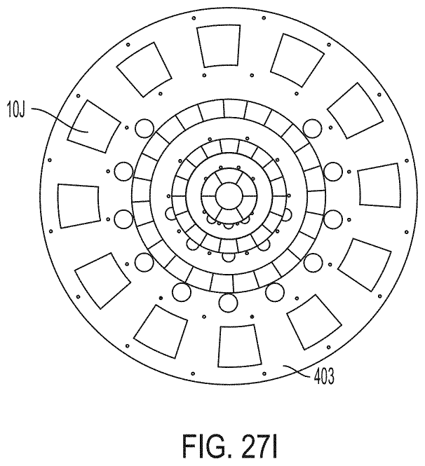

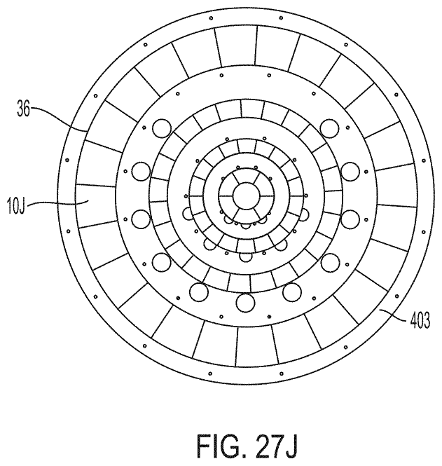

As described herein, a robotic gripper (e.g., gripper 422) may be configured to assemble a B₀ magnet according to a specified layout (e.g., a concentric ring layout) by grasping a permanent magnet 10, using first and second jaws 1108A-B of the gripper 422, lifting the permanent magnet 10, and positioning the permanent magnet 10 on the plate 403 in accordance with the specified layout 232. FIGS. 27A-27B illustrate views of the example gripper 422 of FIG. 11A placing and assembling permanent magnets 10 on a ferromagnetic plate 403, in accordance with some embodiments of the technology described herein.

FIGS. 27C-27J illustrate an example process of assembling a magnet assembly having a plurality of concentric rings according to a permanent magnet layout, in accordance with some embodiments of the technology described herein. In FIG. 27C, permanent magnets 10C are positioned in anchoring positions on the ferromagnetic surface 403. In FIG. 27D, permanent magnets 10D are positioned among the permanent magnets 10C positioned in anchoring positions to form an inner ring 30. In the illustrated embodiment, the set of permanent magnets 10C and the set of permanent magnets 10D each consists of three permanent magnets. However, any suitable number of permanent magnets may be used to form a permanent magnet ring, such as inner ring 30, as aspects of the technology described herein are not limited in this respect.

The inventors have recognized that it is advantageous to first position a set of permanent magnets at anchoring positions and subsequently position a second set of permanent magnets between the first set of permanent magnets to improve robustness and accuracy of the magnet assembly process. A permanent magnet being positioned on a ferromagnetic plate 403 will experience a large pulling force when close to the ferromagnetic plate 403 due to the magnetic field generated by components of the magnetic assembly 402. Particularly, adjacent permanent magnets already assembled on the ferromagnetic plate 403 may exert strong lateral pulling forces on neighboring permanent magnets being positioned by the gripper 422. By positioning a first set of permanent magnets in anchoring positions first, and placing a second set of permanent magnets among permanent magnets already in the anchoring positions, the lateral pulling forces on the permanent magnets being placed will be balanced and therefore be reduce or eliminated. In addition, placing a permanent magnet in a position equidistant from neighboring permanent magnets further reduces the effect of lateral pulling forces on a permanent magnet being positioned. However, in other embodiments, permanent magnets may be positioned according to an alternative sequence (e.g., without regard to minimizing lateral magnetic forces), for example, by placing neighboring permanent magnets next to each other, one by one, on the ferromagnetic plate in a clockwise or counterclockwise manner.

In FIG. 27E, permanent magnets 10E are placed in anchoring positions on the ferromagnetic plate 403 outside of the inner ring 30. In FIG. 27F, permanent magnets 10F are placed between permanent magnets 10E positioned in anchoring positions to form a first middle ring 32. In the illustrated embodiment, each of the third set of permanent magnets 10E and the fourth set of permanent magnets 10F consists of nine permanent magnets, however, any suitable number of permanent magnets may be used to form a first middle ring, such as first middle ring 32, as aspects of the technology described herein are not limited in this respect.

In FIG. 27G, permanent magnets 10G are placed in anchoring positions on the ferromagnetic plate 403 outside of the first middle ring 32 and the inner ring 30. In FIG. 27H, permanent magnets 10H are placed between permanent magnets 10G positioned in anchoring positions to form a second middle ring 34. In the illustrated embodiment, permanent magnets 10G and the permanent magnets 10H each consist of twelve permanent magnets. However, any suitable number of permanent magnets may be used to form a second middle ring, such as second middle ring 34, as aspects of the technology described herein are not limited in this respect.

In FIG. 27I, permanent magnets 10I are placed in anchoring positions on the ferromagnetic plate 403 outside of the second middle ring 34, the first middle ring 32, and the inner ring 30. In FIG. 27J, permanent magnets 10J are placed between permanent magnets 10I to form an outer ring 36. In the embodiment illustrated in FIG. 27J, the outer ring 36, the second middle ring 34, the first middle ring 32, and the inner ring are concentric. In the illustrated embodiment, permanent magnets 10I and permanent magnets 10J each consist of twelve permanent magnets, however, any suitable number of permanent magnets may be used to form an outer ring, such as outer ring 36, as aspects of the technology described herein are not limited in this respect.

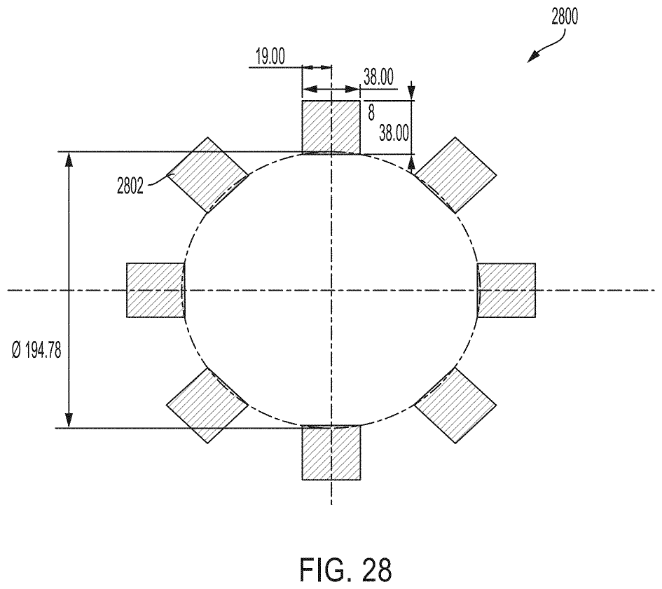

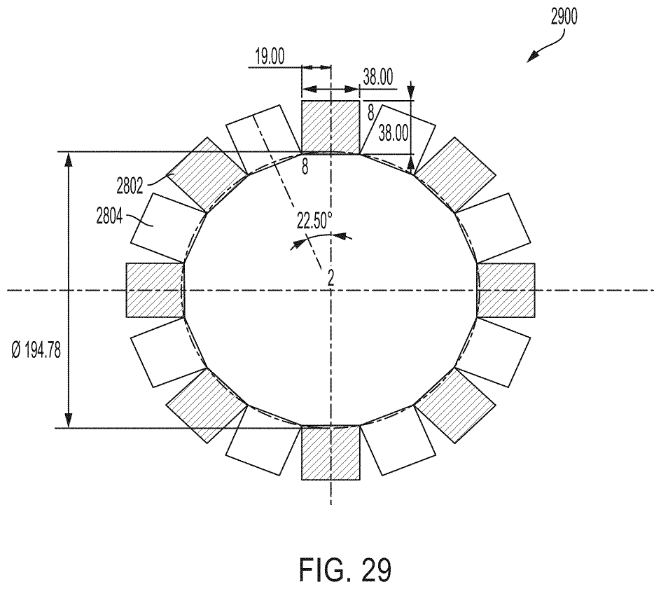

FIGS. 28-29 illustrate an example permanent magnet layout for a ring-type magnet assembled by the example system of FIG. 1, in accordance with some embodiments of the technology described herein. In FIG. 28, an assembly pattern 2800 is shown having eight permanent magnets 2802 positioned in anchoring positions. In FIG. 29, an assembly pattern 2900 is shown having eight permanent magnets positioned between pairs of anchoring permanent magnets 2802.

Various magnet assemblies can be achieved by the methods and systems described herein. For example, as shown in FIGS. 27A-27J, the methods and systems described herein may be used to create a magnet assembly having a plurality of concentric rings. In the illustrated embodiment, the magnet assembly comprises four concentric rings, however, the magnet assembly may comprise any suitable number of concentric rings (e.g., a single ring, two rings, three rings, five rings, etc.). Furthermore, each ring may be configured having any suitable number of permanent magnets. In some embodiments, the magnet assembly comprises four concentric rings: an inner ring having 7 permanent magnets, a first middle ring having 15 permanent magnets, a second middle ring having 28 permanent magnets, and an outer ring having 30 permanent magnets, however, other embodiments are within the scope of the technology described herein. The robot and gripper described herein are capable of precisely positioning the one or more permanent magnets on the ferromagnetic surface such that a large number of permanent magnets per ring can be placed (e.g., at least 20 permanent magnets per ring, at least 25 permanent magnets per ring, etc.). The robot and gripper described herein are also capable of precisely positioning a large number of permanent magnets total. In some embodiments, the total number of permanent magnets per magnet assembly positioned by the robot and gripper is at least 20 permanent magnets, at least 50 permanent magnets, at least 80 permanent magnets or any other suitable number of permanent magnets for a particular magnet layout.

The plurality of concentric rings may be configured having any suitable dimensions. In particular, because the robot 406 and gripper 422 can translate and rotate along multiple axes, the robot 406 and gripper 422 can create a magnetic assembly having any desired dimension without the need to interchange components of the robot, gripper, or ferromagnetic plate to achieve magnet assemblies of different dimensions. In some embodiments, an inner ring of permanent magnets comprises an outer diameter of at least 50 millimeters, a first middle ring of permanent magnets comprises an outer diameter of at least 100 millimeters, a second middle ring of permanent magnets comprises an outer diameter of at least 300 millimeters, and an outer ring of permanent magnets comprises an outer diameter of at least 500 millimeters.

The robot 406 and gripper 422 may further achieve positioning and placement of the plurality of permanent magnets at a high rate of placement. For example, in some embodiments, the robot 406 and gripper 422 can place at least one permanent magnet every 3.5 minutes. The rate of placement may include the time necessary to hold the permanent magnet in place on the ferromagnetic plate to allow the adhesive (e.g., epoxy) to dry, as described herein. For larger permanent magnets, the drying time may be longer, and thus the rate of placement is decreased. For smaller permanent magnets, the drying time is shorter, and more permanent magnets can be positioned and placed in a particular amount of time. In some embodiments, at least one permanent magnet is placed every 3 minutes, every 2.5 minutes, every 2 minutes, every 1.5 minutes, every 1 minute, etc. As some magnet assemblies comprise a large number of permanent magnets (e.g., at least 80 permanent magnets per ferromagnetic plate), a high rate of positioning and placement of the permanent magnets facilitates efficient formation of the permanent magnet assembly.

As shown in the illustrated embodiments herein, each of the concentric rings of a magnet assembly may comprise permanent magnets of different sizes. For example, permanent magnets of the outer ring may be larger than permanent magnets of the inner ring, as the size of the permanent magnets may increase for each successive ring. In other embodiments, the size of the permanents magnets may decrease for each successive ring. In some embodiments, some or all of the concentric rings may comprise permanent magnets of the same or approximately the same size and/or shape.

The permanent magnets used to assemble the concentric rings of the magnet assembly may have any suitable dimensions. For example, as shown in FIGS. 28-29, the permanent magnets may be rectangular in shape and comprise a maximum dimension of no more than approximately 40 millimeters. In some embodiments, one or more of the permanent magnets may have a maximum dimension of no more than 80 millimeters. In some embodiments, the permanent magnet may be tapered in shape (e.g., as shown in FIGS. 26C-26D) comprising a first end and a second end opposite the first end. The first end may have length of at least 20 millimeters and no more than 50 millimeters and the second end may have a length of at least 30 millimeters and no more than 70 millimeters. The difference in length between the first end and the second end (due to the tapered shape of the permanent magnet) may be at least 5 millimeters.

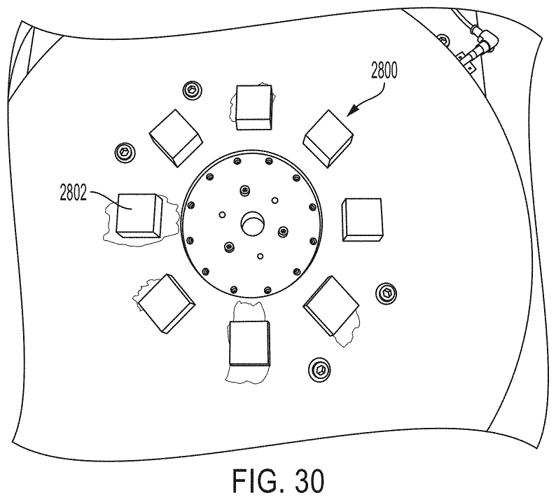

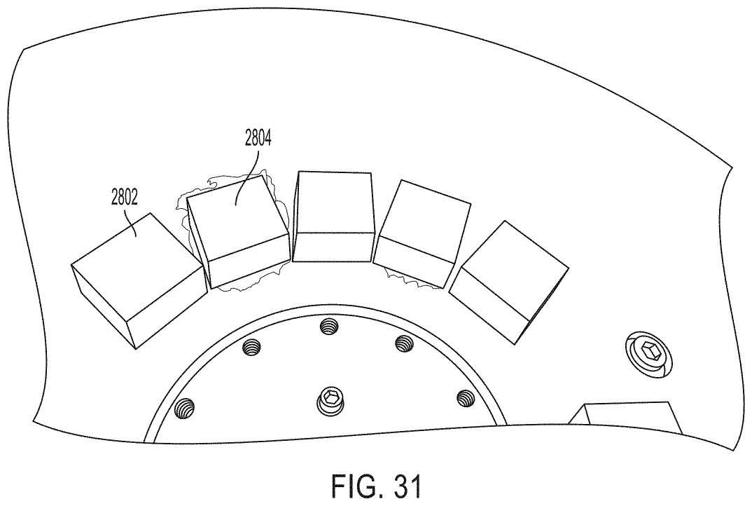

FIG. 30 illustrates an example magnet assembly having the first set of permanent magnets 2802 positioned in anchoring positions according to the assembly pattern 2800 in FIG. 28, in accordance with some embodiments of the technology described herein. FIG. 31 illustrates part of an example magnet assembly having first and second sets of permanent magnets 2802, 2804 positioned according to the assembly pattern 2900 of FIG. 29, in accordance with some embodiments of the technology described herein.

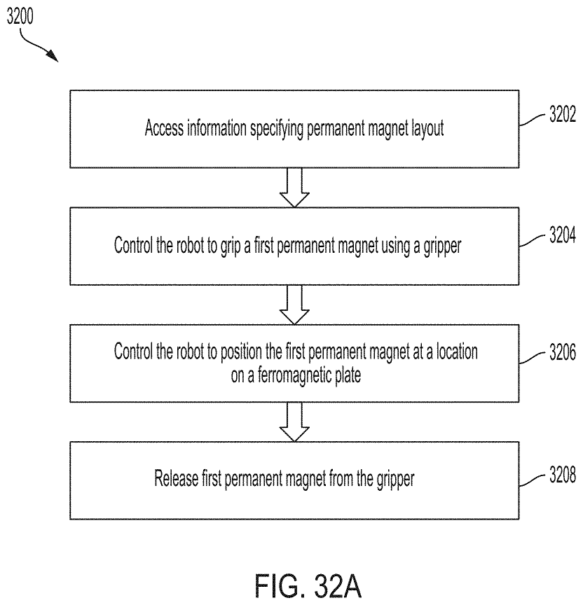

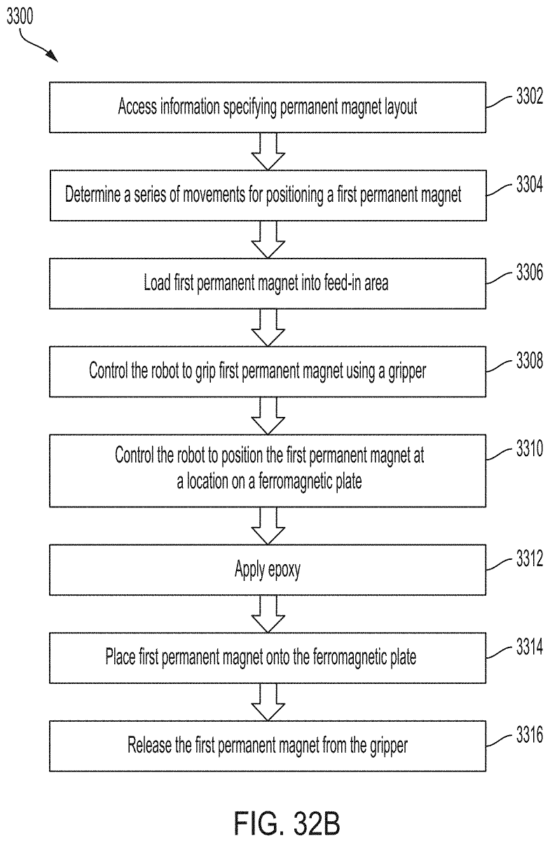

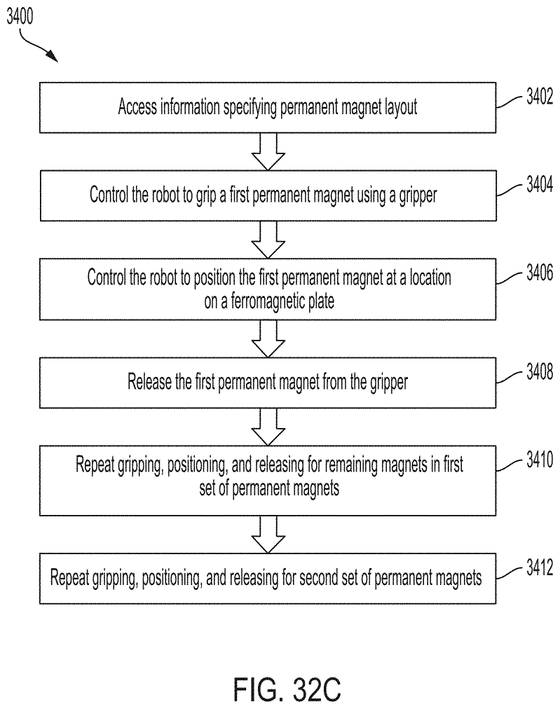

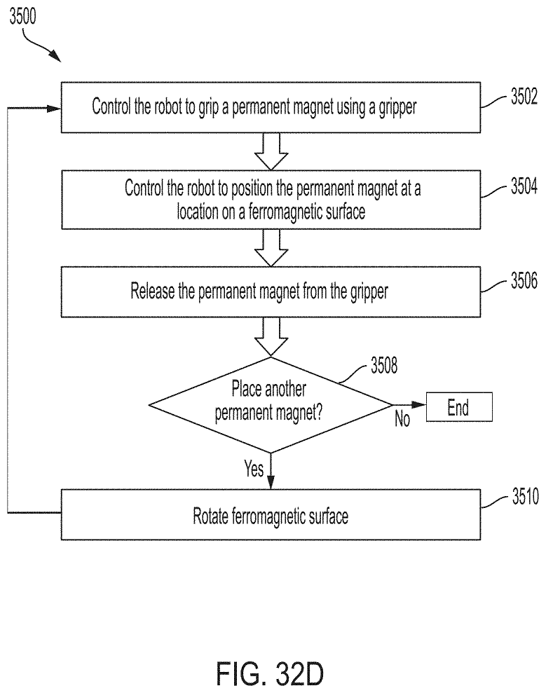

FIGS. 32A-32D illustrate example methods of assembling a magnet assembly using the example robot of FIG. 4A, in accordance with some embodiments of the technology described herein. In some embodiments, the methods described herein may be performed by system 400 comprising robot 406 having robotic arm 408 with multiple arm segments (e.g. first arm segment 419, second arm segment 415, and third arm segment 411) movable along respective degrees of freedom (e.g. the A, B, C axes and AC and BC planes of rotation described herein), and gripper 422 having first and second jaws 1108A-B movably coupled to base 1102 of gripper 422. It should be appreciated that any of the systems described herein and variants thereof may be used to perform the processes illustrated in FIGS. 32A-32D.

FIG. 32A is a flowchart of an illustrative process 3200 for placing permanent magnets on a ferromagnetic plate in accordance with a specified permanent magnet layout for a magnet assembly, using the system 400 described herein.

Process 3200 begin at act 3202, where information specifying permanent magnet layout is accessed, for example, by controller 228 of system 400. Information specifying permanent layout may be stored, for example, in a data store of system 400. In some embodiments, information specifying permanent layout indicates a series of movements to be made by the robot 406 to position one or more permanent magnets.

Next, at act 3204, the robot 406 is controlled to grip a first permanent magnet using a gripper, for example, gripper 422. For example, robot 406 may be configured to position gripper 422 at a feed-in area of the system. First and second jaws of the gripper 422 may be configured to grip a first permanent magnet by exerting a clamping force on first permanent magnet.

Next, at act 3206, the robot 406 is controlled to position the first permanent magnet at a location on a ferromagnetic plate. For example, robot 406 may move along respective degrees of freedom, including translational and rotational movement as described herein, to position the gripper 422 over a ferromagnetic plate.

Next, at act 3208, the robot 406 is controlled to release the first magnet from the gripper 422. For example, gripper 422 may release the first permanent magnet from the gripper 422 by moving first and second jaws away from the permanent magnet.

One or more acts of the process 3200 (e.g., acts 3206-3208) may be repeated to position multiple permanent magnets on a ferromagnetic plate in accordance with the layout obtained at 3202.

FIG. 32B is a flowchart of another illustrative process 3300 for placing permanent magnets on a ferromagnetic plate in accordance with a specified permanent magnet layout.

Process 3300 begins at act 3302, information specifying permanent magnet layout is accessed, for example, by a controller of the system.

Next, at act 3304, a series of movements for positioning a first permanent magnet is determined, for example, by a controller of the system. For example, the series of movements of positioning a first magnet may be used to move the robot 406 along respective degrees of freedom. For example, a controller of the system may transmit commands to the one or more motors of the robot based on the series of movements for positioning a first permanent magnet determined in act 3304. The series of movements for positioning a first magnet may be determined based on the information specifying permanent layout accessed in act 3302. In some embodiments, act 3304 is performed by an external device external to the system and the determination may be transmitted to the system.

Next, at act 3306, a first permanent magnet is loaded into a feed-in area. Act 3306 may be performed according to the techniques described herein. For example, act 3306 may be performed manually in some embodiments. In other embodiments, act 3306 is performed automatically by system 400 or by an external device.

Next, at act 3308, the robot 406 is controlled to grip a first permanent magnet using a gripper, for example, gripper 422.

Next, at act 3310, the robot 406 is controlled to position the first permanent magnet at a location on a ferromagnetic plate.

Next, at act 3312, epoxy is applied to a surface of the first permanent magnet and/or to the ferromagnetic surface. Epoxy may be applied according to the techniques described herein, for example, manually, or automatically using the system 400 or an external device.

Next, at act 3314, the first permanent magnet is placed onto the ferromagnetic plate of the magnetic assembly, and in act 3316, the first permanent magnet is released from jaws of the gripper. One or more acts of the process 3300 (e.g., acts 3306-3314) may be repeated to position multiple permanent magnets on a ferromagnetic plate in accordance with the layout obtained at 3302.

FIG. 32C is a flowchart of another illustrative process 3400 for placing permanent magnets on a ferromagnetic plate, in accordance with a specified permanent magnet layout.

Process 3400 begins at act 3402, where information specifying permanent magnet layout is accessed. Next, at act 3404, the robot 406 is controlled to grip a first permanent magnet using a gripper, for example, gripper 422. Next, at act 3406, the robot is controlled to position the first permanent magnet at a location on a ferromagnetic plate. Next, at act 3408, the robot is controlled to release the first permanent magnet from the gripper.

In act 3410, the robot is controlled to repeat the gripping, positioning, and releasing acts 3404-3408 for the remaining permanent magnets in a first set of permanent magnets.

In act 3412, the robot is controlled to repeat the gripping, positioning, and releasing acts 3404-3408 for a second set of permanent magnets. For example, in some embodiments, the first set of permanent magnets may be placed in anchoring positions and ones of the second set of permanent magnets may be placed between pairs of permanent magnets of the first set of permanent magnets as described herein.

FIG. 32D is a flowchart of another illustrative process 3500 for placing permanent magnets on a ferromagnetic plate in accordance with a specified permanent magnet layout.

In act 3502, the robot is controlled to grip a permanent magnet using a gripper.

In act 3504, the robot is controlled to position the permanent magnet at a location on a ferromagnetic plate.

In act 3506, the robot is controlled to release the permanent magnet from the gripper.

Next, process 3500 proceeds to decision block 3508, where it is determined whether another permanent block is to be placed on the ferromagnetic plate. That decision may be made based on a specified permanent magnet layout, in some embodiments. For example, the determination to place an another permanent magnet on the ferromagnetic plate may be when it is determined that there are permanent magnets in the layout that have not yet been placed by the robot.

When it is determined, in act 3508, that another permanent magnet is to be placed, the process moves to act 3510. In act 3510, the ferromagnetic plate is rotated. For example, as described herein, the ferromagnetic plate may comprise a turn table and the ferromagnetic plate may be rotated by a system motor coupled to the system. After rotating the ferromagnetic plate in act 3510, the process 3500 returns via the “yes” branch to act 3502. On the other hand, when it is determined that no additional magnets are to be placed, the process 3500 completes.

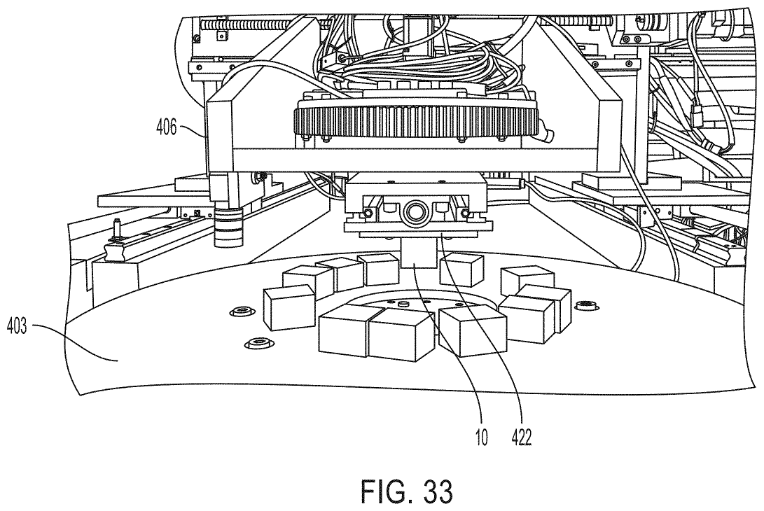

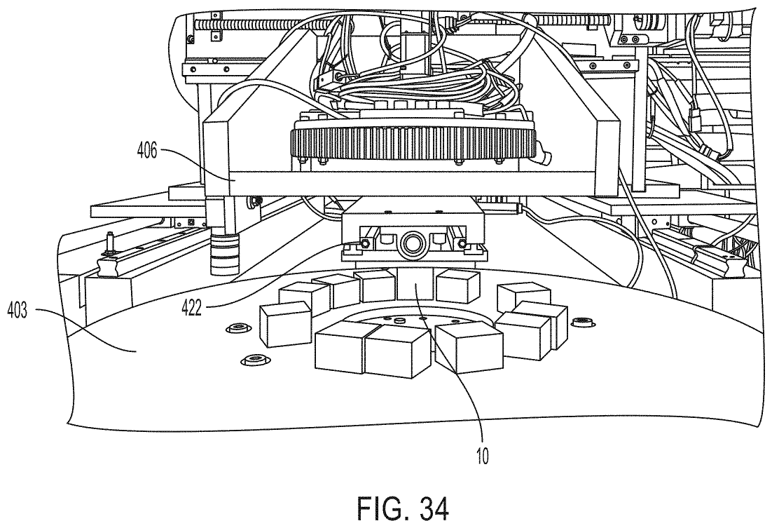

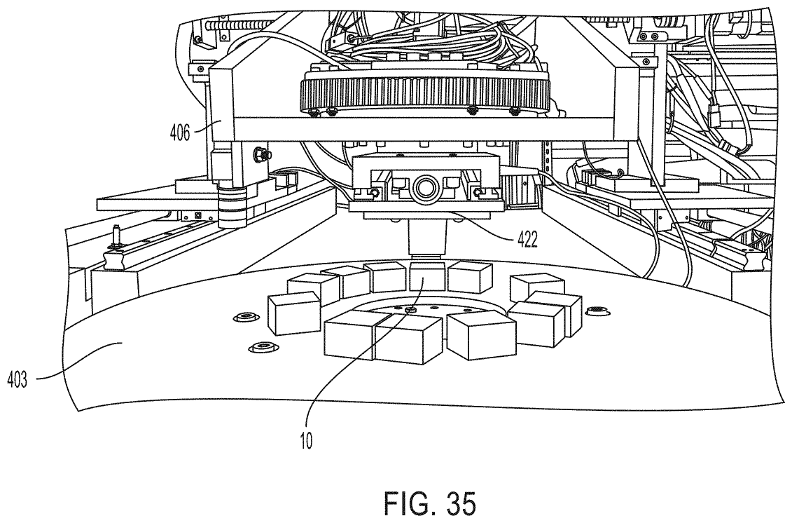

Aspects of the methods described herein are shown in FIGS. 33-35. For example, FIG. 33 illustrates an example of robot 406 using the gripper 422 to place a permanent magnet 10 between a pair of permanent magnets placed in anchoring positions on a ferromagnetic plate 403, in accordance with some embodiments of the technology described herein. FIG. 34 illustrates an example of robot 406 using gripper 422 to hold a permanent magnet 10 between a pair of permanent magnets, placed in anchoring positions, for epoxy hardening on a ferromagnetic plate 403, in accordance with some embodiments of the technology described herein. FIG. 35 illustrates an example of robot 406 using the gripper 422 to release a permanent magnet 10 inserted between a pair of permanent magnets placed in anchoring positions on a ferromagnetic plate 403, in accordance with some embodiments of the technology described herein.

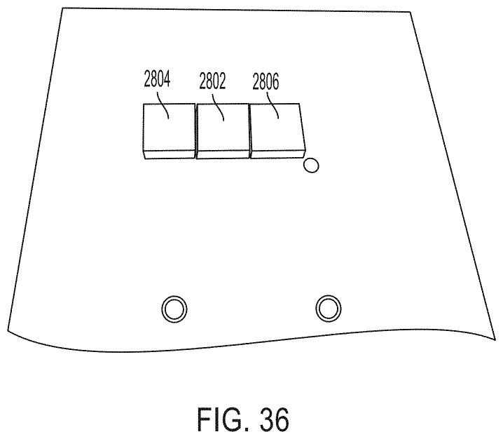

The inventors have developed a system 400 having a robot 406 and gripper 422 capable of tightly positioning permanent magnets, for example, permanent magnets separated by less than 25 mm. FIG. 36 illustrates an example of three permanent magnets positioned on a ferromagnetic plate assembled by the example system of FIG. 1. For example, permanent magnet 2802 is placed between neighboring permanent magnets 2804 and 2806 which have been positioned in anchoring positions with minimal spacing between each of the permanent magnets. For example, in some embodiments, the distance between adjacent permanent magnets is no more than 2.0 mm, 1.5 mm, 1.0 mm, etc.

FIG. 37 illustrates an example of robot 406 using gripper 422 to place a permanent magnet 2804 between a pair of permanent magnets 2802, 2806 placed in anchoring positions on a ferromagnetic surface, in accordance with some embodiments of the technology described herein. The direction of the downward pulling force on the permanent magnet 2804 is shown by arrow 2808 in FIG. 37.

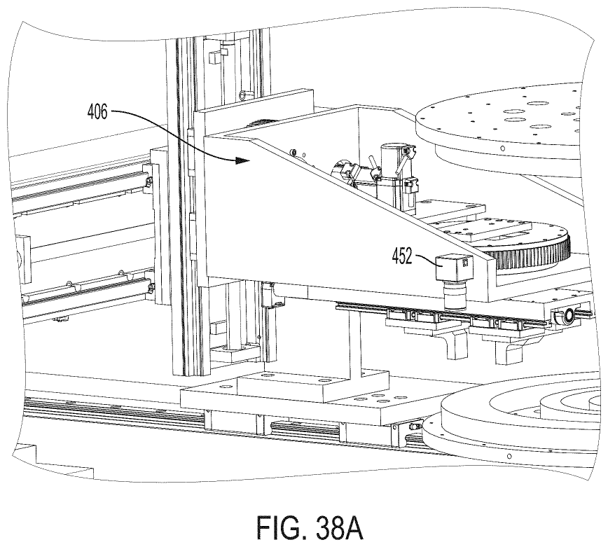

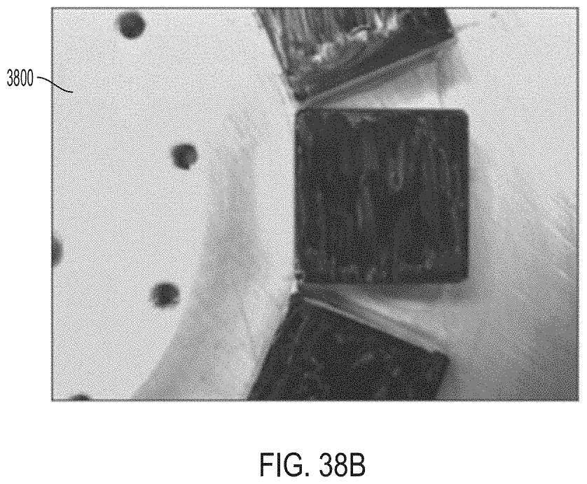

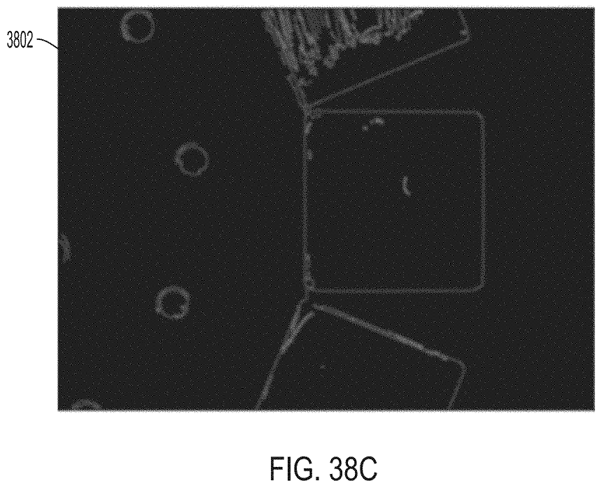

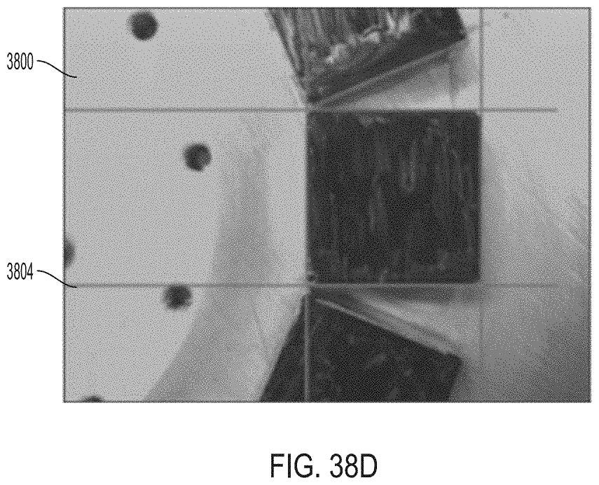

In some embodiments, the system 1 further comprises a monitoring system 24. FIGS. 38A-38D illustrate aspects of an example monitoring system for monitoring the placement of permanent magnets on a ferromagnetic plate, in accordance with some embodiments of the technology described herein. Monitoring system 24 may be used to ensure the position and orientation of the assembled permanent magnets is within specified tolerances.

Monitoring system 24 may comprise one or more cameras 222 for monitoring the positioning and placement of permanent magnets. A camera 222 may of any suitable type. Non-limiting examples include: a color camera, a monochrome camera, a 1/1.8″ Monochrome CMOS camera (1600×1200 pixels), a camera having a frame rate of at least 50 FPS, a USB camera, a camera with a high contrast megapixel lens, or a camera with a fixed focal length lens (e.g., a 12 mm lens).

In the embodiment illustrated in FIG. 38A, a first camera 452 is coupled to the robot 406. The first camera 452 may provide a top view of the ferromagnetic plate 403 during placement of the plurality of permanent magnets on the ferromagnetic plate 403. In the illustrated embodiment, first camera 452 is shown coupled to the gripper 422 adjacent to the housing 434, but could be coupled to gripper 422 at different locations (e.g., between the jaws). Although one camera is shown in FIG. 38A, as being coupled to the gripper 422, in other embodiments, multiple cameras may be coupled to the gripper 422, as aspects of the technology described herein are not limited in this respect.

In some embodiments, a second camera may be coupled to the gripper 422, for example, between first and second jaws 1108A, 1108B of the gripper 422. The second camera may be configured to monitor the alignment of a permanent magnet while the permanent magnet is grasped between the first and second jaws 1108A, 1108B of the gripper 422.

Additionally or alternatively, the monitoring system 24 may include an external camera decoupled from the robot 406 configured to provide a side view of the robot 406 and the magnet assembly 402 during placement of the plurality of permanent magnets on the ferromagnetic plate 403. Monitoring system 24 can be implemented having any suitable number of cameras, including one or more cameras 222 coupled to the robot 406 and/or one or more cameras 222 external to the system 400, as aspects of the technology described herein are not limited in this respect.

In some embodiments, the monitoring system 24 may be configured to determine characteristics of permanent magnets before, during, and/or after placement of their placement on the ferromagnetic plate 403. For example, one or more of the cameras 222 may capture one or more images (e.g., the images shown in FIGS. 38B-38D) and/or video of the assembly process, and the captured image(s) and/or video(s) may be automatically processed using image and/or video processing techniques to determine various permanent magnet characteristics. Examples of such characteristics include, but are not limited to, alignment of a permanent magnet placed on a ferromagnetic plate with its neighbors on the ferromagnetic plate, alignment of a permanent magnet placed on the ferromagnetic plate with the planned position for that magnet on the plate in accordance with the layout being assembled, dimensions of the magnet, and whether there is any damage to and/or defects of the magnet. The image and/or video techniques may utilize algorithms implemented in libraries such as Open Source Computer Vision Library (OpenCV) and/or any other suitable software libraries.

For example, a software library such as OpenCV may be used to process an image captured by the one or more cameras 222, detect features of a permanent magnet, and conduct a measurement and alignment check of the permanent magnet. For example, FIG. 38B illustrates an example image 3800 captured by the one or more cameras 222. FIG. 38C illustrates an example image 3802 being processed by the monitoring system 24, for example, to detect features of a permanent magnet in the image 3802 using histogram equalization and Gaussian blur. FIG. 38D illustrates results of applying edge detection techniques (e.g., a Hough transform) to the example image 3800—the detected lines 3804 are overlaid onto the image 3800. In some embodiments, the detected lines may be used to determine the position and/or orientation (pose) of the permanent magnet with respect to (e.g., a center of a) camera.

In some embodiments, the monitoring system 24 may be configured to compare the placement of the permanent magnets with a specified layout to determine whether there is any deviation in the placement of the permanent magnets from the specified layout and the extent of such deviation, if any. In some embodiments, the monitoring system 24 may be configured to determine whether the deviation in the placement of the permanent magnets is within an tolerance indicative of an acceptable amount of deviation in the placement of the permanent magnets. In some embodiments, the deviation tolerance may vary depending on the specified layout. In some embodiments, the deviation tolerance may be set by a user.

As described herein, the monitoring system 24 may be configured to display information related to the alignment of one or more permanent magnets using the GUI 300. For example, a user may use the GUI to view images and/or video of the placement of the permanent magnets on the ferromagnetic plate 403. In some embodiments, the system 400 may be configured to automatically and/or upon request display information related to the alignment of the permanent magnets using the GUI 300, including, for example, images and/or video captured by the one or more cameras 222 of the monitoring system 24 during placement of the permanent magnets on the ferromagnetic plate 403, deviation in the placement of a permanent magnet as compared to a specified layout, and/or an alert that the deviation in the placement of a permanent magnet as compared to a specified layout is outside of a deviation tolerance.

As described herein, the inventors have developed a gripper capable of gripping a permanent magnet experiencing large pulling forces without slippage. As described herein, a permanent magnet may experience a large pulling force when the permanent magnet approaches the ferromagnetic plate. For a N42 neodymium permanent magnet and having dimensions 38 mm×38 mm×26 mm, for example, the pulling force on the permanent magnet could as much as 500 N.

FIG. 39A illustrates an example model of forces exerted on a permanent magnet during positioning of the permanent magnet in a magnet assembly, in accordance with some embodiments of the technology described herein. As shown in FIG. 39A, the strength of the pull force, F, on the permanent magnet having width 2b can be expressed as an integral according to:

F=∫_{-b}^{b}f(x)dx

The surface pressure, P, exerted on each side of a permanent having height 2a can be expressed as an integral according to:

P=∫₋ₐ^{a}p(y)dy

The surface tension, T, applied on each side of the permanent having height 2a can be expressed as an integral according to:

T=∫₋ₐ^{a}t(y)dy

The relationship of the pull force, F, surface tension, T, and surface pressure, P, can be expressed by the Coulomb Friction Law shown by the following equation, where μ is the Coulomb Friction Coefficient between the first and second jaws and the permanent magnet:

F=2*T=2*μ*P

The above equation can be rewritten as:

∫_{-b}^{b}f(x)dx=2*∫₋ₐ^{a}t(y)dy=2*μ*∫₋ₐ^{a}p(y)dy

Thus, it is shown that the pulling force, F, is proportional to the surface tension, T, and the surface pressure, P. As such, the inventors have recognized that increasing the surface tension between the permanent magnet and the first and second jaws of the gripper to be sufficiently high prevents slippage of the permanent magnet from between the first and second jaws.

According to some aspects of the technology described herein, the inventors have developed a gripper capable of firmly holding a permanent magnet between jaws of the gripper without the need for modifying coating or geometry of the magnet. However, the inventors have recognized that methods of preparing the permanent magnets and/or the gripper 422 prior to assembly of the magnet assembly 402 may be advantageous.

In some embodiments, additional surface texture may be added to the surface of a permanent magnet to increase the coefficient of friction between the permanent magnet and jaws of the gripper. In some embodiments, adding additional surface texture to the magnetic block comprises applying rough plastic shims to the magnetic block. For example, FIG. 39B illustrates an example of a permanent magnet 10 having shims 3902 applied to the surface of the permanent magnet 10. The inventors have recognized that adding additional surface texture to the surface of the magnetic block presents a tradeoff between slippage of the magnetic block from the jaws 1108 of the gripper 422 and homogeneity of the magnetic field produced by the one or more magnetic blocks.

In some embodiments, additional surface texture may be added to the padding 1118 of first and second jaws 1108A-B to further increase the coefficient of friction between the block and the gripper 422. For example, FIG. 39C illustrates an example of a surface 1109 of a jaw 1108 having one or more shims 3902 applied to the surface 1109 of the jaw 1108.

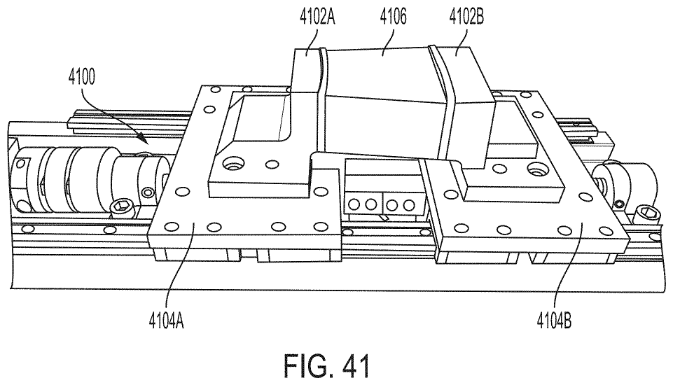

FIG. 41 illustrates an example gripper having interchangeable jaws, in accordance with some embodiments of the technology described herein. As described herein, a magnet assembly robot may be configured having a gripper 4100 for gripping an object, such as a permanent magnet, 4106. In addition, the magnet assembly assembled by the magnet assembly robot may comprise a plurality of permanent magnets which differ in size and shape. The inventors have recognized that different size and shape permanent magnets may require different clamping forces and/or differently shaped and/or sized jaws for gripping the different permanent magnets.

Thus, the inventors have thus recognized that it is advantageous to configure a gripper 4100 with interchangeable jaws and adjustable clamping force. In particular, as described herein, a gripper may comprise first and second jaws 4102A-B coupled to the gripper 4100 via movable surfaces 4104A-B. First and second jaws 4102A-B may be sized and shaped to accommodate a particular object gripped between the first and second jaws 4102A-B. For example, as shown in FIG. 41, the first and second jaws 4102A-B are sized and shaped for gripping a tapered permanent magnet 4106. When it is desired to grip a differently shaped object, the first and second jaws may be decoupled from the movable surfaces 4104A-B (for example, by unfastening one or more screws securing the first and second jaws 4102A-B to movable surfaces 4104A-B), and replaced with differently sized and/or shaped jaws. As such, differently sized and/or shaped objects may be securely gripped using gripper 4100.

In some embodiments, the gripper 4100 is additionally or alternatively configured to provide a variable clamping force on an object disposed between first and second jaws 4102A-B of the gripper 4100. For example, in some embodiments, the gripper 4100 may be configured to apply a clamping force between 150 lbf and 1000 lbf on an object. The clamping force may be selectable based on the object to be gripped. For example, with reference to FIGS. 27C-27J, the gripper 4100 may be configured to apply a clamping force of at least 150 lbf on permanent magnets of an inner ring 30, a clamping force of between 150 lbf and 250 lbf on permanent magnets of first and second middle rings 32, 34, and a clamping force of at least 250 lbf on permanent magnets of outer ring 36.

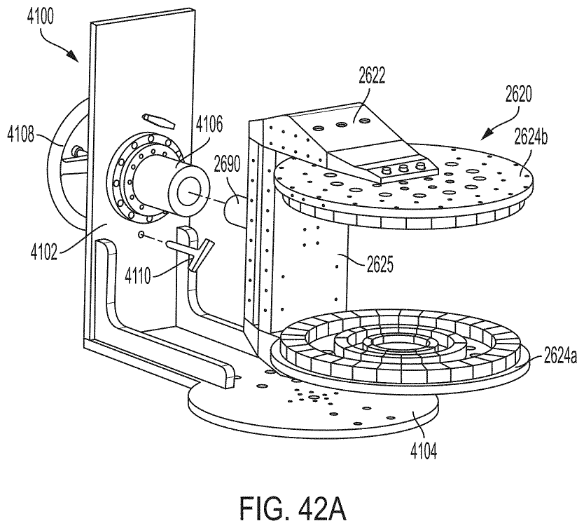

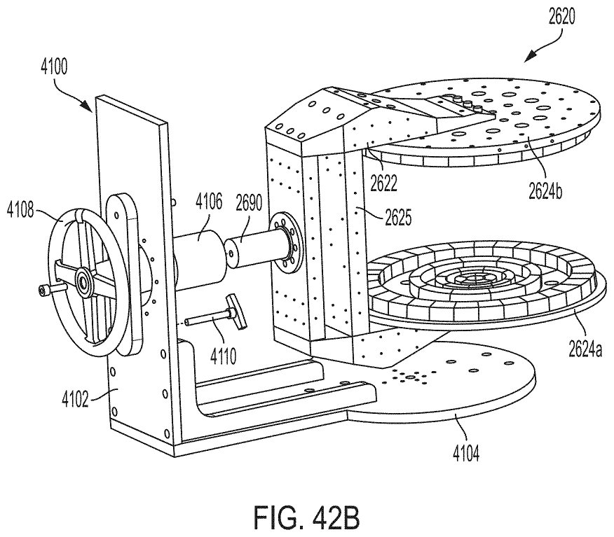

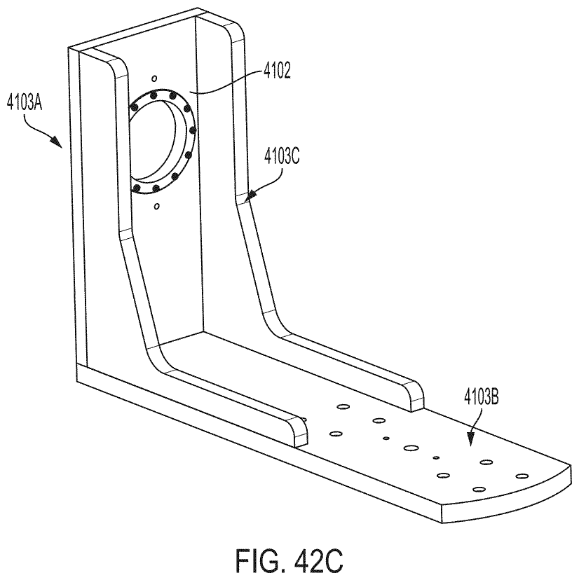

FIGS. 42A-42B illustrates perspective views of an example rotary mechanism for rotating a yoke of a magnet assembly, in accordance with some embodiments of the technology described herein. As described herein, the magnet assembly may comprise a yoke 2620 having first and second ferromagnetic plates 2624a-b on which permanent magnets may be placed by the robot and gripper. In some embodiments, the gripper may be rotated to enable placement of permanent magnets on a top plate 2624b of the yoke 2620. The inventors have recognized, however, that the robot may be simplified by coupling a rotary mechanism 4100 to rotate the yoke 2620 when it is desired to place permanent magnets on a top plate 2624b of the yoke 2620.

For example, as shown in FIGS. 42A-42B, the yoke 2620 comprises a first ferromagnetic plate 2624a and a second ferromagnetic plate 2624b disposed opposite and above the first ferromagnetic plate 2624b. The first and second ferromagnetic plates 2624a-b may be coupled to a frame 2622 and separated from each other by a vertical support 2625 of the frame 2622. The rotary mechanism 4100, further described herein, facilitates rotation of the yoke 2620 such that the second ferromagnetic plate 2624b can be disposed below the first ferromagnetic plate 2624a. Subsequent to the rotation, the robot may place permanent magnets on the second ferromagnetic plate 2624b of the yoke 2620 without having to rotate the gripper about the A axis as shown in FIG. 4B. Thus, the design of the robot may be simplified by implementing the rotary mechanism 4100 for rotating the yoke 2620.

As shown in FIGS. 42A-42C, the rotary mechanism 4100 comprises a frame 4102. The frame 4102 may be configured to couple to the yoke frame 2622. More specifically, the vertical support 2625 of the yoke frame 2622 may comprise a yoke mount 2620. The yoke mount 2620 may be received by a bearing mount 4106 of the rotary mechanism 4100. The yoke mount 2620 may be received by the bearing mount 4106 of the rotary mechanism 4100 such that the yoke 2620 rotates when wheel 4108 of the rotary mechanism 4100 is turned. In some embodiments the wheel 4108 may be rotated manually. In some embodiments, rotation of the wheel 4108 may be automated. As shown in FIGS. 42A-42B, the rotary mechanism 4100 may further comprise a pin 4110 for locking a position of the rotary mechanism.

FIG. 42C illustrates a perspective view of a frame 4102 of the example rotary mechanism of FIGS. 42A-42B, in accordance with some embodiments of the technology described herein. The frame may comprise a vertical portion 4103A, a horizontal portion 4103B, and partial side walls 4103C. The horizontal portion 4103B may be nearest to the ferromagnetic plates 2624a-b of the yoke 2620 on which permanent magnets of the magnet assembly are placed. Thus, in some embodiments, the horizontal portion 4103B may comprise a non-ferrous material such as aluminum. In some embodiments, the vertical portion 4103A and the sidewalls 4103C may comprise steel.

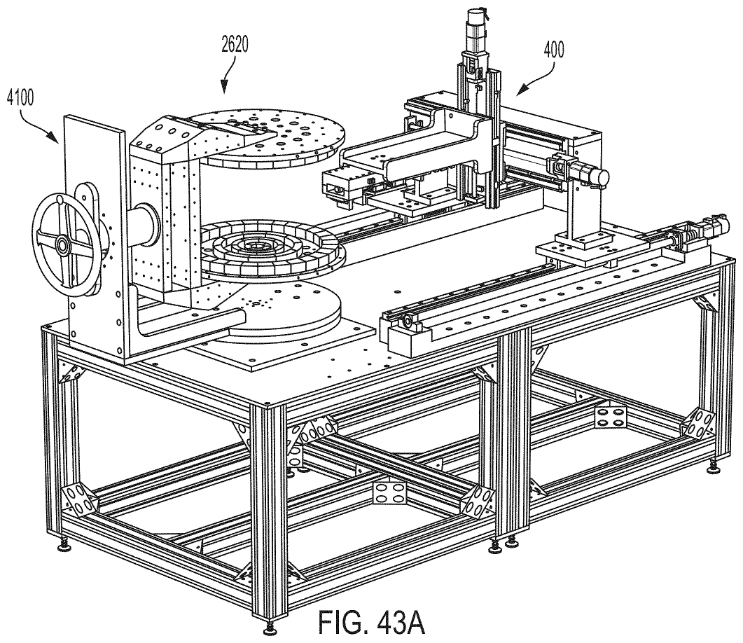

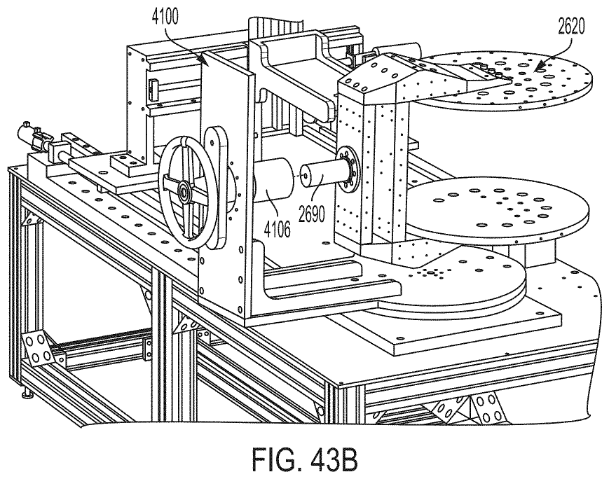

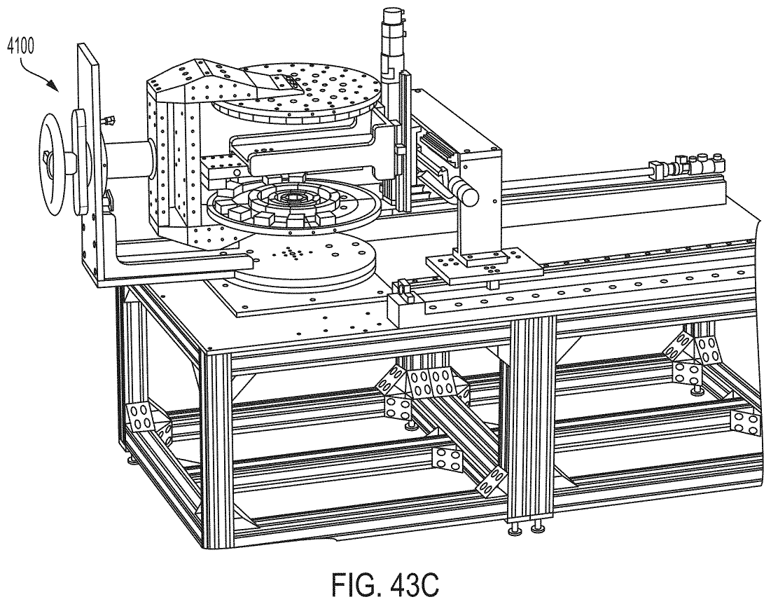

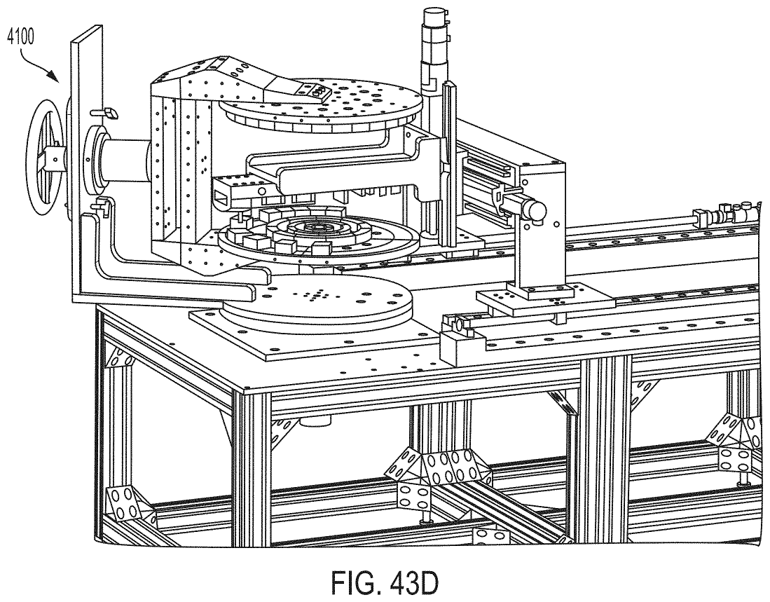

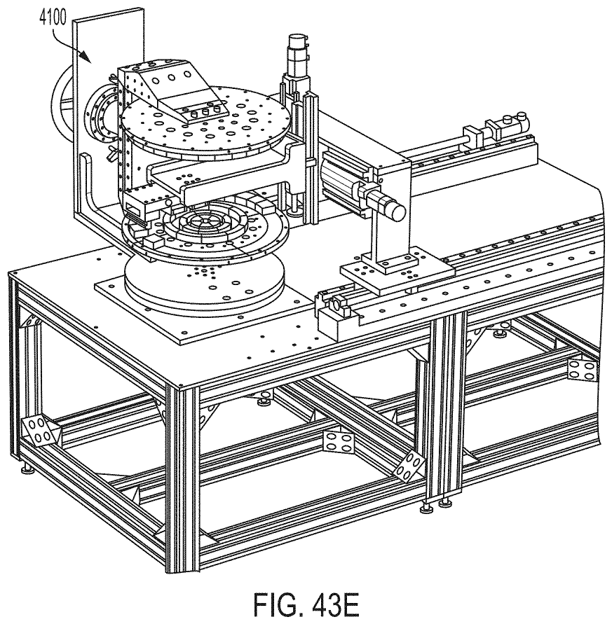

FIG. 43A illustrates a perspective view of the example rotary mechanism 4100 of FIGS. 42A-42B in combination with the example robot 400 of FIG. 4A, in accordance with some embodiments of the technology described herein. As described herein, the rotary mechanism may facilitate placement of permanent magnets on a top ferromagnetic plate of the yoke 4620 without requiring rotation of a gripper of the robot 400 about the A axis.

FIG. 43B illustrates the example rotary mechanism of FIGS. 42A-42B in the process of mounting a yoke of a magnet assembly, in accordance with some embodiments of the technology described herein. As described herein, the yoke 2620 may be coupled to the rotary mechanism 4100 via a yoke mount 2690 of the yoke 2620 and a bearing mount 4106 of the rotary mechanism 4100.

FIGS. 43C-43E illustrate the example rotary mechanism of FIGS. 42A-42B in combination with the example robot of FIG. 4A during a process of assembling a magnet assembly, in accordance with some embodiments of the technology described herein. As shown in FIGS. 43C-43E and described herein, the yoke and rotary mechanism 4100 may rotate about the C axis via a turntable to facilitate placement of permanent magnets on ferromagnetic plates of the yoke using the magnet assembly robot.

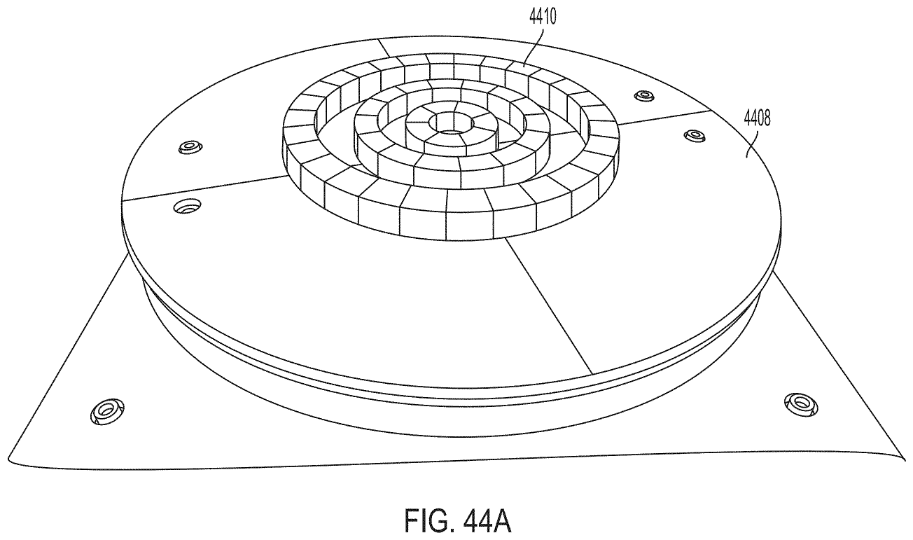

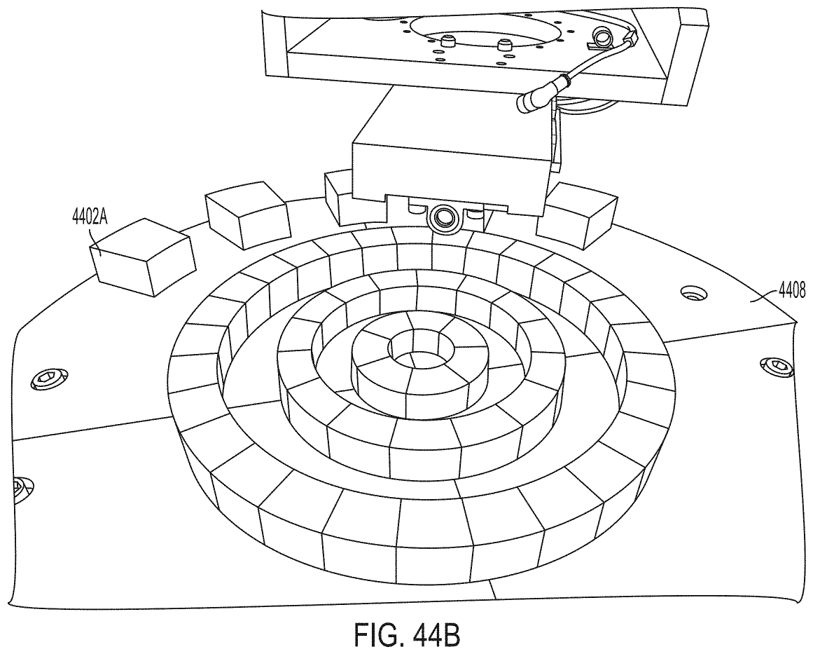

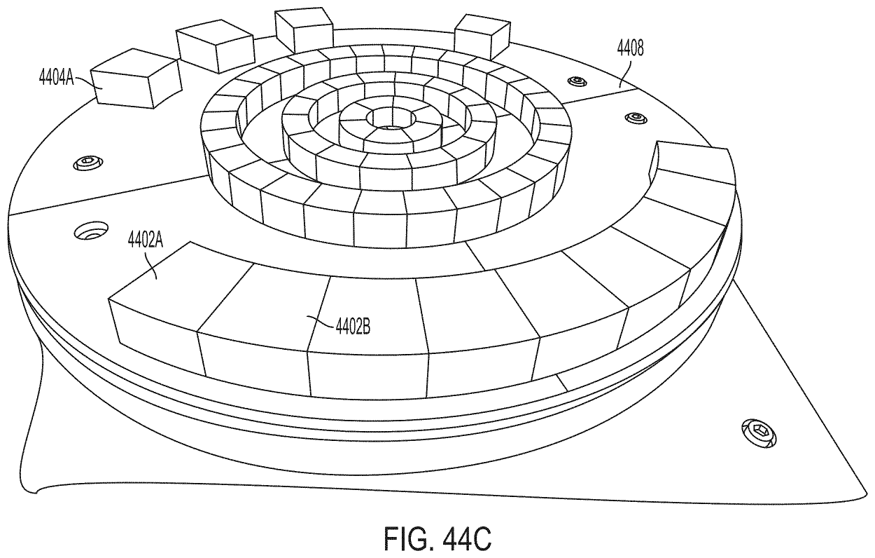

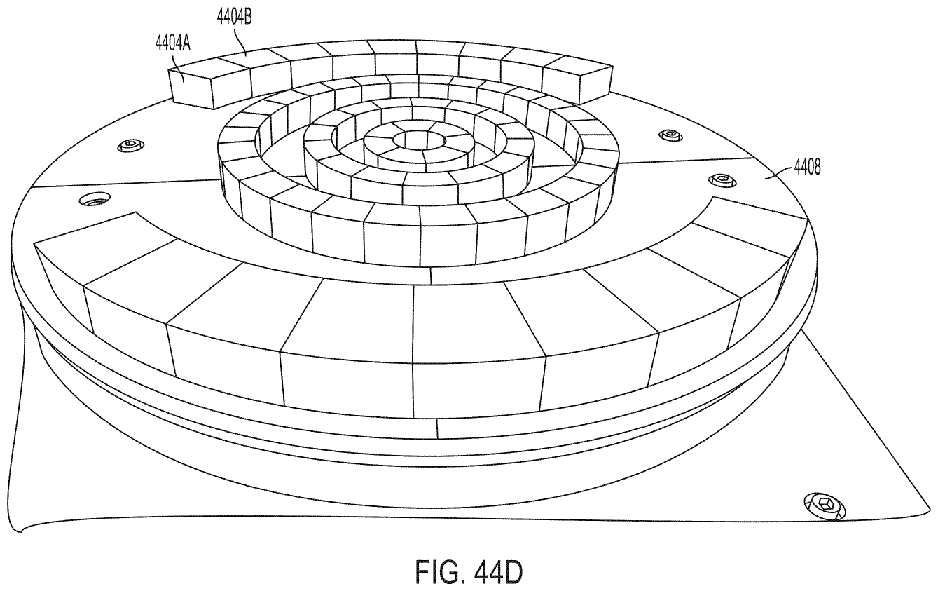

FIGS. 44A-44D illustrate an example method for placing permanent magnets onto a yoke of a magnet assembly, in accordance with some embodiments of the technology described herein. Placement of an outer ring of permanent magnets on a ferromagnetic plate 4108 is shown by way of example in FIGS. 44A-44D, however, the example method for placing permanent magnets onto a yoke of a magnet assembly described herein may likewise be performed for inner and middle rings of the magnet assembly, according to some embodiments.

The inventors have recognized that use of the rotary mechanism may require assembly of permanent magnet rings on a ferromagnetic plate of the magnet assembly in two or more portions. For example, due to the size of the rotary mechanism, full 360 degree rotation of the ferromagnetic plate about the C axis may not be feasible. Thus, the robot may be configured to assemble a first portion of a permanent magnet ring, and subsequently rotate the ferromagnetic plate about the C axis to assemble a second portion of that permanent magnet ring.

For example, as shown in FIG. 44A, a second middle ring 4410 may be assembled on the ferromagnetic plate 4408. As shown in FIG. 44B, subsequent to assembling the second middle ring 4410, the robot may be configured to place a first set of permanent magnets 4402A in anchoring positions on the ferromagnetic surface to begin assembling a first half of an outer ring of the magnet assembly. As shown in FIG. 44C, a second set of permanent magnets 4402B may be placed between permanent magnets of the first set of permanent magnets 4402A to form the first half of the outer ring.

Subsequent to forming the first half of the outer ring, the robot may begin placing permanent magnets of a third set of permanent magnets 4404A in anchoring positions on the ferromagnetic plate 4408 to form a second half of the outer ring. As shown in FIG. 44D, a fourth set of permanent magnets 4404B may be placed between permanent magnets of the second set of permanent magnets 4404A to form the second half of the outer ring.

Subsequent to forming a first half of a permanent magnet ring, first and second jaws of a gripper may be interchanged to adjust for the change in orientation of permanent magnets being placed in respective halves of the permanent magnet ring. For example, a right facing jaw may be interchanged with a left facing jaw, such that the right facing jaw now faces left, and the left facing jaw now faces right.

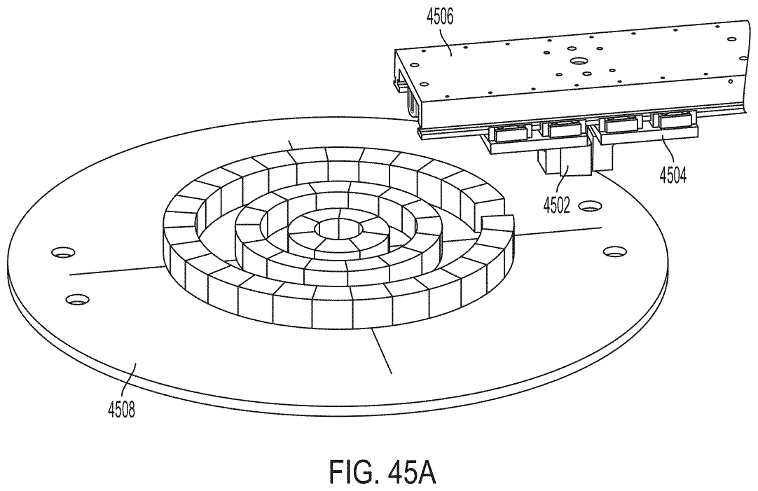

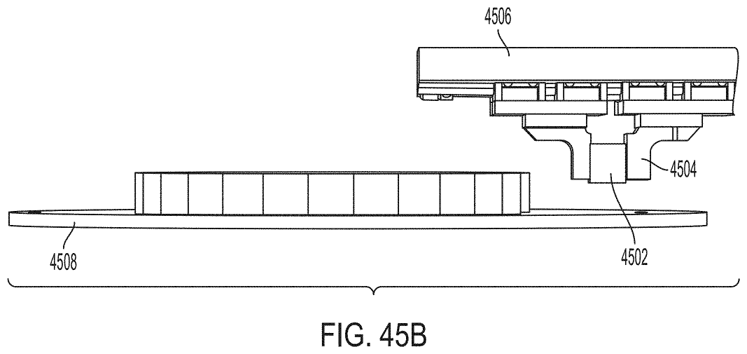

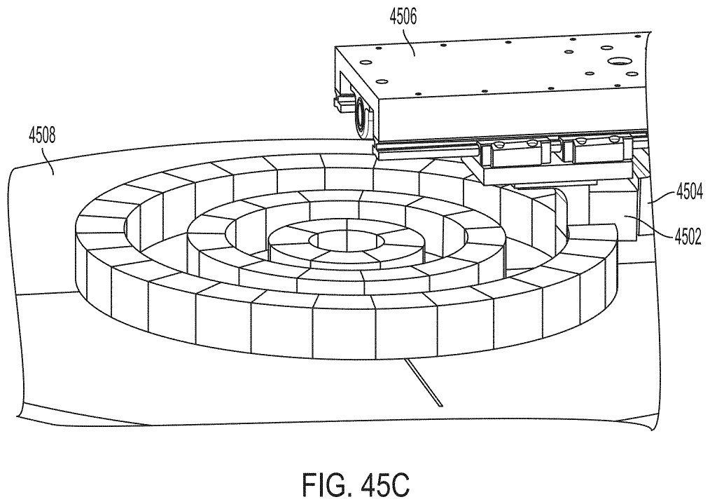

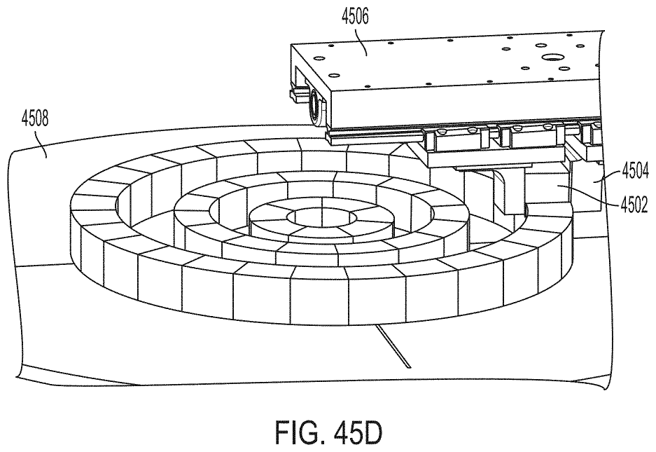

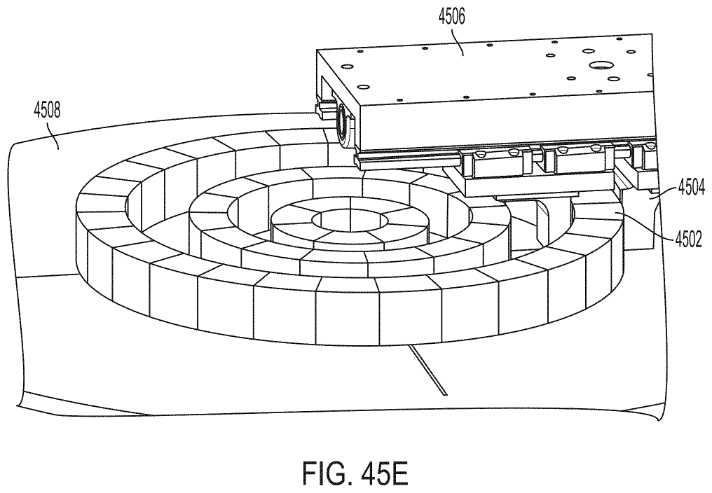

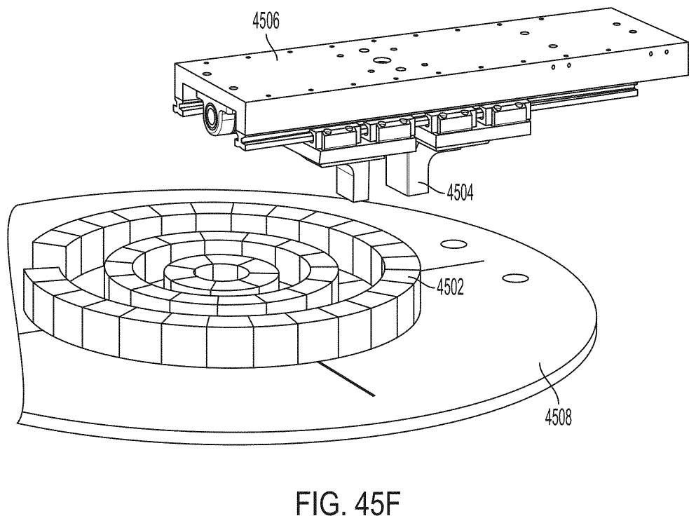

FIGS. 45A-45F illustrate an example method for inserting a permanent magnet onto a yoke of a magnet assembly, in accordance with some embodiments of the technology described herein. According to some embodiments, permanent magnets may be placed on a ferromagnetic plate of the magnet assembly in accordance with the example method illustrated in FIGS. 45A-45F.

FIG. 45A illustrates a first step of an example method for inserting a permanent magnet onto a yoke of a magnet assembly. As shown in FIG. 45A, a permanent magnet 4502 may be gripped between first and second jaws of a gripper 4504. The gripper 4504 may be coupled to a robot 4506 configured to move the gripper along the A, B, and C axes to place permanent magnet 4502 on a ferromagnetic plate 4508. In FIG. 45A, the robot 4506 moves the gripper 4504 and permanent magnet 4502 adjacent to the ferromagnetic plate.

FIG. 45B illustrates a second step of the example method for inserting a permanent magnet onto a yoke of a magnet assembly. As shown in FIG. 45B, the robot 4506 lowers the gripper 4504 and permanent magnet 4502 towards the ferromagnetic plate 4508 by moving the gripper 4504 along the C axis.

FIG. 45C illustrates a third step of the example method for inserting a permanent magnet onto a yoke of a magnet assembly. As shown in FIG. 45C, the robot 4506 moves the gripper 4504 and permanent magnet 4502 along the ferromagnetic plate 4508 and towards previously assembled permanent magnets by moving the gripper along the A axis.

FIG. 45D illustrates a fourth step of the example method for inserting a permanent magnet onto a yoke of a magnet assembly. As shown in FIG. 45D, the robot 4506 places the permanent magnet 4502 in position between previously assembled permanent magnets on the ferromagnetic plate 4508 by moving the gripper 4504 along the C axis.

FIG. 45E illustrates a fifth step of the example method for inserting a permanent magnet onto a yoke of a magnet assembly. As shown in FIG. 45E, once the permanent magnet 4502 is placed in position among previously assembled permanent magnets on the ferromagnetic plate 4508, jaws of the gripper 4504 release the permanent magnet 4502 from the gripper 4504.

FIG. 45F illustrates a sixth step of the example method for inserting a permanent magnet onto a yoke of a magnet assembly. A shown in FIG. 45F, the robot 4506 may move the gripper 4504 away from the ferromagnetic plate 4508 by moving the gripper along the C axis. As shown in FIGS. 45A-45F, the robot may be configured to alternate between moving the gripper 4504 and permanent magnet 4502 along the C axis, then A axis, and again along the C axis as opposed to completing all A axis movement before performing any movement along the C axis.

FIG. 46 illustrates an example method 4600 for assembling a magnetic resonance imaging system, in accordance with some embodiments of the technology described herein. As described herein, the magnet assembly assembled using the magnet assembly robot according to the techniques described herein may be implemented in an MRI system for performing magnetic resonance imaging.

The example method 4600 may begin at act 4602 where a magnetic assembly is assembled. The magnetic assembly may be configured to produce a B₀ field for the magnetic resonance imaging system. For example, the magnetic assembly may be assembled according to any of the techniques described herein. In some embodiments, assembling the magnetic assembly at act 4602 comprises controlling the magnet assembly robot to (1) grasp, using first and second jaws of a gripper coupled to the magnet assembly robot, a plurality of permanent magnets; and (2) position, using a robotic arm of the magnet assembly robot, the plurality of permanent magnets on a ferromagnetic surface.

At act 4604, a permanent magnet shim may be produced for the magnetic assembly. A B₀ magnet may require some level of shimming to produce a B₀ magnetic field with a profile satisfactory for use in MRI (e.g., a B₀ magnetic field at the desired field strength and/or homogeneity). Producing the permanent magnet shim for the magnetic assembly at act 4604 may be performed in accordance with any of the techniques described in are described in U.S. Pat. No. 10,613,168, titled “METHODS AND APPARATUS FOR MAGNETIC FIELD SHIMMING,” filed on Mar. 22, 2017, which is hereby incorporated by reference herein in its entirety. For example, in some embodiments, producing the permanent magnet shim for the magnetic assembly at act 4604 comprises (1) determining deviation of the B₀ field produced by the magnetic assembly from a desired B₀ field; (2) determining a magnetic pattern that, when applied to magnetic material of the magnetic assembly, produces a corrective magnetic field that corrects for at least some of the determined deviation; and (3) applying the magnetic pattern to the magnetic material of the magnetic assembly to produce the shim.

At act 4606, the magnetic resonance imaging system may be assembled using the magnetic assembly assembled at act 4602 and the permanent magnet shim produced at act 4604.

At act 4608, one or more additional magnetics components may be coupled to the magnetic resonance imaging system. For example, at act 4608, at least one radio-frequency coil may be coupled to the magnetic resonance imaging system. As described herein, the at least one radio-frequency coil may be configured to, when operated, transmit radio frequency signals to a field of view of the magnetic resonance imaging system and/or to respond to magnetic resonance signals emitted from the field of view. In some embodiments, a plurality of gradient coils may be coupled to the magnetic resonance imaging system. As described herein, the plurality of gradient coils may be configured to, when operated, generate magnetic fields to provide spatial encoding of emitted magnetic resonance signals. It should be appreciated that the at least one radio-frequency coil and the plurality of gradient coils are examples of additional magnetics components for coupling to the magnetic resonance imaging system, and one or more additional or alternative magnetics components may be coupled to the magnetic resonance imaging system.

In some embodiments, coupling the one or more additional magnetics components to the magnetic resonance imaging system comprises mechanically coupling the one or more additional magnetics components to the magnetic resonance imaging system. In some embodiments, coupling the one or more additional magnetics components to the magnetic resonance imaging system comprises electrically coupling the one or more additional magnetics components to the magnetic resonance imaging system, for example, by coupling the one or more additional magnetics components to a power source of the magnetic resonance imaging system.

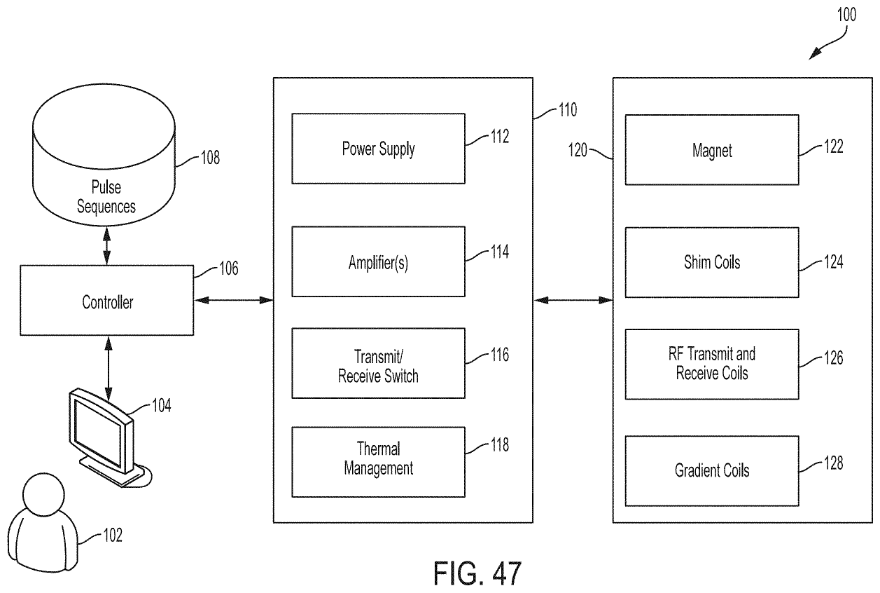

FIG. 47 illustrates exemplary components of a magnetic resonance imaging system, in accordance with some embodiments of the technology described herein. In the illustrative example of FIG. 41, MRI system 100 comprises computing device 104, controller 106, pulse sequences store 108, power management system 110, and magnetics components 120. It should be recognized that system 100 is illustrative and that an MRI system may have one or more other components of any suitable type in addition to or instead of the components illustrated in FIG. 41. However, an MRI system will generally include these high level components, though the implementation of these components for a particular MRI system may differ vastly, as discussed in further detail below.

As illustrated in FIG. 41, magnetics components 120 comprise B₀ magnet 122, shim coils 124, RF transmit and receive coils 126, and gradient coils 128. Magnet 122 may be used to generate the main magnetic field B₀. Magnet 122 may be any suitable type or combination of magnetics components that can generate a desired main magnetic B₀ field. In some embodiments, Magnet 122 can be assembled using the system 400 and/or according to the methods described herein.

Gradient coils 128 may be arranged to provide gradient fields and, for example, may be arranged to generate gradients in the B₀ field in three substantially orthogonal directions (X, Y, Z). Gradient coils 128 may be configured to encode emitted MR signals by systematically varying the B₀ field (the B₀ field generated by magnet 122 and/or shim coils 124) to encode the spatial location of received MR signals as a function of frequency or phase. For example, gradient coils 128 may be configured to vary frequency or phase as a linear function of spatial location along a particular direction, although more complex spatial encoding profiles may also be provided by using nonlinear gradient coils. For example, a first gradient coil may be configured to selectively vary the B₀ field in a first (X) direction to perform frequency encoding in that direction, a second gradient coil may be configured to selectively vary the B₀ field in a second (Y) direction substantially orthogonal to the first direction to perform phase encoding, and a third gradient coil may be configured to selectively vary the B₀ field in a third (Z) direction substantially orthogonal to the first and second directions to enable slice selection for volumetric imaging applications. As discussed above, conventional gradient coils also consume significant power, typically operated by large, expensive gradient power sources, as discussed in further detail herein.

MRI is performed by exciting and detecting emitted MR signals using transmit and receive coils, respectively (often referred to as radio frequency (RF) coils). Transmit/receive coils may include separate coils for transmitting and receiving, multiple coils for transmitting and/or receiving, or the same coils for transmitting and receiving. Thus, a transmit/receive component may include one or more coils for transmitting, one or more coils for receiving and/or one or more coils for transmitting and receiving. Transmit/receive coils are also often referred to as Tx/Rx or Tx/Rx coils to generically refer to the various configurations for the transmit and receive magnetics component of an MRI system. These terms are used interchangeably herein. In FIG. 41, RF transmit and receive coils 126 comprise one or more transmit coils that may be used to generate RF pulses to induce an oscillating magnetic field B₁. The transmit coil(s) may be configured to generate any suitable types of RF pulses.

Power management system 110 includes electronics to provide operating power to one or more components of the low-field MRI system 100. For example, as discussed in more detail below, power management system 110 may include one or more power supplies, gradient power components, transmit coil components, and/or any other suitable power electronics needed to provide suitable operating power to energize and operate components of MRI system 100. As illustrated in FIG. 41, power management system 110 comprises power supply 112, power component(s) 114, transmit/receive switch 116, and thermal management components 118 (e.g., cryogenic cooling equipment for superconducting magnets). Power supply 112 includes electronics to provide operating power to magnetic components 120 of the MRI system 100. For example, power supply 112 may include electronics to provide operating power to one or more B₀ coils (e.g., B₀ magnet 122) to produce the main magnetic field for the low-field MRI system. Transmit/receive switch 116 may be used to select whether RF transmit coils or RF receive coils are being operated.

Power component(s) 114 may include one or more RF receive (Rx) pre-amplifiers that amplify MR signals detected by one or more RF receive coils (e.g., coils 126), one or more RF transmit (Tx) power components configured to provide power to one or more RF transmit coils (e.g., coils 126), one or more gradient power components configured to provide power to one or more gradient coils (e.g., gradient coils 128), and one or more shim power components configured to provide power to one or more shim coils (e.g., shim coils 124).

As illustrated in FIG. 41, MRI system 100 includes controller 106 (also referred to as a console) having control electronics to send instructions to and receive information from power management system 110. Controller 106 may be configured to implement one or more pulse sequences, which are used to determine the instructions sent to power management system 110 to operate the magnetic components 120 in a desired sequence (e.g., parameters for operating the RF transmit and receive coils 126, parameters for operating gradient coils 128, etc.). As illustrated in FIG. 41, controller 106 also interacts with computing device 104 programmed to process received MR data. For example, computing device 104 may process received MR data to generate one or more MR images using any suitable image reconstruction process(es). Controller 106 may provide information about one or more pulse sequences to computing device 104 for the processing of data by the computing device. For example, controller 106 may provide information about one or more pulse sequences to computing device 104 and the computing device may perform an image reconstruction process based, at least in part, on the provided information.

Magnets assembled according to aspects of the technology described herein may be integrated into a portable, low power MRI systems capable of being brought to the patient, providing affordable and widely deployable MRI where it is needed. FIGS. 48A-C illustrate views of a portable MRI system, in accordance with some embodiments. Portable MRI system 1200 comprises a B₀ magnet 1210 formed in part by an upper magnet 1210a and a lower magnet 1210b having a yoke 1220 coupled thereto to increase the flux density within the imaging region. B₀ magnet 1210 may be assembled using the magnet assembly robot according to the methods described herein. The B₀ magnet 1210 may be housed in magnet housing 1212 along with gradient coils 1215. In some embodiments, B₀ magnet 1210 comprises an electromagnet. In some embodiments, B₀ magnet 1210 comprises a permanent magnet (e.g., a permanent magnet 2600 illustrated in FIG. 26A or a similar permanent magnet).

Portable MRI system 1200 further comprises a base 1250 housing the electronics needed to operate the MRI system. For example, base 1250 may house electronics including power components configured to operate the MRI system using mains electricity (e.g., via a connection to a standard wall outlet and/or a large appliance outlet).

Portable MRI system 1200 further comprises moveable slides 1260 that can be opened and closed and positioned in a variety of configurations. Slides 1260 include electromagnetic shielding 1265, which can be made from any suitable conductive or magnetic material, to form a moveable shield to attenuate electromagnetic noise in the operating environment of the portable MRI system to shield the imaging region from at least some electromagnetic noise.

To ensure that the moveable shields provide shielding regardless of the arrangements in which the slides are placed, electrical gaskets may be arranged to provide continuous shielding along the periphery of the moveable shield. For example, as shown in FIG. 48B, electrical gaskets 1267a and 1267b may be provided at the interface between slides 1260 and magnet housing to maintain to provide continuous shielding along this interface. In some embodiments, the electrical gaskets are beryllium fingers or beryllium-copper fingers, or the like (e.g., aluminum gaskets), that maintain electrical connection between shields 1265 and ground during and after slides 1260 are moved to desired positions about the imaging region. According to some embodiments, electrical gaskets 1267c are provided at the interface between slides 1260 so that continuous shielding is provided between slides in arrangements in which the slides are brought together. Accordingly, moveable slides 1260 can provide configurable shielding for the portable MRI system.

FIG. 48C illustrates another example of a portable MRI system, in accordance with some embodiments. Portable MRI system 1300 may be similar in many respects to portable MRI systems illustrated in FIGS. 48A-48B. However, slides 1360 are constructed differently, as is shielding 1365, resulting in electromagnetic shields that are easier and less expensive to manufacture. Aspects of electromagnetic shielding designs are described in U.S. Pat. No. 10,274,561, titled “Electromagnetic Shielding for Magnetic Resonance Imaging Methods and Apparatus,” filed on Jan. 24, 2018, which is hereby incorporated by reference herein in its entirety.

To facilitate transportation, a motorized component 1280 is provided to allow portable MRI system to be driven from location to location, for example, using a controller such as a joystick or other control mechanism provided on or remote from the MRI system. In this manner, portable MRI system 1200 can be transported to the patient and maneuvered to the bedside to perform imaging.

Having thus described several aspects and embodiments of the technology set forth in the disclosure, it is to be recognized that various alterations, modifications, and improvements will readily occur to those skilled in the art. Such alterations, modifications, and improvements are intended to be within the spirit and scope of the technology described herein. For example, those of ordinary skill in the art will readily envision a variety of other means and/or structures for performing the function and/or obtaining the results and/or one or more of the advantages described herein, and each of such variations and/or modifications is deemed to be within the scope of the embodiments described herein. Those skilled in the art will recognize, or be able to ascertain using no more than routine experimentation, many equivalents to the specific embodiments described herein. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

For example, although aspects of the technology have been described herein with reference to lead screws, the technology may be implemented using any suitable screw and/or other driving mechanism (e.g. ball screws, worm drives, etc.), as aspects of the technology described herein are not limited in this respect.

The above-described embodiments can be implemented in any of numerous ways. For example, the embodiments may be implemented using hardware, software or a combination thereof. When implemented in software, the software code can be executed on any suitable processor (e.g., a microprocessor) or collection of processors, whether provided in a single computing device or distributed among multiple computing devices. It should be recognized that any component or collection of components that perform the functions described above can be generically considered as one or more controllers that control the above-discussed functions. The one or more controllers can be implemented in numerous ways, such as with dedicated hardware, or with general purpose hardware (e.g., one or more processors) that is programmed using microcode or software to perform the functions recited above.

In this respect, it should be recognized that one implementation of the embodiments described herein comprises at least one computer-readable storage medium (e.g., RAM, ROM, EEPROM, flash memory or other memory technology, CD-ROM, digital versatile disks (DVD) or other optical disk storage, magnetic cassettes, magnetic tape, magnetic disk storage or other magnetic storage devices, or other tangible, non-transitory computer-readable storage medium) encoded with a computer program (i.e., a plurality of executable instructions) that, when executed on one or more processors, performs the above-discussed functions of one or more embodiments. The computer-readable medium may be transportable such that the program stored thereon can be loaded onto any computing device to implement aspects of the techniques discussed herein. In addition, it should be recognized that the reference to a computer program which, when executed, performs any of the above-discussed functions, is not limited to an application program running on a host computer. Rather, the terms computer program and software are used herein in a generic sense to reference any type of computer code (e.g., application software, firmware, microcode, or any other form of computer instruction) that can be employed to program one or more processors to implement aspects of the techniques discussed herein.

Various aspects of the technology described herein may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the technology described herein may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

The terms “approximately”, “substantially,” and “about” may be used to mean within ±20% of a target value in some embodiments, within ±10% of a target value in some embodiments, within ±5% of a target value in some embodiments, and within ±2% of a target value in some embodiments. The terms “approximately” and “about” may include the target value.

What is claimed is:

1. A system, comprising:
a robot configured to place a plurality of permanent magnets on a ferromagnetic surface in accordance with a permanent magnet layout for a magnetic assembly, the robot comprising:
a robotic arm comprising multiple arm segments movable along respective degrees of freedom;
a gripper comprising a base, and first and second jaws movably coupled to the base; and
at least one controller configured to:
access information specifying the permanent magnet layout;
grasp, using the first and second jaws of the gripper, a first permanent magnet from the plurality of permanent magnets;
position, using the robotic arm, the first permanent magnet at a location on the ferromagnetic surface in accordance with the permanent magnet layout; and
release the first permanent magnet from the gripper after positioning the first permanent magnet.

2. The system of claim 1, wherein the at least one controller is further configured to position each of the plurality of permanent magnets, including the first permanent magnet, on the ferromagnetic surface in accordance with the permanent magnet layout.

3. The system of claim 2, wherein the at least one controller is further configured to position the plurality of permanent magnets on the ferromagnetic surface at a rate of no more than 3.5 minutes per permanent magnet.

4. The system of claim 2, wherein the at least one controller is further configured to position each of the plurality of permanent magnets to form at least one ring of permanent magnets on the ferromagnetic surface.

5. The system of claim 4, wherein the at least one ring comprises a plurality of concentric rings of permanent magnets.

6. The system of claim 4, wherein the at least one ring comprises at least 20 permanent magnets.

7. The system of claim 1, wherein the at least one controller is further configured to position, using the robotic arm, a second permanent magnet at a location on the ferromagnetic surface no more than 2 millimeters apart from the first permanent magnet.

8. The system of claim 1, wherein the first permanent magnet has a maximum dimension of 80 millimeters or less.

9. The system of claim 2, wherein the plurality of permanent magnets comprises at least 20 permanent magnets.

10. The system of claim 2, wherein the at least one controller is further configured to:
place the first permanent magnet on the ferromagnetic surface;
rotate the ferromagnetic surface; and
place a second permanent magnet of the plurality of permanent magnets on the ferromagnetic surface after rotating the ferromagnetic surface.

11. The system of claim 4, wherein the at least one controller is further configured to:
position a first set of permanent magnets at anchoring positions in a ring layout; and
after positioning the first set of permanent magnets, position a second set of permanent magnets at positions between the anchoring positions in the ring layout.

12. The system of claim 11, wherein the anchoring positions in the ring layout are equidistant from one another.

13. The system of claim 1, wherein the robot is configured to determine a series of movements to be performed to place the plurality of permanent magnets on the ferromagnetic surface based on the information specifying permanent magnet layout.

14. The system of claim 1, wherein the information specifying permanent magnet layout indicates a series of movements to be performed by the robot to place the plurality of permanent magnets on the ferromagnetic surface.

15. The system of claim 1, wherein:
the ferromagnetic surface comprises a first ferromagnetic surface and a second ferromagnetic surface disposed above the first ferromagnetic surface; and
the system further comprises a frame coupled to the first and second ferromagnetic surfaces and configured to rotate to first and second ferromagnetic surfaces such that, subsequent to rotating the first and second ferromagnetic surfaces, the second ferromagnetic surface is disposed below the first ferromagnetic surface.

16. A method for placing permanent magnets on a ferromagnetic surface in accordance with a permanent magnet layout for a magnetic assembly using a robot comprising a robotic arm comprising multiple arm segments movable along respective degrees of freedom, and a gripper having a first and second jaw movably coupled to a base of the gripper, the method comprising:
accessing information specifying the permanent magnet layout for the magnetic assembly; and
controlling the robot to:
grasp, using the first and second jaws of the gripper, a first permanent magnet from a plurality of permanent magnets;
position, using the robotic arm, the first permanent magnet at a location on the ferromagnetic surface in accordance with the permanent magnet layout; and
release the first permanent magnet from the gripper after positioning the first permanent magnet.

17. The method of claim 16, further comprising causing the ferromagnetic surface to rotate using a motor coupled to the ferromagnetic surface after releasing the first permanent magnet from the gripper.

18. The method of claim 16, further comprising controlling the robot to place a first plurality of permanent magnets on the ferromagnetic surface and then controlling the robot to place one or more permanent magnets in a second plurality of permanent magnets between each of the permanent magnets in the first plurality of permanent magnets.

19. The method of claim 16, wherein:
the ferromagnetic surface comprises a first ferromagnetic surface and a second ferromagnetic surface disposed above the first ferromagnetic surface; and
the method further comprises rotating the first and second ferromagnetic surfaces such that, subsequent to the rotating, the second ferromagnetic surface is disposed below the first ferromagnetic surface.

20. A computer-readable medium storing instructions that, when executed by an apparatus configured to place permanent magnets on a ferromagnetic surface in accordance with a permanent magnet layout for a magnetic assembly, the apparatus comprising a robot comprising a robotic arm having multiple arm segments movable along respective degrees of freedom, and a gripper having a first and second jaw coupled to a base of the gripper, cause the apparatus to perform a process comprising:
accessing information specifying the permanent magnet layout for the magnetic assembly; and
controlling the robot to:
grasp, using the first and second jaws of the gripper, a first permanent magnet from a plurality of permanent magnets;
position, using the robotic arm, the first permanent magnet at a location on the ferromagnetic surface in accordance with the permanent magnet layout; and
release the first permanent magnet from the gripper after positioning the first permanent magnet.
